(19) United States
(12) Patent Application Publication
(10) Pub. No.: US 2016/0005994 A1
(43) Pub. Date: Jan. 7, 2016

(54) ORGANIC ELECTROLUMINESCENCE DEVICE

(71) Applicants: NIPPON HOSO KYOKAI, Shibuya-ku, Tokyo (JP); NIPPON SHOKUBAI CO., LTD., Osaka-shi, Osaka (JP)

(72) Inventors: Hirohiko FUKAGAWA, Tokyo (JP); Takahisa SHIMIZU, Tokyo (JP); Katsuyuki MORII, Osaka (JP)

(73) Assignees: NIPPON HOSO KYOKAI, Shibuya-ku, Tokyo (JP); NIPPON SHOKUBAI CO., LTD., Osaka-shi, Osaka (JP)

(21) Appl. No.: 14/768,646

(22) PCT Filed: Feb. 28, 2014
(86) PCT No.: PCT/JP2014/055101

§ 371 Date: Aug. 18, 2015

(30) Foreign Application Priority Data
Feb. 28, 2013 (JP) 2013-039902

(51) Int. Cl. H01L 51/52; H01L 51/00; H01L 51/50

(52) U.S. Cl. CPC H01L 51/5246; H01L 51/5088; H01L 51/5221; H01L 51/0097; H01L 2251/303; H01L 2251/301; H01L 2251/5338; H01L 51/0072; H01L 51/004; H01L 51/008; H01L 51/0034

(57) ABSTRACT

The present invention aims to provide an organic electroluminescence device that operates successfully without strict sealing. Provided is an organic electroluminescence device having a structure in which a plurality of layers is stacked between an anode and a cathode formed on a substrate, wherein the organic electroluminescence device is sealed to provide a water vapor transmission rate of 10⁻⁶ to 10⁻³ g/m²·day.

### TECHNICAL FIELD

The present invention relates to an organic electroluminescence device. More specifically, the present invention relates to an organic electroluminescence device that can be used for a display device such as a display unit of an electronic device, a lighting system, and the like.

### BACKGROUND ART

An organic electroluminescence device (organic EL device) is promising as a novel luminescence device applicable to display devices and lighting.

The organic electroluminescence device has a structure in which one or more kinds of layers including an emitting layer containing a light-emitting organic compound are sandwiched between an anode and a cathode. The organic electroluminescence device excites the light-emitting organic compound with energy generated upon recombination of holes injected from the anode with electrons injected from the cathode to achieve emission. The organic electroluminescence device is a current-driven device. Various studies have been made on device structures and materials of the layers constituting the device for more efficient use of a flowing current.

The most basic and much studied structure of the organic electroluminescence device is a three-layer structure proposed by Adachi et al. (see Non-Patent Literature 1) in which a hole transport layer, an emitting layer, and an electron-transport layer are sandwiched in this order between an anode and a cathode. Since this proposal, the three-layer structure has become the basic structure of the organic electroluminescence device, and many studies have been made to improve performance such as efficiency and life by assigning a more specific function to each layer. This idea is based on the fact that electrons to be injected already have high energy at the time of injection (in the electrode).

Thus, the organic electroluminescence device is usually prone to degradation by oxygen and water, and must be strictly sealed to prevent entrance of oxygen and water. Degradation is caused by the following factors: materials that can be used as cathodes are limited to those having a low work function such as alkali metals and alkali metal compounds for ease of electron injection into an organic compound; and an organic compound that is used easily reacts with oxygen or water. The organic electroluminescence device has become more competitive than other luminescence devices as a result of strict sealing, but its features such as low cost and flexibility are sacrificed at the same time.

### CITATION LIST

### Non-Patent Literature

Non-Patent Literature 1: Japanese Journal of Applied Physics, 1988, vol. 27, L269

### SUMMARY OF INVENTION

### Technical Problem

As described above, an organic electroluminescence device is generally strictly sealed, which made the device more competitive than other luminescence devices while its features such as low cost and flexibility are sacrificed. As of 2013, along with rapid development of flexible devices and increasing interest, there is a rapidly increasing demand today for a technique for organic electroluminescence devices that can actually meet flexibility requirements.

The present invention is made in view of the current situation described above. The present invention aims to solve the most challenging problem of sealing from the fundamental perspective, and to provide an organic electroluminescence device that operates successfully without strict sealing.

### Solution to Problem

The present inventors conducted various studies on organic electroluminescence devices that operate without strict sealing. With a focus on an inverted organic electroluminescence device in which a plurality of layers is laminated between an anode and a cathode that is formed on a substrate, the present inventors studied sealing conditions for operation of the inverted organic electroluminescence. As a result, they found that while conventional strict sealants (such as glass) have excellent sealing properties with a water vapor transmission rate of 10⁻⁶ or better sealing properties, it is possible to provide a good continuous operation life and good storage stability to a device even with lower sealing properties as long as the device is sealed to provide a water vapor transmission rate of 10⁻⁶ to about 10⁻³ g/m²·day (hereinafter described as the device being sealed to provide a water vapor transmission rate of 10⁻⁶ to 10⁻³ g/m²·day). The above problems were successfully solved based on this finding, and the present invention was thus accomplished.

Specifically, the present invention provides an organic electroluminescence device having a structure in which a plurality of layers is laminated between an anode and a cathode formed on a substrate, wherein the organic electroluminescence device is sealed to provide a water vapor transmission rate of 10⁻⁶ to 10⁻³ g/m²·day.

The present invention is described in detail below.

A combination of two or more of individual preferred embodiments of the present invention described below is also a preferred embodiment of the present invention.

The organic electroluminescence device of the present invention is sealed to provide a water vapor transmission rate of 10⁻⁶ to 10⁻³ g/m²·day.

Generally, in the case of an organic electroluminescence device that must be strictly sealed, the device must be sealed to provide a water vapor transmission rate of 10⁻⁶ g/m²·day or lower. In contrast, the organic electroluminescence device of the present invention is a simply sealed organic electroluminescence device that allows a water vapor transmission rate of about 1000 times higher than that of the strictly sealed organic electroluminescence device.

The greatest advantages of such a simply sealed organic electroluminescence device are that the device can be made flexible and that the device can be produced at low cost. Another great advantage is that a member (such as a film for increasing light extraction efficiency) whose use was limited due to its sealing properties can be used in the simply sealed organic electroluminescence device. This results in a device with low power consumption and a long life. Other advantages are that the variation in quality among individual devices is reduced and that the size of a display device or a lighting system can be easily increased.

The organic electroluminescence device of the present invention is sealed to provide a water vapor transmission rate of 10⁻⁶ to 10⁻³ g/m²·day to achieve good luminescence properties by simple sealing. The term “good luminescence properties” means not only that no dark spots are present but also that the basic properties of the device (for example, voltage-luminance properties) remain the same between the initial period and after 500 hours of being left in air from the production of the device. More preferably, the term means that the voltage-luminance properties remain the same between the initial period and after 10000 hours of being left in air from the production of the device. A device sealed to provide a water vapor transmission rate of 10⁻² g/m²·day will suffer from many spots with weak luminance and a significant decrease in luminance, although dark spots do not appear under optimal conditions of the present invention. A device sealed to provide a higher water vapor transmission rate will consecutively suffer from degradation of luminescence properties.

An organic electroluminescence device that does not require strict sealing is preferred in terms of production cost, and an organic electroluminescence device that is strictly sealed is preferred in terms of operation life of the device. In view of these points, it is preferred that the organic electroluminescence device of the present invention be sealed to provide a water vapor transmission rate of 10⁻⁶ to 10⁻³ g/m²·day. It is more preferred that the organic electroluminescence device be sealed to provide a water vapor transmission rate of 10⁻⁵ to 10⁻³ g/m²·day. It is still more preferred that the organic electroluminescence device be sealed to provide a water vapor transmission rate of 10⁻⁵ to 10⁻⁴ g/m²·day.

The water vapor transmission rate of the organic electroluminescence device can be measured by several measuring devices. In the present invention, the calcium corrosion method can be used for measurement because the water vapor transmission rate must be measured to a rate of 10⁻⁶ g/m²·day.

The method for sealing the device to provide a water vapor transmission rate of 10⁻⁶ to 10⁻³ g/m²·day is not particularly limited. For example, the organic electroluminescence device can be sealed with a sealing film having a water vapor transmission rate of 10⁻⁶ to 10⁻³ g/m²·day. Sealing the device to provide a water vapor transmission rate of 10⁻⁶ to 10⁻³ g/m²·day (a sealing system to provide a water vapor transmission rate of 10⁻⁶ to 10⁻³ g/m²·day) and a member for sealing to provide a water vapor transmission rate of 10⁻⁶ to 10⁻³ g/m²·day are also encompassed by the present invention. A sealing film is preferred as a member for sealing to provide such a water vapor transmission rate.

An organic electroluminescence device sealed with a sealing film may have a structure in which a substrate different from the sealing film is provided on the sealing film, a cathode is formed on the substrate, and various layers are laminated on the cathode; or may have a structure in which the sealing film is used as a substrate, a cathode is directly formed on the sealing film, and various layers are laminated on the cathode. In either case, the organic electroluminescence device is formed using a thin film material essentially including a sealing film having a water vapor transmission rate of 10⁻⁶ to 10⁻³ g/m²·day.

Such a thin film material is used to form the organic electroluminescence device of the present invention. The thin film material for forming the organic electroluminescence device essentially including a film having a water vapor transmission rate of 10⁻⁶ to 10⁻³ g/m²·day is also encompassed by the present invention.

The thin film material for forming the organic electroluminescence device may consist of a film having a water vapor transmission rate of 10⁻⁶ to 10⁻³ g/m²·day or may include one or more layers laminated on a film having a water vapor transmission rate of 10⁻⁶ to 10⁻³ g/m²·day.

In the case of the thin film material in which one or more layers are laminated on the film, the number and the kind of layers laminated are not particularly limited. Yet, examples of preferred embodiments include one consisting of a film and a substrate formed on the film; one consisting of a film on which a substrate and a cathode are formed in that order; one consisting of a film on which a substrate, a cathode, and an electron injection layer are formed in that order; one consisting of a film on which a substrate, a cathode, an electron injection layer, and a buffer layer are formed in that order; one consisting of a film and a cathode directly formed on the film; one consisting of a film, a cathode directly formed on the film, and an electron injection layer formed on the cathode; and one consisting of a film, a cathode directly formed on the film, an electron injection layer formed on the cathode, and a buffer layer formed on the electron injection layer.

Preferred substrate, cathode, electron injection layer, and buffer layer are described later.

Layers forming the organic electroluminescence device may include, in addition to an emitting layer, layers such as an electron injection layer, an electron-transport layer, a hole transport layer, and a hole injection layer. These layers are suitably selected and laminated to form the organic electroluminescence device.

The organic electroluminescence device of the present invention is not particularly limited in terms of the layer laminate structure as long as the device has a structure in which a plurality of layers is laminated between the anode and the cathode formed on the substrate. Yet, preferably, the device has a structure in which the following layers are laminated adjacently in the stated order: a cathode, an electron injection layer, a hole blocking layer (if necessary), an electron-transport layer, an emitting layer, a hole transport layer (if necessary), a hole injection layer, and an anode.

In the case where the organic electroluminescence device of the present invention includes a buffer layer (described later) and does not include an electron-transport layer, or in the case where a buffer layer also acts as an electron-transport layer, the device preferably has a structure in which the following layers are laminated adjacently in the stated order: a cathode, an electron injection layer, a buffer layer, a hole blocking layer, an emitting layer, a hole transport layer (if necessary), a hole injection layer, and an anode.

In the case where the organic electroluminescence device of the present invention includes a buffer layer (described later) and also includes an electron-transport layer as an independent layer separate from the buffer layer, the organic electroluminescence device of the present invention preferably has a structure in which the following layers are laminated adjacently in the stated order: a cathode, an electron injection layer, a buffer layer, a hole inhibition layer, an electron-transport layer, an emitting layer, a hole transport layer (if necessary), and a hole injection layer, and an anode.

Each of these layers may consist of one layer or two or more layers.

In the organic electroluminescence device of the present invention, known conductive materials can be suitably used as an anode and a cathode. Yet, at least one of them is preferably transparent for light extraction. Examples of known transparent conductive materials include ITO (tin-doped indium oxide), ATO (antimony-doped indium oxide), IZO (indium-doped zinc oxide), AZO (aluminum-doped zinc oxide), and FTO (fluorine-doped indium oxide). Examples of non-transparent conductive materials include calcium, magnesium, aluminum, tin, indium, copper, silver, gold, platinum, and alloys thereof.

The cathode is preferably ITO, IZO, or FTO among these examples.

The anode is preferably Au, Ag, or Al among these examples.

As described above, metals commonly used as an anode can be used as a cathode and an anode, so that a top emission structure in which light is to be extracted from the upper electrode can be readily achieved, and various types of the electrodes can be selected and used as lower and upper electrodes. For example, Al may be used as a lower electrode, and ITO may be used as an upper electrode.

The average thickness of the cathode is not particularly limited but is preferably 10 to 500 nm. It is more preferably 100 to 200 nm. The average thickness of the cathode can be measured with a probe-type step meter or a spectroscopic ellipsometer.

The average thickness of the anode is not particularly limited but is preferably 10 to 1000 nm. It is more preferably 30 to 150 nm. Even a non-transparent material can be used as an anode for the top emission type device and the transparent type device if the average thickness of the non-transparent material is about 10 to 30 nm.

The average thickness of the anode can be measured during film formation with a quartz crystal film thickness monitor.

The organic electroluminescence device of the present invention preferably includes a metal oxide layer between the anode and the cathode.

If the metal oxide layer is present between the anode and the cathode, the simply sealed organic electroluminescence device can provide a longer continuous operation life and better storage stability.

More preferably, the organic electroluminescence device includes a first metal oxide layer between the cathode and the emitting layer, and a second metal oxide layer between the anode and the emitting layer. One of the electron injection layers is preferably the first metal oxide layer described below.

As for the importance of the metal oxide layers, the first metal oxide layer is more important than the second metal oxide layer, and the second metal oxide layer can be replaced by an organic material having an extremely deep lowest unoccupied molecular orbital level (for example, HATCN).

The first metal oxide layer is a layer of a thin semiconductive or insulating film consisting of one single-metal oxide film, or a layer of thin semiconductive or insulating films consisting of a laminate and/or a mixture of single-metal oxides or multiple-metal oxides. The metal element constituting the metal oxide is selected from the group consisting of magnesium, calcium, strontium, barium, titanium, zirconium, hafnium, vanadium, niobium, tantalum, chromium, molybdenum, tungsten, manganese, indium, gallium, iron, cobalt, nickel, copper, zinc, cadmium, aluminum, and silicon. The layer consisting of a laminate or a mixture of metal oxides preferably includes a layer formed from at least one metal element selected from magnesium, aluminum, calcium, zirconium, hafnium, silicon, titanium, or zinc among the metal elements mentioned above. In the case of the layer consisting of single-metal oxides, the layer preferably includes a metal oxide selected from the group consisting of magnesium oxide, aluminum oxide, zirconium oxide, hafnium oxide, silicon oxide, titanium oxide, and zinc oxide.

Examples of the layer consisting of a laminate and/or a mixture of single-metal oxides or multiple-metal oxides include layers in which the following combinations of metal oxides are laminated and/or mixed: titanium oxide/zinc oxide, titanium oxide/magnesium oxide, titanium oxide/zirconium oxide, titanium oxide/aluminum oxide, titanium oxide/hafnium oxide, titanium oxide/silicon oxide, zinc oxide/magnesium oxide, zinc oxide/zirconium oxide, zinc oxide/hafnium oxide, zinc oxide/silicon oxide, calcium oxide/aluminum oxide, and the like. Examples thereof also include layers in which the following combinations of three kinds of metal oxides are laminated and/or mixed: titanium oxide/zinc oxide/magnesium oxide, titanium oxide/zinc oxide/zirconium oxide, titanium oxide/zinc oxide/aluminum oxide, titanium oxide/zinc oxide/hafnium oxide, titanium oxide/zinc oxide/silicon oxide, indium oxide/gallium oxide/zinc oxide, and the like. The above examples also include IGZO (an oxide semiconductor) and 12CaO7Al₂O₃ (an electride) which have special compositions and exhibit good properties.

In the present invention, those having a specific resistance of less than 10⁻⁴ Ωcm are classified as conductors and those having a specific resistance of not less than 10⁻⁴ cm are classified as semiconductors or insulators. Thus, thin films known as transparent electrodes such as ITO (tin-doped indium oxide), ATO (antimony-doped indium oxide), IZO (indium-doped zinc oxide), AZO (aluminum-doped zinc oxide), and FTO (fluorine-doped indium oxide), which are highly conductive, do not fall into the category of the semiconductor or insulator; and thus, these thin films do not meet the definition of a film constituting the first metal oxide layer of the present invention.

The second metal oxide layer may be formed from any metal oxide, and examples thereof include vanadium oxide (V₂O₅) molybdenum oxide (MoO₃), tungsten oxide (WO₃), and ruthenium oxide (RuO₂). These can be used alone or in combination of two or more thereof. Among these, vanadium oxide or molybdenum oxide is preferably used as the main component. Vanadium oxide or molybdenum oxide as the main component of the second metal oxide layer enhances the function of the second metal oxide layer as the hole injection layer for injecting holes from the anode to transport the holes to the emitting layer or to the hole transport layer. Another advantage is that vanadium oxide and molybdenum oxide inherently have high hole transportability so that they can suitably prevent a decrease in hole injection efficiency from the anode to the emitting layer or to the hole transport layer. More preferably, the second metal oxide layer is formed from vanadium oxide and/or molybdenum oxide.

The average thickness of the first metal oxide layer may range from about 1 nm to several micrometers. The average thickness is preferably 1 to 1000 nm for obtaining an organic electroluminescence device that can operate at low voltages. The average thickness is more preferably 2 to 100 nm.

The average thickness of the second metal oxide layer is not particularly limited but is preferably 1 to 1000 nm. The average thickness is more preferably 5 to 50 nm.

The average thickness of the first metal oxide layer can be measured with a probe-type step meter or a spectroscopic ellipsometer.

The average thickness of the second metal oxide layer can be measured with a quartz crystal film thickness monitor during film formation.

The organic electroluminescence device of the present invention preferably includes a buffer layer formed from a material containing an organic compound, between the metal oxide layer and the emitting layer. More preferably, the device includes a buffer layer formed by applying a solution containing an organic compound.

The functions of the buffer layer in the inverted organic EL include the followings: (1) while the energy level of the electron injected from the electrode is raised by the metal oxide layer, the buffer layer further raises the energy level of the electron to the energy level of the lowest unoccupied molecular orbital of an organic compound layer (e.g., emitting layer); and (2) the buffer layer protects the main organic EL material layer from the active metal oxide layer. As a means to accomplish the function (1), the buffer layer may be doped with a reducing agent or the buffer layer may be formed from a compound having a site with a dipole such as a nitrogen-containing substituent. The organic electroluminescence device having a buffer layer doped with a reducing agent is one preferred embodiment of the organic electroluminescence device. The organic electroluminescence device of the present invention is a simply sealed device, and the buffer layer needs to be atmospherically stable to allow the device to stably operate with such simple sealing conditions. Thus, in the case of using a buffer layer doped with a reducing agent, the buffer layer needs to be made thin film. In contrast, in the case of forming a buffer layer from a compound having a site with a dipole and having carrier transportability, the buffer does not necessarily need to be made thin.

In regard to the function (2), the metal oxide layer of the organic electroluminescence device is formed by a method such as a spray pyrolysis method, a sol-gel method, or a sputtering method as described later, and the surface of the layer is not smooth but is irregular. In the case where the emitting layer is formed on the metal oxide layer by a method such as a vacuum deposition, irregularities on the surface of the metal oxide layer may act as crystal nuclei, depending on a component used as a material of the emitting layer, which promotes crystallization of a material forming the emitting layer in contact with the metal oxide layer. As a result, a high leakage current will flow on the resulting organic electroluminescence device, resulting in non-uniform luminance of the light emitting surface. Thus, the device tends to have poor properties.

However, in the case where the buffer layer is formed, or more preferably, in the case the buffer layer is formed by applying a solution, a layer with a smooth surface can be formed, so that the buffer layer formed between the metal oxide layer and the emitting layer can suppress crystallization of a material forming the emitting layer. As a result, suppressed leakage current and uniform plane emission can be obtained even when a material that is easily crystallized is used for the emitting layer or the like in the organic electroluminescence device having a metal oxide layer.

The buffer layer preferably has an average thickness of 5 to 100 nm. With the average thickness in the above range, crystallization in the emitting layer can be sufficiently suppressed. A buffer layer having an average thickness of less than 5 nm cannot sufficiently smooth out irregularities on the metal oxide surface, resulting in an increase in leakage current and reducing the effect of the buffer layer. A buffer layer having an average thickness of more than 100 nm tends to result in a significant increase in the driving voltage. If the later-described compound having a preferred structure of the present invention is used as the organic compound, the buffer layer can sufficiently function also as the electron-transport layer. The average thickness of the buffer layer is more preferably 5 to 60 nm, still more preferably 10 to 60 nm. In view of continuous operation life of the organic electroluminescence device of the present invention, the average thickness of the buffer layer is yet still more preferably 10 to 30 nm.

As described above, in the case where the buffer layer is doped with a reducing agent, the buffer layer is preferably made thin in view of atmospheric stability of the device. In this case, a preferred average thickness of the buffer layer is associated with the amount of the reducing agent in the material containing an organic compound forming the buffer layer. In the case where the amount of the reducing agent in the material is 0.1 to 15% by mass relative to the amount of the organic compound, the average thickness of the buffer layer is preferably 5 to 30 nm. In contrast, in the case where the material is not doped with a reducing agent or is doped with a very small amount of a reducing agent (for example, the amount of the reducing agent relative to the organic compound is 0 to 0.1% by mass in the material), the buffer layer tends to maintain good atmospheric stability even if the buffer layer is made thicker.

In this case, for example, the buffer layer preferably has an average thickness of 5 to 60 nm. The buffer layer is preferably thick in terms of process stability in the production of the device and device stability.

Specifically, the followings are also preferred embodiments of the present invention: (1) an organic electroluminescence device including a buffer layer formed from a material containing an organic compound, wherein the material containing the organic compound contains 0.1 to 15% by mass of a reducing agent relative to the amount of the organic compound, and the buffer layer has an average thickness of 5 to 30 nm; and (2) an organic electroluminescence device including a buffer layer formed from a material containing an organic compound, wherein the material containing the organic compound contains 0 to 0.1% by mass of a reducing agent relative to the organic compound, and the buffer layer has an average thickness of 5 to 60 nm.

The average thickness of the buffer layer can be measured with a probe-type step meter or a spectroscopic ellipsometer.

In the organic electroluminescence device of the present invention, a material forming the emitting layer may be a low-molecular compound, a high-molecular compound, or a mixture thereof.

The term “low-molecular material” as used herein refers to a material that is not a high-molecular material (polymer), and does not necessarily refer to a low molecular weight organic compound.

Examples of the high-molecular material of the emitting layer include polyacetylene-based compounds such as trans-polyacetylene, cis-polyacetylene, poly(di-phenylacetylene) (PDPA), and poly(alkyl,phenylacetylene) (PAPA); polyparaphenylenevinylene-based compounds such as poly(para-phenylenevinylene) (PPV), poly(2,5-dialkoxy-para-phenylenevinylene) (RO-PPV), cyano-substituted-poly(para-phenylenevinylene) (CN-PPV), poly(2-dimethyloctylsilyl-para-phenylenevinylene) (DMOS-PPV), and poly(2-methoxy,5-(2′-ethylhexoxy)-para-phenylenevinylene) (MEH-PPV); polythiophene-based compounds such as poly(3-alkylthiophene) (PAT) and poly(oxypropylene)triol (POPT); polyfluorene-based compounds such as poly(9,9-dialkylfluorene) (PDAF), poly(dioctylfluorene-alt-benzothiadiazole) (F8BT), α,ω-bis[N,N′-di(methylphenyl)aminophenyl]-poly[9,9-bis(2-ethylhexyl)fluorene-2,7-diyl] (PF2/6am4), and poly(9,9-dioctyl-2,7-divinylenefluorenyl-ortho-co(anthracene-9,10-diyl); polyparaphenylene-based compounds such as poly(para-phenylene) (PPP) and poly(1,5-dialkoxy-para-phenylene) (RO-PPP); polycarbazole-based compounds such as poly(N-vinylcarbazole) (PVK); polysilane-based compounds such as poly(methylphenylsilane) (PMPS), poly(naphthylphenylsilane) (PNPS), and poly(biphenylphenylsilane) (PBPS); and a boron compound-based polymer materials disclosed in Japanese Patent Application No. 2010-230995 and Japanese Patent Application No. 2011-6457.

Examples of the low-molecular material of the emitting layer include, in addition to metal complexes that function as host materials and phosphorescent materials, which are described later, various metal complexes such as 8-hydroxyquinoline aluminum (Alq₃), tris(4-methyl-8-quinolinolate)aluminum(III) (Almq₃), 8-hydroxyquinoline zinc (Znq₂), (1,10-phenanthroline)-tris-(4,4,4-trifluoro-1-(2-thienyl)-butane-1,3-dionate) europium(III) (Eu(TTA)₃(phen)), and 2,3,7,8,12,13,17,18-octaethyl-21H,23H-porphin platinum(II); benzene-based compounds such as distyrylbenzene (DSB) and diaminodistyrylbenzene (DADSB); naphthalene-based compounds such as naphthalene and Nile red; phenanthrene-based compounds such as phenanthrene; chrysene-based compounds such as chrysene and 6-nitrochrysene; perylene-based compounds such as perylene and N,N′-bis(2,5-di-t-butylphenyl)-3,4,9,10-perylene-di-carboxy imide (BPPC); coronene-based compounds such as coronene; anthracene-based compounds such as anthracene and bisstyrylanthracene; pyrene-based compounds such as pyrene; pyran-based compounds such as 4-(di-cyanomethylene)-2-methyl-6-(para-dimethylaminostyryl)-4H-pyran (DCM); acridine-based compounds such as acridine; stilbene-based compounds such as stilbene; carbazole-based compounds such as 4,4′-bis[9-dicarbazolyl]-2,2′-biphenyl (CBP) and 4,4′-bis(9-ethyl-3-carbazovinylene)-1,1′-biphenyl (BCzVBi); thiophene-based compounds such as 2,5-dibenzooxazolethiophene; benzooxazole-based compounds such as benzooxazole; benzimidazole-based compounds such as benzoimidazole; benzothiazole-based compounds such as 2,2′-(para-phenylenedivinylene)-bisbenzothiazole; butadiene-based compounds such as bistyryl(1,4-diphenyl-1,3-butadiene) and tetraphenylbutadiene; naphthalimide-based compounds such as naphthalimide; coumarin-based compounds such as coumarin; perynone-based compounds such as perynone; oxadiazole-based compounds such as oxadiazole; aldazine-based compounds; cyclopentadiene-based compounds such as 1,2,3,4,5-pentaphenyl-1,3-cyclopentadiene (PPCP); quinacridone-based compounds such as quinacridone and quinacridone red; pyridine-based compounds such as pyrrolopyridine and thiadiazolopyridine; Spiro compounds such as 2,2′,7,7′-tetraphenyl-9,9′-spirobifluorene; metallic or non-metallic phthalocyanine-based compounds such as phthalocyanine (H₂Pc) and copper phthalocyanine; and boron compound materials disclosed in JP-A 2009-155325 and Japanese Patent Application No. 2010-28273. These examples can be used alone or in combination of two or more thereof.

The organic electroluminescence device of the present invention can use any of the high-molecular compounds or the low-molecular compounds mentioned above as a material of the emitting layer. Yet, the emitting layer preferably contains one metal complex that functions as a host in which a light-emitting material (i.e., a low-molecular compound) as a guest is dispersed. Owing to such an emitting layer containing a combination of a host and a guest which are both low-molecular compounds, the organic electroluminescence device can have excellent luminescence properties such as luminous efficiency and operation life. The reason is that use of a certain metal complex as a host material achieves extremely rapid energy transfer between the host and the guest and can reduce the time in which a carrier (electron) is placed in a high energy state. Thus, the host material is required to have physical properties that can bring the energy gap between singlet and triplet energy levels to as close to zero as possible. This achieves rapid energy transfer and better atmospheric stability. This is described in more detail below.

The host of the emitting layer transfers energy and electrons between the host and the guest to bring the guest into an excited state, and the excitation energy of the host that transfers energy and electrons between the host and the guest is preferably higher than the excitation energy of the guest. The metal complex used as a host of the emitting layer is not limited as long as it is an electrically conductive and amorphous material that can have above mentioned energy level compared to that of the light emitting material used as a host. Examples of the metal complex used as a host include a metal complex represented by formula (1):

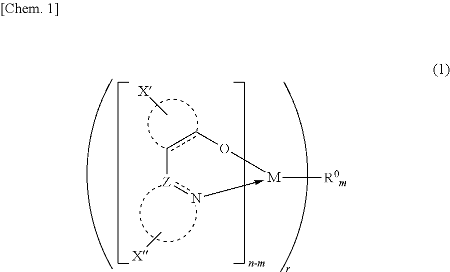

(in formula (1), dotted arcs indicate that ring structures are formed with a portion of the backbone connecting an oxygen atom and a nitrogen atom, and a ring structure formed with Z and the nitrogen atom is a heterocyclic structure; X′ and X″, which are the same or different, each represent a hydrogen atom or a monovalent substituent as a substituent in a ring structure, and a plurality of such substituents may be bonded to the ring structures forming the dotted arc portions; X′ and X″ may be bonded together to form a new ring structure with a portion of the two ring structures represented by dotted arcs; each dotted line in the backbone connecting the oxygen atom and the nitrogen atom represents two atoms connected by the dotted line are bonded by a single bond or a double bond; M represents a metal atom; Z represents a carbon atom or a nitrogen atom; an arrow from the nitrogen atom to M indicates that the nitrogen atom is coordinated to the M atom; R⁰ represents a monovalent substituent or a divalent linking group; m represents the number of R⁰ and is an integer of 0 or 1; n represents the valence of the metal atom M; and r is an integer of 1 or 2);
a metal complex represented by formula (2) below:

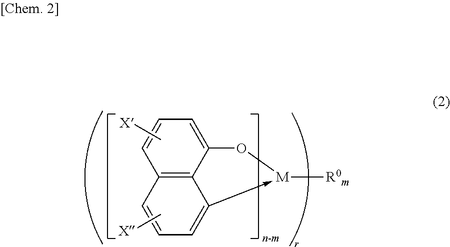

(in formula (2), X′ and X″, which are the same or different, each represent a hydrogen atom or a monovalent substituent as a substituent in a quinoline ring structure, and a plurality of such substituents may be bonded to the quinoline ring structure; M represents a metal atom; an arrow from the nitrogen atom to M indicates that the nitrogen atom is coordinated to the M atom; R⁰ represents a monovalent substituent or a divalent linking group; m represents the number of R⁰ and is an integer of 0 or 1; n represents the valence of the metal atom M; and r is an integer of 1 or 2); and
a metal complex represented by formula (3) below:

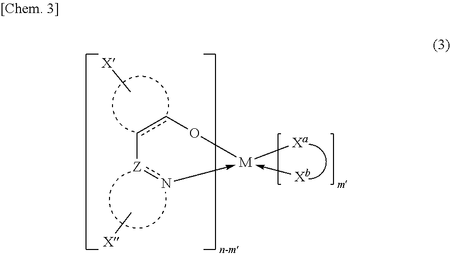

(in formula (3), dotted arcs indicate that ring structures are formed with a portion of the backbone connecting an oxygen atom and a nitrogen atom, and a ring structure formed with Z and the nitrogen atom is a heterocyclic structure; X′ and X″, which are the same or different, each represent a hydrogen atom or a monovalent substituent as a substituent in a ring structure, and a plurality of such substituents may be bonded to the ring structures forming the dotted arc portions; X′ and X″ may be bonded together to form a new ring structure with a portion of the two ring structures represented by dotted arcs; each dotted line in the backbone connecting the oxygen atom and the nitrogen atom represents two atoms connected by the dotted line are bonded by a single bond or a double bond; M represents a metal atom; Z represents a carbon atom or a nitrogen atom; an arrow from the nitrogen atom to M indicates that the nitrogen atom is coordinated to the M atom; n represents the valence of the metal atom M; and a solid arc connecting X^{a} and X^{b} represents a bond between X^{a} and X^{b} via at least one other atom, and the atom together with X^{a} and X^{b} may form a ring structure; the bond between X^{a} and X^{b} via at least one other atom may include a coordinate bond; X^{a} and X^{b}, which are the same or different, each represent an oxygen atom, a nitrogen atom, or a carbon atom; an arrow from X^{b} to M indicates that X^{b} is coordinated to the M atom; and m′ is an integer of 1 to 3). These can be used alone or in combination of two or more thereof.

The metal complex represented by formula (1) above wherein r is 1 is a metal complex represented by formula (4-1) below having one M atom in the structure; and the metal complex represented by formula (1) wherein r is 2 is a metal complex represented by formula (4-2) below having two M atoms in the structure.

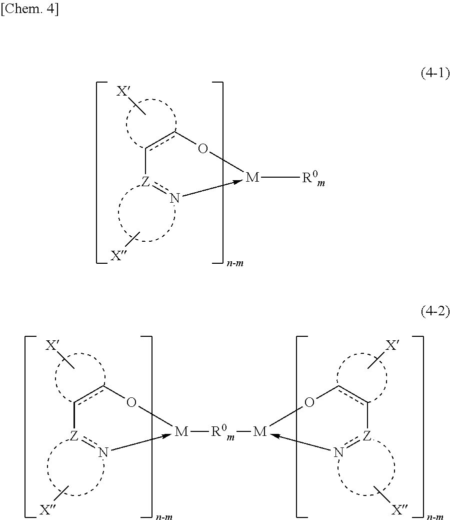

The ring structures represented by dotted arcs in formulae (1) and (3) may each consist of one ring or two or more rings. Examples of the ring structures include C2-20 aromatic rings and heterocyclic rings. Examples of aromatic rings include a benzene ring, a naphthalene ring, and an anthracene ring; and examples of heterocyclic rings include a diazole ring, a thiazole ring, an isothiazole ring, an oxazole ring, an isoxazole ring, a thiadiazole ring, an oxadiazole ring, a triazole ring, an imidazole ring, an imidazoline ring, a pyridine ring, a pyrazine ring, a pyridazine ring, a pyrimidine ring, a diazine ring, a triazine ring, a benzimidazole ring, a benzothiazole ring, a benzoxazole ring, and a benzotriazole ring.

Preferred among these are a benzene ring, a thiazole ring, an isothiazole ring, an oxazole ring, an isoxazole ring, a thiadiazole ring, an oxadiazole ring, a triazole ring, an imidazole ring, an imidazoline ring, a pyridine ring, a pyridazine ring, a pyrimidine ring, a benzimidazole ring, a benzothiazole ring, a benzoxazole ring, and a benzotriazole ring.

In the ring structures in formulae (1) to (3), examples of the substituents represented by X′ and X″ include halogen atoms and groups such as C1-20 (preferably C1-10) alkyl groups; C1-20 (preferably C1-10) aralkyl groups; C1-20 (preferably C1-10) alkenyl groups; C1-20 (preferably C1-10) aryl, arylamino, cyano, amino and acyl groups; C1-20 (preferably C1-10) alkoxycarbonyl and carboxyl groups; C1-20 (preferably C1-10) alkoxy groups; C1-20 (preferably C1-10) alkylamino groups; C1-20 (preferably C1-10) dialkylamino groups; C1-20 (preferably C1-10) aralkylamino groups; C1-20 (preferably C1-10) haloalkyl, hydroxy, aryloxy, and carbazole groups.

If the substituent represented by X′ or X″ in the ring structure is an aryl group or an arylamino group, the aromatic ring in the aryl group or the arylamino group may further be substituted. In this case, examples of the substituent include the same specific examples of the substituents represented by X′ and X″.

If the substituents in the two ring structures represented by dotted arcs in formulae (1) and (3) are bonded together to forma new ring structure with a portion of the two ring structures represented by dotted arcs, examples of the new ring structure include a five-membered ring structure and a six-membered ring structure, and examples of a ring structure in which the two ring structures represented by dotted arcs are combined with the new ring structure include structures represented by formulae (5-1) and (5-2) below:

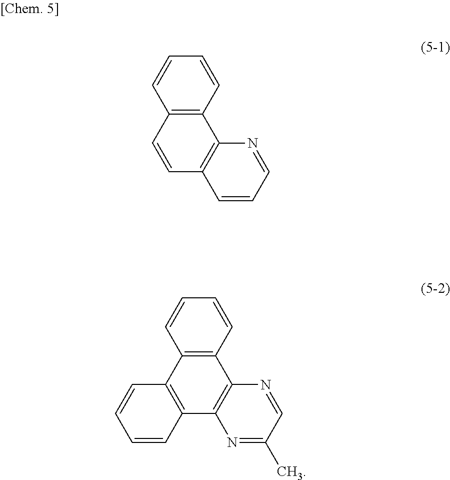 [SMILES: c1ccc2c(c1)ccc1cccnc12 ; Cc1cnc2c3ccccc3c3ccccc3c2n1]

In formulae (1) to (3), preferred examples of the metal atom represented by M include metal atoms in Groups 1 to 3, 9, 10, 12, and 13 of the periodic table. Among these, any of zinc, aluminum, gallium, platinum, rhodium, iridium, beryllium, and magnesium is preferred.

In formulae (1) and (2), if R⁰ is a monovalent substituent, the monovalent substituent is preferably any of those represented by formulae (6-1) to (6-3) below:

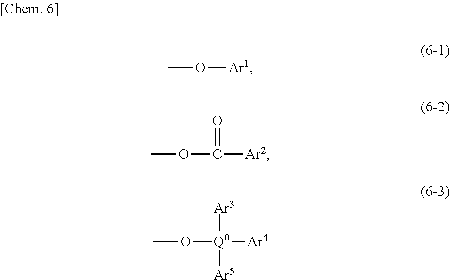

(in the formulae, Ar¹ to Ar⁵ each represent an optionally substituted aromatic ring, a heterocyclic ring, or a structure in which two or more aromatic rings or heterocyclic rings are directly bonded together, and Ar³ to Ar⁵ may have the same structure or different structures; and Q⁰ represents a silicon atom or a germanium atom).

Specific examples of the aromatic rings or the heterocyclic rings represented by Ar¹ to Ar⁵ include the same specific examples of the aromatic ring or the heterocyclic ring of the ring structures represented by dotted arcs in formula (1). Examples of the structure in which two or more aromatic rings or heterocyclic rings are directly bonded together include a structure in which two or more ring structures mentioned as specific examples of the aromatic ring or the heterocyclic ring are directly bonded together. In this case, two or more aromatic rings or heterocyclic rings that are directly bonded together may have the same ring structure or different ring structures.

Specific examples of a substituent in the aromatic ring or the heterocyclic ring include the same specific examples of the substituent in the aromatic ring or the heterocyclic ring of the ring structures represented by dotted arcs in formula (1).

In addition, in formulae (1) and (2), if R⁰ is a divalent linking group, R⁰ is preferably —O— or —CO—.

In formula (3), the structure formed by X^{a}, X^{b}, and the solid arc connecting X^{a} and X^{b} may include one or more ring structures. The ring structure may contain X^{a} and X^{b}. In this case, examples of the ring structure include the same ring structures represented by dotted arcs in formulae (1) and (3) and a pyrazole ring. A preferred structure is a pyrazole ring formed with X^{a} and X^{b}.

In formula (3), the solid arc connecting X^{a} and X^{b} may consist of only carbon atoms or contain other atoms. Examples of other atoms include a boron atom, a nitrogen atom, and a sulfur atom.

In addition, the solid arc connecting X^{a} and X^{b} may contain one or more ring structures other than the ring structure formed with X^{a} and X^{b}. In this case, examples of the ring structure include the same ring structures represented by dotted arcs in formulae (1) and (3) and a pyrazole ring.

Examples of the structure represented by formula (3) include a structure represented by formula (7) below:

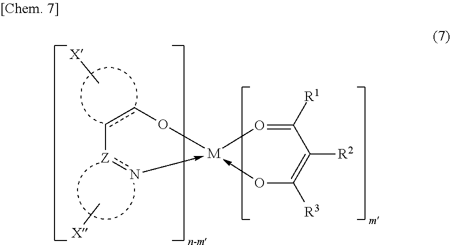

(in formula (7), R¹ to R³, which are the same or different, each represent a hydrogen atom or a monovalent substituent; an arrow from a nitrogen atom to M and an arrow from an oxygen atom to M indicate that the nitrogen atom and the oxygen atom are coordinated to the M atom; and dotted arcs, dotted lines in the backbone connecting the oxygen atom and the nitrogen atom, X′, X″, M, Z, n, and m′ are as defined above for formula (3)).

Examples of the monovalent substituents represented by R¹ to R³ in formula (7) include the same substituents represented by X′ and X″ in the ring structures in formulae (1) to (3).

Specific examples of compounds represented by formula (1) include those having structures represented by formulae (8-1) to (8-40) below:

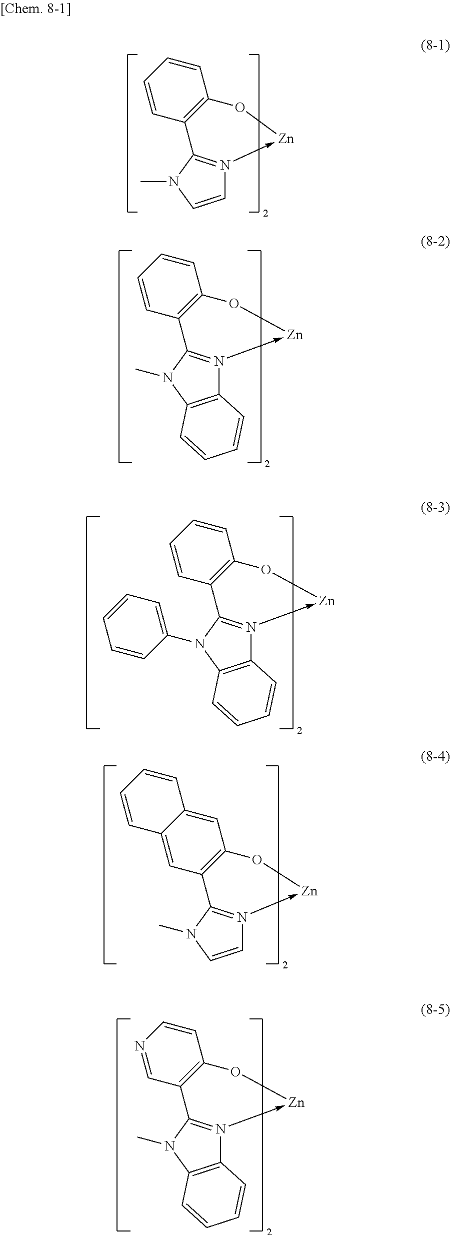

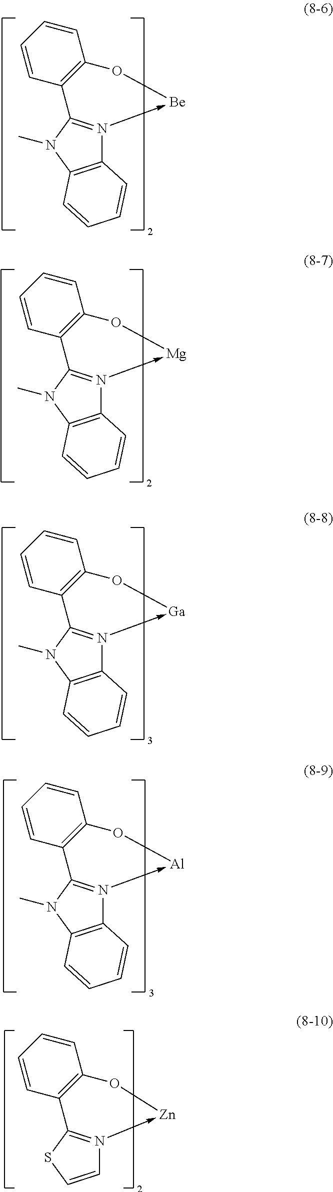

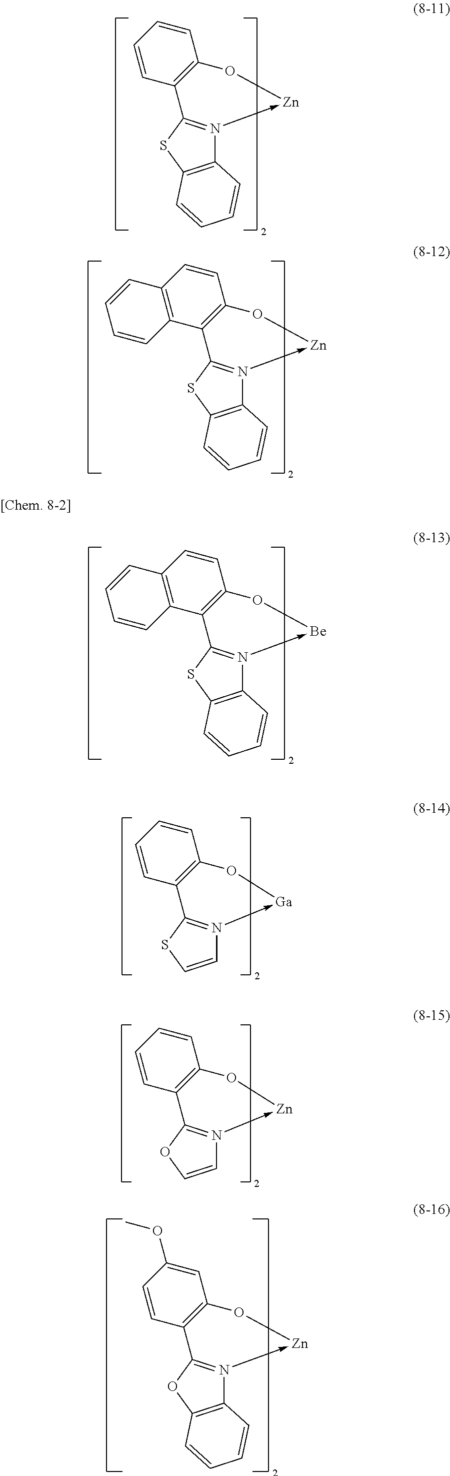

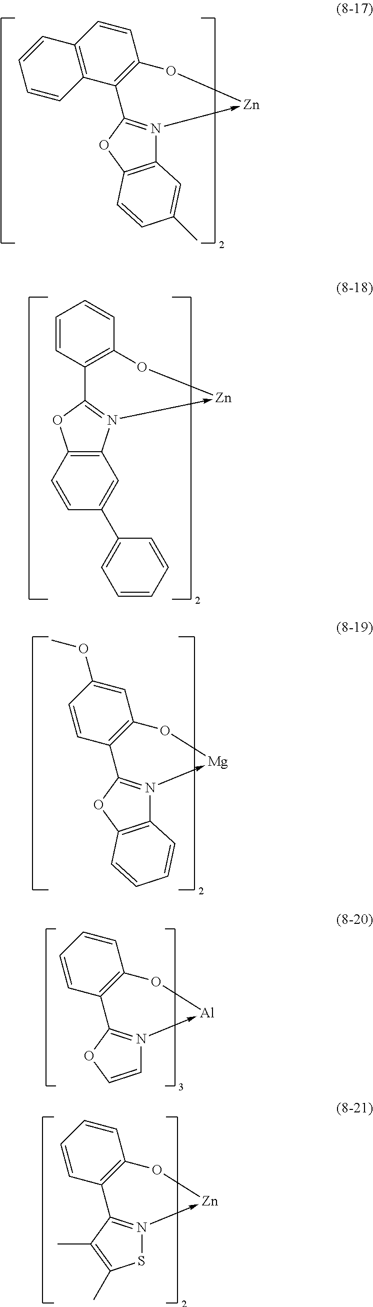

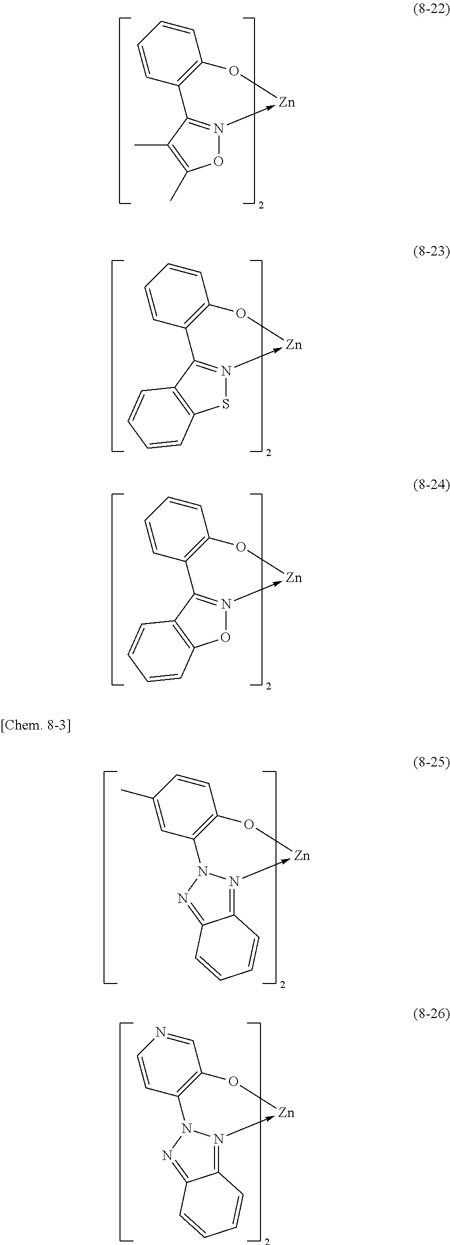

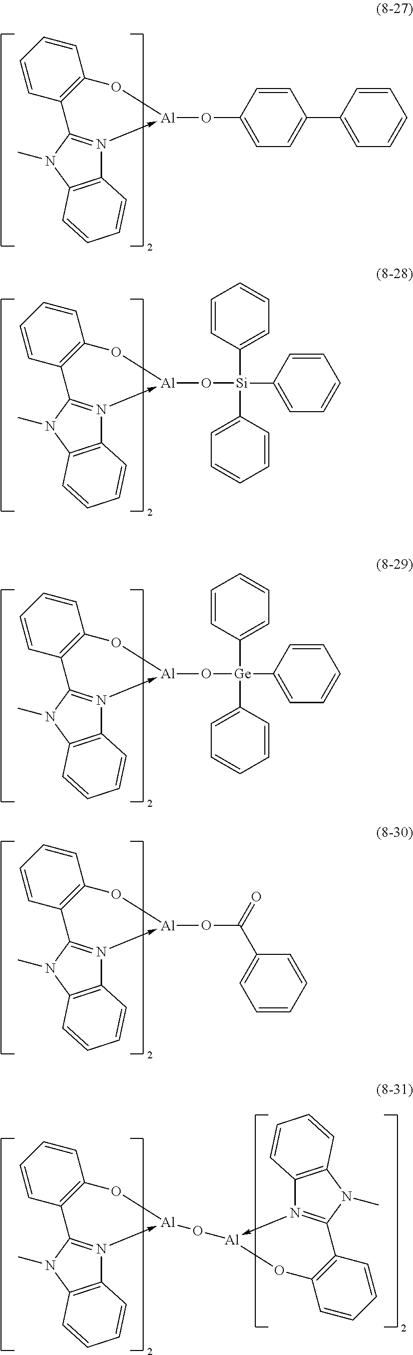

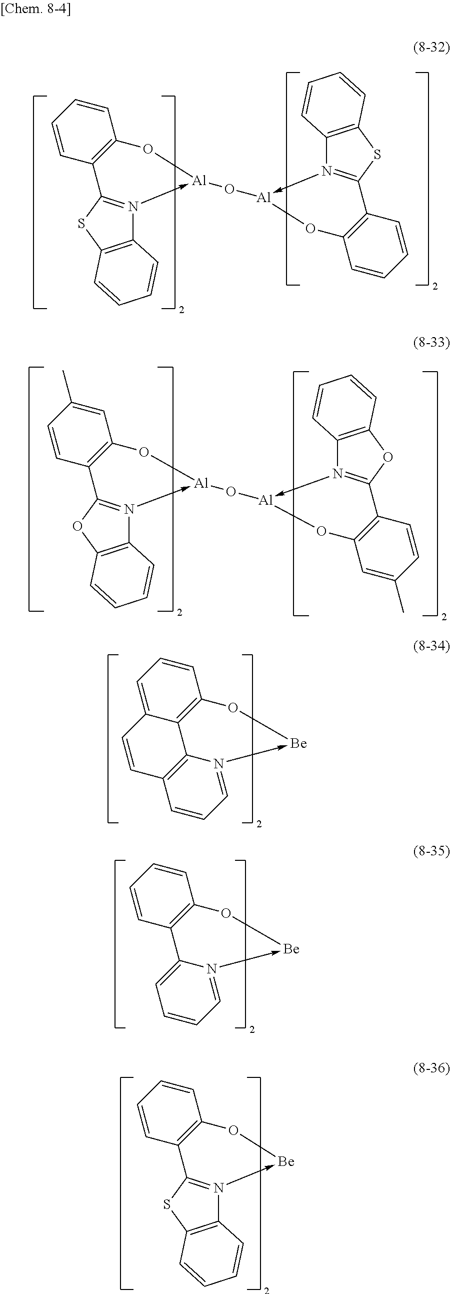

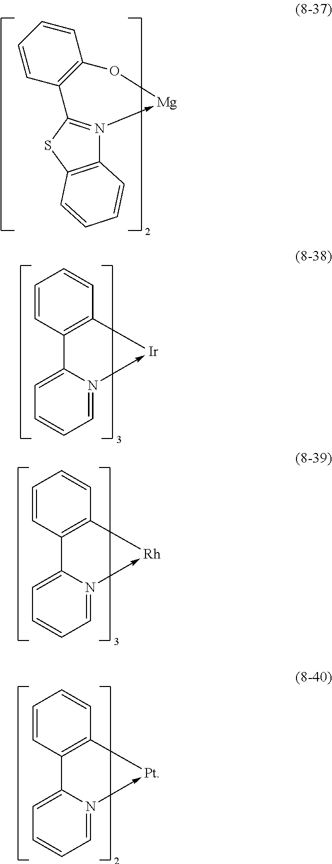

Specific examples of the compounds represented by formula (2) include those having structures represented by formulae (9-1) to (9-3) below:

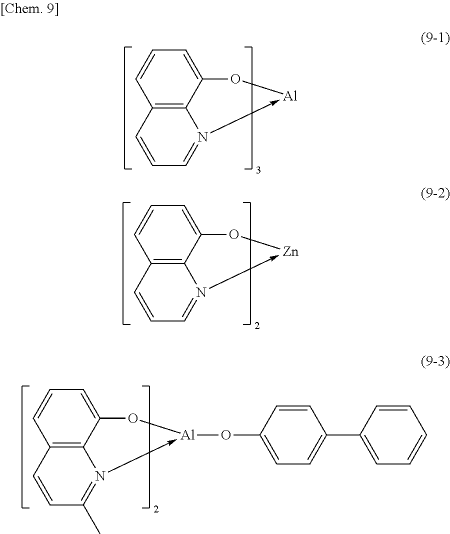

Specific examples of compounds represented by formula (3) include those having structures represented by formulae (10-1) to (10-8) below:

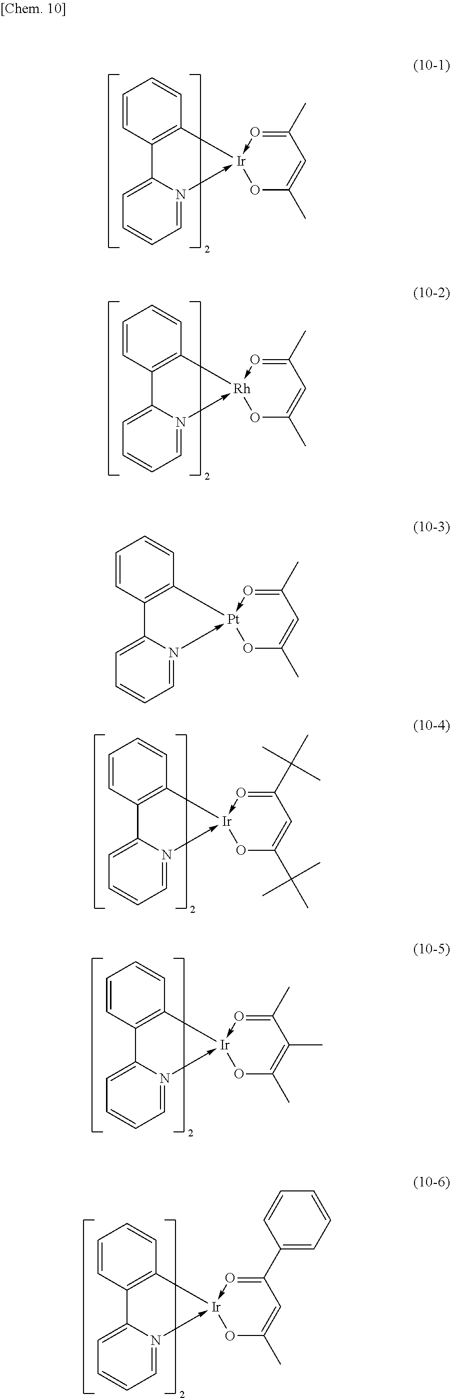

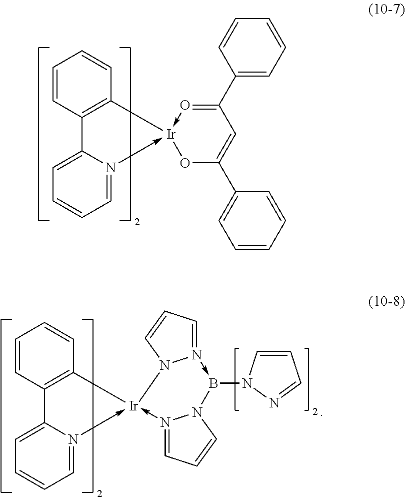

The metal complex used in the present invention may be one or a combination of two or more of those mentioned above. Preferred among these are bis[2-(2-benzothiazolyl)phenolato]zinc represented by formula (8-11), bis(10-hydroxybenzo[h]quinolinate)beryllium (Bebq₂) represented by formula (8-34), and bis[2-(2-hydroxyphenyl)-pyridine]beryllium (Bepp₂) represented by formula (8-35).

The emitting layer in the organic electroluminescence device of the present invention preferably contains a phosphorescent material. The presence of the phosphorescent material as a guest improves the luminous efficiency and operation life of the organic electroluminescence device of the present invention.

The phosphorescent material is preferably either a compound represented by formula (11) or a compound represented by (12) below:

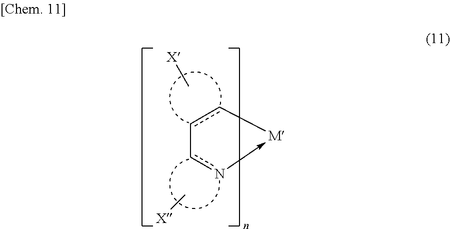

(in formula (11), dotted arcs indicate that ring structures are formed with a portion of the backbone consisting of an oxygen atom and three carbon atoms, and a ring structure formed with a nitrogen atom is a heterocyclic structure; X′ and X″, which are the same or different, each represent a hydrogen atom or a monovalent substituent as a substituent in a ring structure, and a plurality of such substituents may be bonded to the ring structures forming the dotted arc portions; X′ and X″ may be bonded together to form a new ring structure with a portion of the two ring structures represented by dotted arcs; when n is 2 or more, a plurality of X′'s may be bonded together to form one substituent or a plurality of X″'s may be bonded together to form one substituent; each dotted line in the backbone consisting of the nitrogen atom and three carbon atoms represents two atoms connected by the dotted line are bonded by a single bond or a double bond; M′ represents a metal atom; an arrow from the nitrogen atom to M′ indicates that the nitrogen atom is coordinated to the M′ atom; and n represents the valence of the metal atom M′); or

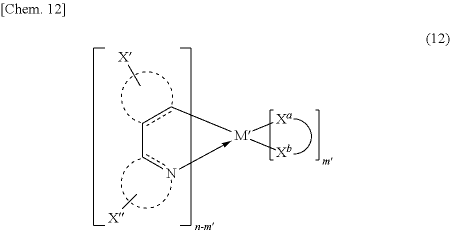

(in formula (12), dotted arcs indicate that ring structures are formed with a portion of the backbone consisting of an oxygen atom and three carbon atoms, and a ring structure formed with a nitrogen atom is a heterocyclic structure; X′ and X″, which are the same or different, each represent a hydrogen atom or a monovalent substituent as a substituent in a ring structure, and a plurality of such substituents may be bonded to the ring structures forming the dotted arc portions; X′ and X″ may be bonded together to forma new ring structure with a portion of the two ring structures represented by dotted arcs; each dotted line in the backbone consisting of the nitrogen atom and three carbon atoms represents two atoms connected by the dotted line are bonded by a single bond or a double bond; M′ represents a metal atom; an arrow from the nitrogen atom to M′ indicates that the nitrogen atom is coordinated to the M′ atom; n represents the valence of the metal atom M′; a solid arc connecting X^{a} and X^{b} represents a bond between X^{a} and X^{b} via at least one other atom, and the atom together with X^{a} and X^{b} may form a ring structure; X^{a} and X^{b}, which are the same or different, each represent an oxygen atom, a nitrogen atom, or a carbon atom; an arrow from X^{b} to M′ indicates that X^{b} is coordinated to the M′ atom; and m′ is an integer of 1 to 3).

Examples of the ring structures represented by dotted arcs in formulae (11) and (12) include C2-20 aromatic rings and heterocyclic rings. Examples of aromatic hydrocarbon rings include a benzene ring, a naphthalene ring, and a anthracene ring; and examples of heterocyclic rings include a pyridine ring, a pyrimidine ring, a pyrazine ring, a triazine ring, a benzothiazole ring, a benzothiol ring, a benzoxazole ring, a benzoxazole ring, a benzimidazole ring, a quinoline ring, an isoquinoline ring, a quinoxaline ring, a phenanthridine ring, a thiophene ring, a furan ring, a benzothiophene ring, and a benzofuran ring.

Examples of substituents represented by X′ and X″ in formulae (11) and (12) include the same substituents represented by X′ and X″ in formula (1).

In formulae (11) and (12), if the substituents in the two ring structures represented by dotted arcs are bonded together to form a new ring structure with a portion of the two ring structures represented by dotted arcs, examples of a ring structure in which the two ring structures represented by dotted arcs are combined with the new ring structure include structures represented by formulae (5-1) and (5-2).

Examples of the metal atom represented by M′ in formulae (11) and (12) include ruthenium, rhodium, palladium, silver, rhenium, osmium, iridium, platinum, and gold.

Examples of the structure represented by formula (12) include those represented by formulae (13-1) and (13-2) below:

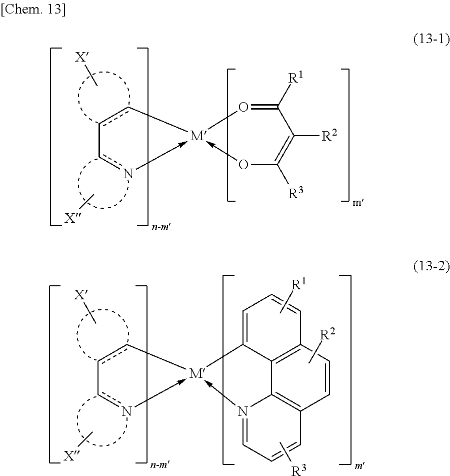

(in formulae (13-1) and (13-2), R¹ to R³, which are the same or different, each represent a hydrogen atom or a monovalent substituent; in formula (13-2), if R¹ to R³ are monovalent substituents, the ring structure may further be substituted with a plurality of monovalent substituents; an arrow from a nitrogen atom to M′ and an arrow from an oxygen atom to M′ indicate that the nitrogen atom and the oxygen atom are coordinated to the M′ atom; and dotted arcs, dotted lines in the backbone connecting the nitrogen atom and three carbon atoms, X′, X″, M′, n, and m′ are as defined above for formula (12)).

Examples of the monovalent substituents represented by R¹ to R³ include the same substituents represented by X′ and X″ in the ring structures in formulae (1) to (3).

Specific examples of compounds represented by formulae (11) and (12) include those represented by formulae (14-1) to (14-30) below:

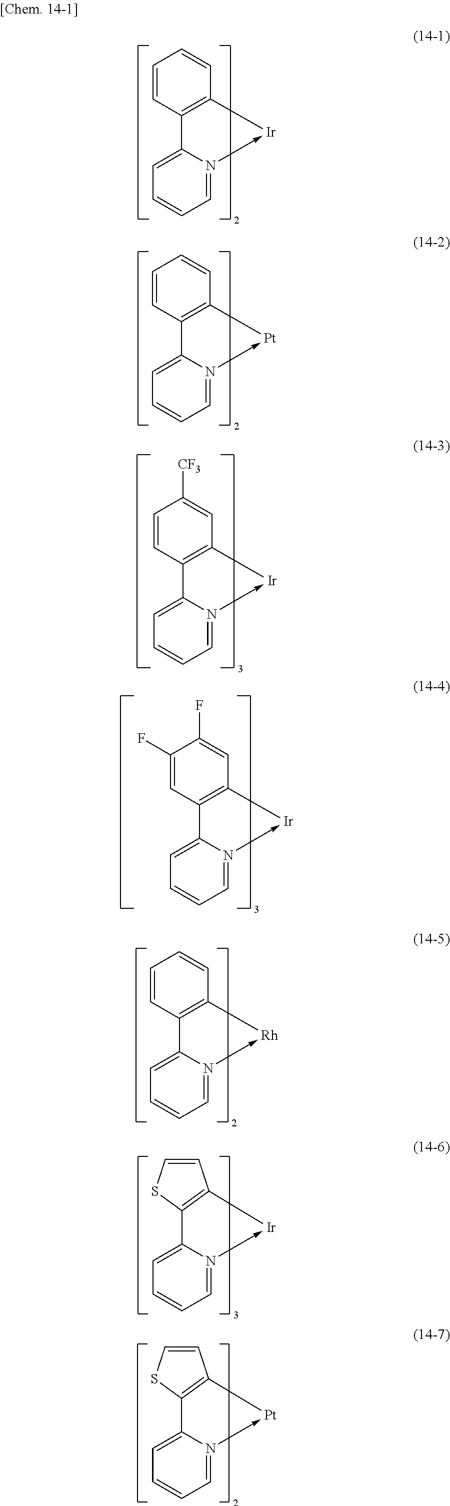

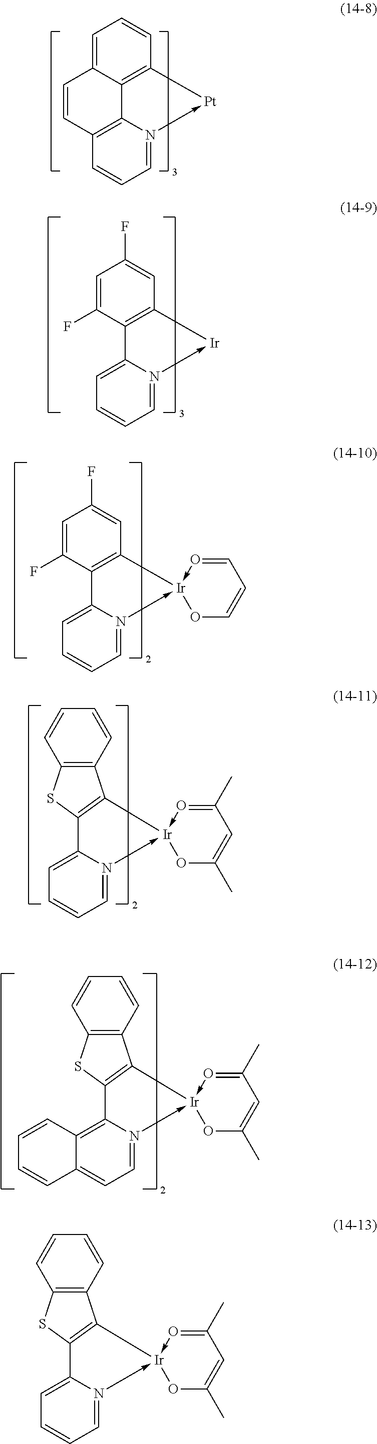

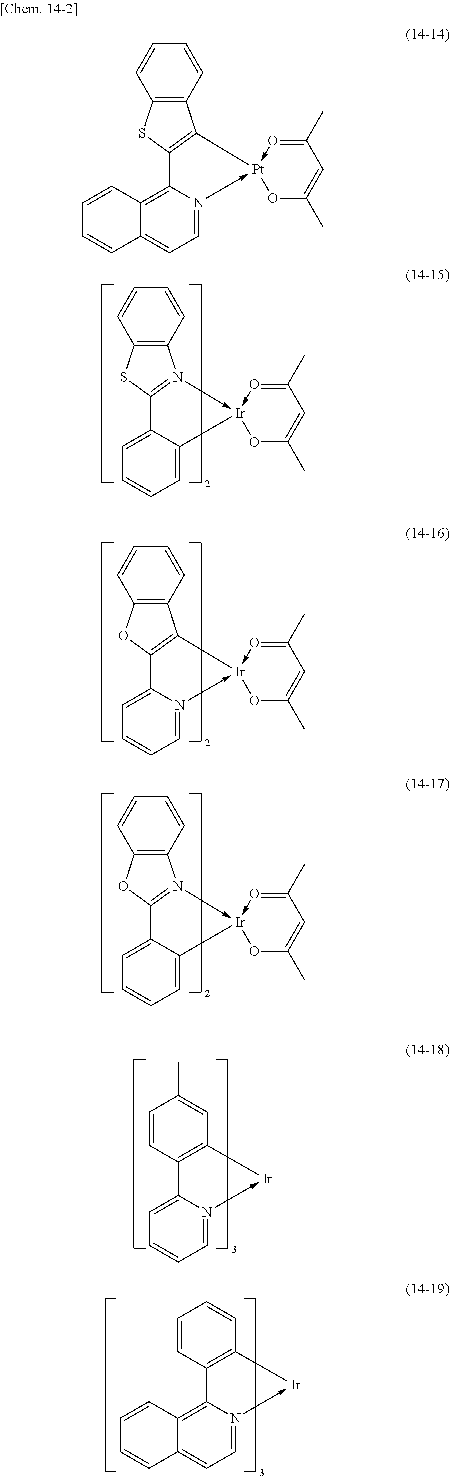

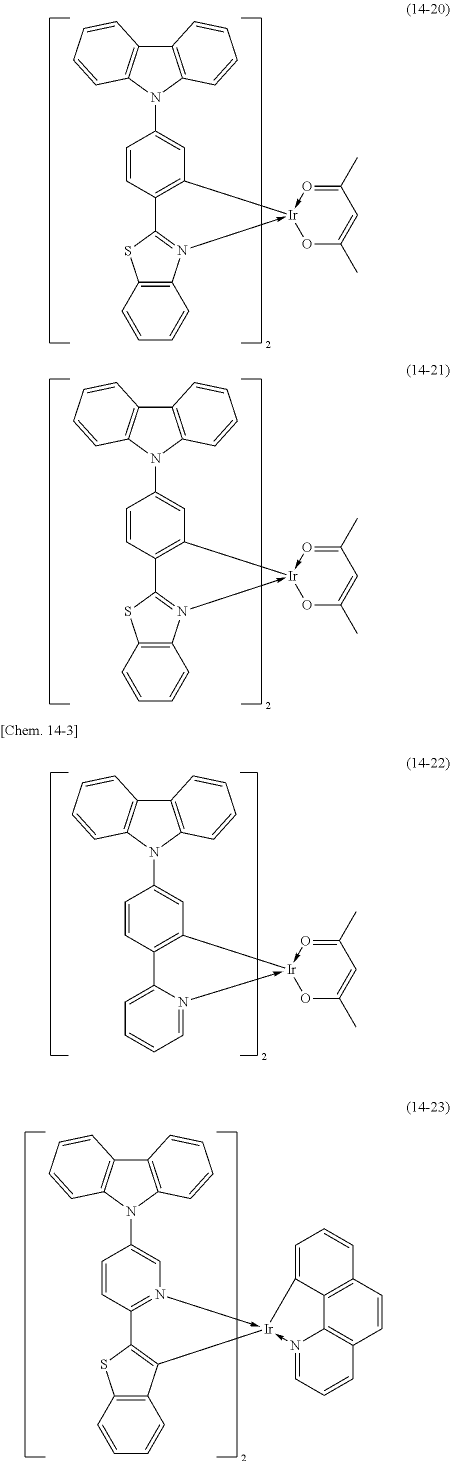

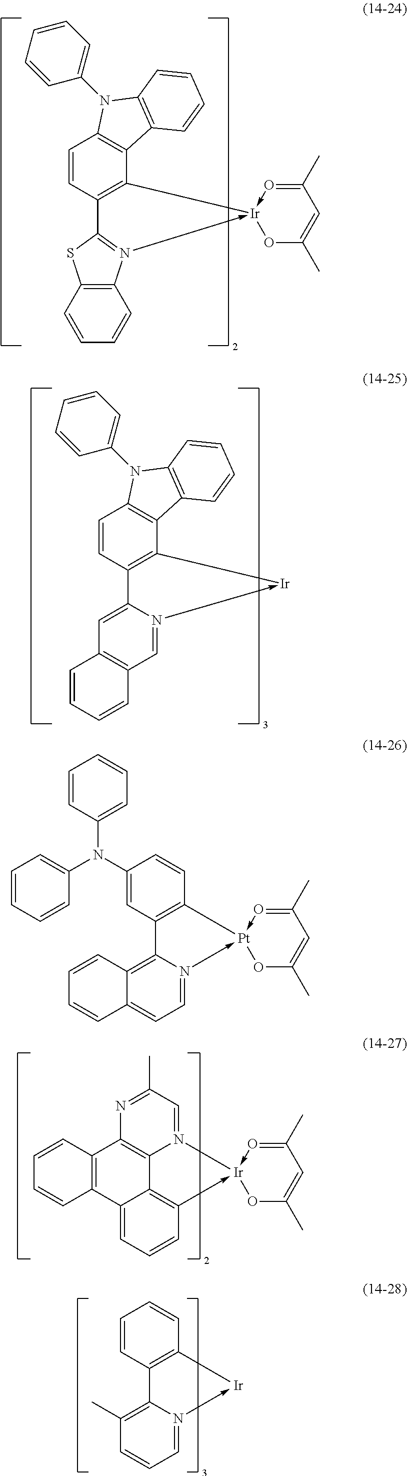

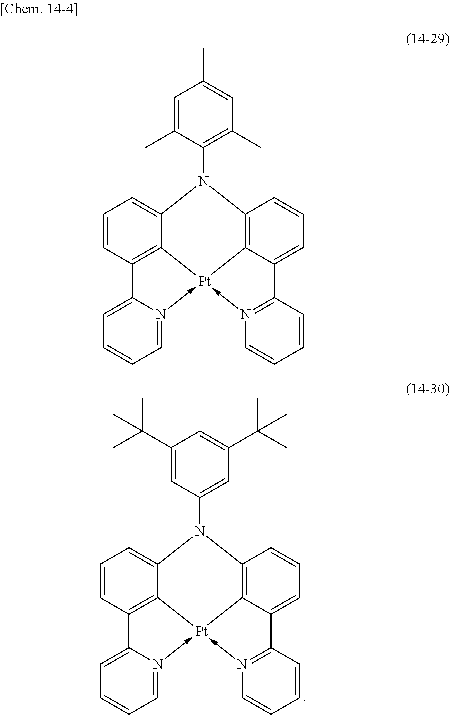

The phosphorescent material used in the present invention may be one or a combination of two or more of those mentioned above. Preferred among these are iridium tris(2-phenylpyridine) (Ir(ppy)₃) represented by formula (14-1), iridium tris(1-phenylisoquinoline) (Ir(piq)₃) represented by formula (14-19), iridium bis(2-methylbenzo-[f,h]quinoxaline) (acetylacetonate) (Ir(MDQ)₂(acac)) represented by formula (14-27), and iridium tris[3-methyl-2-phenylpyridine](Ir(mpy)₃) represented by formula (14-28).

The amount of the phosphorescent material in the emitting layer is preferably 0.5 to 20% by mass relative to 100% by mass of the material forming the emitting layer. With the amount in this range, it is possible to improve the luminescence properties. The amount is more preferably 0.5 to 10% by mass, still more preferably 1 to 6% by mass.

The average thickness of the emitting layer is not particularly limited but is preferably 10 to 150 nm. It is more preferably 20 to 100 nm.

The average thickness of the emitting layer can be measured with a quartz crystal film thickness monitor in the case of a low-molecular compound, or with a contact-type step meter in the case of a polymer compound.

The material of the hole transport layer can be any compound that can be usually used as a material of a hole transport layer. Various p-type polymer materials or various p-type low-molecular materials can be used alone or in combination.

Examples of p-type high-molecular materials (organic polymers) include polyarylamine, fluorene-arylamine copolymer, fluorene-bithiophene copolymer, poly(N-vinylcarbazole), polyvinylpyrene, polyvinylanthracene, polythiophene, polyalkylthiophene, polyhexylthiophene, poly(p-phenylenevinylene), polythienylenevinylene, pyrene-formaldehyde resin, ethylcarbazole-formaldehyde resin, and derivatives thereof.

Each of these compounds can be used as a mixture with other compounds. For example, a mixture containing polythiophene may be exemplified by poly(3,4-ethylenedioxythiophene/styrenesulfonate) (PEDOT/PSS).

Examples of the p-type low-molecular materials include arylcycloalkane-based compounds such as 1,1-bis(4-di-para-triaminophenyl)cyclohexane and 1,1′-bis(4-di-para-tolylaminophenyl)-4-phenyl-cyclohexane; arylamine-based compounds such as 4,4′,4″-trimethyltriphenylamine, N,N,N′,N′-tetraphenyl-1,1′-biphenyl-4,4′-diamine, N,N′-diphenyl-N,N′-bis(3-methylphenyl)-1,1′-biphenyl-4,4′-d famine (TPD1), N,N′-diphenyl-N,N′-bis(4-methoxyphenyl)-1,1′-biphenyl-4,4′-diamine (TPD2), N,N,N′,N′-tetrakis(4-methoxyphenyl)-1,1′-biphenyl-4,4′-diamine (TPD3), N,N′-di(1-naphthyl)-N,N′-diphenyl-1,1′-biphenyl-4,4′-diamine (α-NPD), and TPTE; phenylenediamine-based compounds such as N,N,N′,N′-tetraphenyl-para-phenylenediamine, N,N,N′,N′-tetra(para-tolyl)-para-phenylenediamine, and N,N,N′,N′-tetra(meta-tolyl)-meta-phenylenediamine (PDA); carbazole-based compounds such as carbazole, N-isopropylcarbazole, and N-phenylcarbazole; stilbene-based compounds such as stilbene and 4-di-para-tolylaminostilbene; oxazole-based compounds such as OxZ; triphenylmethane-based compounds such as triphenylmethane and m-MTDATA; pyrazoline-based compounds such as 1-phenyl-3-(para-dimethylaminophenyl)pyrazoline; benzine(cyclohexadiene)-based compounds; triazole-based compounds such as triazole; imidazole-based compounds such as imidazole; oxadiazole-based compounds such as 1,3,4-oxadiazole and 2,5-di(4-dimethylaminophenyl)-1,3,4-oxadiazole; anthracene-based compounds such as anthracene and 9-(4-diethylaminostyryl)anthracene; fluorenone-based compounds such as fluorenone, 2,4,7-trinitro-9-fluorenone, and 2,7-bis(2-hydroxy-3-(2-chlorophenylcarbamoyl)-1-naphthylazo) fluorenone; aniline-based compounds such as polyaniline; silane-based compounds; pyrrole-based compounds such as 1,4-dithioketo-3,6-diphenyl-pyrrolo-(3,4-c)pyrrolopyrrole; fluorene-based compounds such as fluorene; porphyrin-based compounds such as porphyrin and metal tetraphenylporphyrin; quinacridon-based compounds such as quinacridon; metallic or non-metallic phthalocyanine-based compounds such as phthalocyanine, copper phthalocyanine, tetra(t-butyl)copper phthalocyanine, and iron phthalocyanine; metallic or non-metallic naphthalocyanine-based compounds such as copper naphthalocyanine, vanadyl naphthalocyanine, and monochloro gallium naphthalocyanine; and benzidine-based compounds such as N,N′-di(naphthalen-1-yl)-N,N′-diphenyl-benzidine and N,N,N′,N′-tetraphenylbenzidine. These can be used alone or in combination of two or more thereof.

Among these, arylamine-based compounds such as α-NPD and TPTE are preferred.

In the case where the organic electroluminescence device of the present invention includes a hole transport layer as an independent layer, the average thickness of the hole transport layer is not particularly limited but is preferably 10 to 150 nm. It is more preferably 40 to 100 nm.

The average thickness of the hole transport layer can be measured with a quartz crystal film thickness monitor in the case of a low-molecular compound, or with a contact-type step meter in the case of a polymer compound.

The material of the electron-transport layer can be any compound that can be usually used as a material of an electron-transport layer. A mixture of these compounds can also be used.

Examples of low-molecular compounds that can be used as a material of the electron-transport layer include a boron-containing compound represented by formula (15) which is described later; pyridine derivatives such as tris-1,3,5-(3′-(pyridin-3″-yl)phenyl)benzene (TmPyPhB); quinoline derivatives such as (2-(3-(9-carbazolyl)phenyl)quinoline (mCQ)); pyrimidine derivatives such as 2-phenyl-4,6-bis(3,5-dipyridylphenyl)pyrimidine (BPyPPM); pyrazine derivatives; phenanthroline derivatives such as bathophenanthroline (BPhen); triazine derivative such as 2,4-bis(4-biphenyl)-6-(4′-(2-pyridinyl)-4-biphenyl)-[1,3,5]triazine (MPT); triazole derivatives such as 3-phenyl-4-(1′-naphthyl)-5-phenyl-1,2,4-triazole (TAZ); oxazole derivatives; oxadiazole derivatives such as 2-(4-biphenyl)-5-(4-tert-butylphenyl-1,3,4-oxadiazole) (PBD); imidazole derivatives such as 2,2′,2″-(1,3,5-benzinetriyl)-tris(1-phenyl-1-H-benzimidazole) (TPBI); aromatic ring tetracarboxylic anhydrides such as naphthalene and perylene; various metal complexes such as bis[2-(2-hydroxyphenyl)benzothiazolato]zinc (Zn(BTZ)₂) and tris(8-hydroxyquinolinato)aluminum (Alq₃); and organic silane derivatives typified by silole derivatives such as 2,5-bis(6′-(2′,2″-bipyridyl))-1,1-dimethyl-3,4-diphenylsilole (PyPySPyPy). These can be used alone or in combination of two or more thereof.

Among these, metal complexes such as Alq₃ and pyridine derivatives such as TmPyPhB are preferred.

In the case where the organic electroluminescence device of the present invention includes an electron-transport layer as an independent layer, the average thickness of the electron-transport layer is not particularly limited but is preferably 10 to 150 nm. It is more preferably 40 to 100 nm.

The average thickness of the electron-transport layer can be measured with a quartz crystal film thickness monitor in the case of a low-molecular compound, or with a contact-type step meter in the case of a polymer compound.

In the organic electroluminescence device of the present invention, the method for forming layers such as a metal oxide layer, a cathode, an anode, an emitting layer, a hole transport layer, and an electron-transport layer is not particularly limited. Examples of the method include chemical vapor deposition (CVD) methods (which are vapor phase film forming methods) such as plasma CVD, thermal CVD, and laser CVD; dry plating methods such as vacuum deposition, sputtering, and ion plating; spraying method; wet plating methods (which are liquid phase film forming methods) such as electrolytic plating, immersion plating, and electroless plating; a sol-gel method; a MOD method; a spray pyrolysis method; a doctor blade method using a fine particulate dispersion; a spin coating method; and printing techniques such as an inkjet method and a screen printing method. A method suitable to the material can be selected and used.

These methods are preferably selected according to the properties of the material of each layer. Each layer may be formed by a different method. It is more preferred to form the second metal oxide layer by the vapor phase film forming method among other methods. With the vapor phase film forming method, the second metal oxide layer can be cleanly formed without destroying the surface of the organic compound layer and in good contact with the anode. As a result, the effect of the second metal oxide becomes more significant.

In the organic electroluminescence device of the present invention, the buffer layer is preferably a layer formed by applying a solution containing an organic compound. Owing to the formation of a buffer layer having a certain thickness by applying the solution containing an organic compound, the crystallization of a material forming a layer formed on the buffer layer can be effectively suppressed.

The method for applying the solution containing an organic compound is not particularly limited. Examples thereof include various application methods such as a spin coating method, a casting method, a micro gravure coating method, a gravure coating method, a wire bar coating method, a bar coating method, a slit coating method, a roll coating method, a dip coating method, a spray coating method, a screen printing method, a flexographic printing method, an offset printing method, and an inkjet printing method. Among these, a spin coating method and a slit coating method are preferred because the layer thickness can be easily controlled.

Owing to the formation of the buffer layer by an application method, irregularities on the metal oxide layer can be smoothed out so that the crystallization of a material forming a layer sequentially formed on the buffer layer can be suppressed.

Inorganic solvents and various organic solvents can be used to prepare the solution containing an organic compound. Examples of inorganic solvents include nitric acid, sulfuric acid, ammonia, hydrogen peroxide, water, carbon disulfide, carbon tetrachloride, and ethylene carbonate. Examples of organic solvents include ketone-based solvents such as methyl ethyl ketone (MEK), acetone, diethyl ketone, methyl isobutyl ketone (MIBK), methyl isopropyl ketone (MIPK), and cyclohexanone; alcohol-based solvents such as methanol, ethanol, isopropanol, ethylene glycol, diethylene glycol (DEG), and glycerine; ether-based solvents such as diethyl ether, diisopropylether, 1,2-dimethoxy ethane (DME), 1,4-dioxane, tetrahydrofuran (THF), tetrahydropyran (THP), anisole, diethylene glycol dimethyl ether (diglyme), and diethylene glycol ethyl ether (carbitol); cellosolve-based solvents such as methyl cellosolve, ethyl cellosolve, and phenyl cellosolve; aliphatic hydrocarbon-based solvents such as hexane, pentane, heptane, and cyclohexane; aromatic hydrocarbon-based solvents such as toluene, xylene, and benzene; aromatic heterocyclic compound-based solvents such as pyridine, pyrazine, furan, pyrrole, thiophene, and methylpyrrolidone; amide-based solvents such as N,N-dimethylformamide (DMF) and N,N-dimethylacetamide (DMA); halogenated compound-based solvents such as chlorobenzene, dichloromethane, chloroform, dichloromethane, and 1,2-dichloroethane; ester-based solvents such as ethyl acetate, methyl acetate, and ethyl formate; sulfur compound-based solvents such as dimethyl sulfoxide (DMSO) and sulfolane; nitrile-based solvents such as acetonitrile, propionitrile, and acrylonitrile; and organic acid-based solvents such as formic acid, acetic acid, trichloroacetic acid, and trifluoroacetic acid. Examples also include mixtures of these solvents.

Among these, THF, toluene, chloroform, and 1,2-dichloroethane are preferred.

The solution containing an organic compound is preferably such that the concentration of the organic compound in the solvent is 0.05 to 10% by mass. With the concentration in this range, the occurrence of uneven coating and irregularities resulting from application of the solution containing an organic compound can be prevented. The concentration of the organic compound in the solvent is more preferably 0.1 to 5% by mass, still more preferably 0.1 to 3% by mass.

The organic electroluminescence device of the present invention may be a top emission type in which light is extracted from the side opposite to the substrate, or may be a bottom emission type in which light is extracted from the substrate side.

Examples of materials of the substrate used in the organic electroluminescence device of the present invention include resin materials such as polyethylene terephthalate, polyethylene naphthalate, polypropylene, cycloolefin polymer, polyamide, polyethersulfone, polymethylmethacrylate, polycarbonate, polyarylate, and cyclic olefin; and glass materials such as silica glass and soda glass. These can be used alone or in combination of two or more thereof. Use of the resin materials is preferred in terms of flexibility.

In the case of the top emission type, an opaque substrate can also be used in addition to the substrate materials described above. For example, a substrate formed from a ceramic material such as alumina, a substrate in which an oxide film (insulating film) is formed on the surface of a metal substrate such as stainless steel, or the like can be used. These substrates can be used alone or in combination of two or more thereof. In addition, these substrates are preferably thin films in terms of flexibility.

The average thickness of the substrate is preferably 0.1 to 30 mm. It is more preferably 0.1 to 10 mm.

The average thickness of the substrate can be measured with a digital multimeter or a caliper.

In the organic electroluminescence device of the present invention, the organic compound forming the buffer layer is not particularly limited as long as it can form an organic compound layer by an application method. Examples of the organic compound include polyacetylene-based compounds such as trans-polyacetylene, cis-polyacetylene, poly(di-phenylacetylene) (PDPA), and poly(alkyl,phenylacetylene) (PAPA); polyparaphenylenevinylene-based compounds such as poly(para-phenylenevinylene) (PPV), poly(2,5-dialkoxy-para-phenylenevinylene) (RO-PPV), cyano-substituted-poly(para-phenylenevinylene) (CN-PPV), poly(2-dimethyloctylsilyl-para-phenylenevinylene) (DMOS-PPV), and poly(2-methoxy, 5-(2′-ethylhexoxy)-para-phenylenevinylene) (MEH-PPV); polythiophene-based compounds such as poly(3-alkylthiophene) (PAT) and poly(oxypropylene)triol (POPT); polyfluorene-based compounds such as poly(9,9-dialkylfluorene) (PDAF) (e.g., poly(9,9-dioctylfluorene)), poly(dioctylfluorene-alt-benzothiadiazole) (F8BT), α,ω-bis[N,N′-di(methylphenyl)aminophenyl]-poly[9,9-bis(2-ethylhexyl)fluorene-2,7-diyl] (PF2/6am4), and poly(9,9-dioctyl-2,7-divinylenefluorenyl-ortho-co(anthracene-9,10-diyl); polyparaphenylene-based compounds such as poly(para-phenylene) (PPP) and poly(1,5-dialkoxy-para-phenylene) (RO-PPP); polycarbazole-based compounds such as poly(N-vinylcarbazole) (PVK); polysilane-based compounds such as poly(methylphenylsilane) (PMPS), poly(naphthylphenylsilane) (PNPS), and poly(biphenylylphenylsilane) (PBPS); boron-containing compounds represented by formulae (15), (21), and (26) below; polyamines; and triazine ring-containing compounds. These may be used alone or in combination of two or more thereof.

In the organic electroluminescence device of the present invention, the organic compound forming the buffer layer is preferably a boron-containing organic compound. More preferably, the organic compound is a boron-containing organic compound having a structure represented by formula (15), (21), or (26) below.

In the organic electroluminescence device of the present invention, the organic compound forming the buffer layer is preferably a compound having a LUMO level deeper than that of a light-emitting compound in the emitting layer in order to achieve efficient electron injection from the first metal oxide layer.

Further, in order to prevent a situation where the energy of excitons generated in the emitting layer is transferred to a compound in the buffer layer to cause light emission, the organic compound forming the buffer layer is more preferably a compound having a HOMO-LUMO energy gap greater than that of the light-emitting compound in the emitting layer.

The boron-containing compounds represented by formulae (15), (21), and (26) below have various properties such as (i) thermal stability, (ii) low HOMO and LUMO energy levels, and (iii) a capability to form a good coating film. These compounds can be suitably used as materials of the organic electroluminescence device of the present invention.

Specifically, in the organic electroluminescence device of the present invention, the boron-containing organic compound forming the buffer layer is preferably a boron-containing compound represented by formula (15) below:

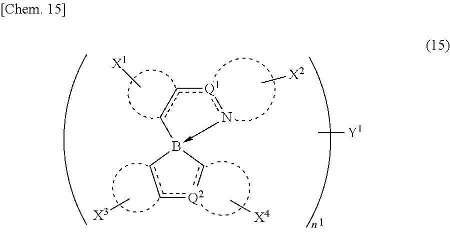

(in formula (15), dotted arcs indicate that ring structures are formed with the backbone shown in solid lines. Dotted line portions of the backbone shown in solid lines indicate that pairs of atoms connected by these dotted lines may be bonded by a double bond. An arrow from a nitrogen atom to a boron atom indicates that the nitrogen atom is coordinated to the boron atom. Q¹ and Q², which are the same or different, each represent a linking group in the backbone shown in solid lines, at least a portion thereof forms a ring structure with a dotted arc portion, and these linking groups may be substituted; X¹, X², X³, and X⁴, which are the same or different, each represent a hydrogen atom or a monovalent substituent as a substituent in a ring structure, and a plurality of such substituents may be bonded to the ring structures forming the dotted arc portions; n¹ represents an integer of 2 to 10; and Y¹ is a direct bond or an n¹-valent linking group. Y¹ bonds to n¹ number of structures other than Y¹ each independently at any one of a ring structure forming a dotted arc portion, Q¹, Q², X¹, X², X³, and X⁴).

In formula (15), dotted arcs indicate that ring structures are formed with a portion of the backbone shown in solid lines (i.e., a portion of the backbone connecting the boron atom, Q¹, and the nitrogen atom, or a portion of the backbone connecting the boron atom and Q²). This indicates that the compound represented by formula (15) has at least four ring structures, and that these ring structures incorporate the backbone connecting the boron atom, Q¹, and the nitrogen atom and the backbone connecting the boron atom and Q² in formula (15). The backbone of a ring structure to which X¹ is bonded consists of only carbon atoms.

In formula (15), dotted line portions of the backbone shown in solid lines (i.e., a dotted portion of the backbone connecting the boron atom, Q¹, and the nitrogen atom, and a dotted portion of the backbone connecting the boron atom and Q²) indicate that pairs of atoms connected by these dotted lines in the respective portions of the backbone may be bonded by a double bond.

In formula (15), an arrow from the nitrogen atom to the boron atom indicates that the nitrogen atom is coordinated to the boron atom. The term “coordinated” as used herein means that the nitrogen atom is acting as a ligand and chemically affecting the boron atom. These atoms may or may not form a coordination bond (covalent bond). Preferably, these atoms form a coordination bond.

In formula (15), Q¹ and Q², which are the same or different, each represent a linking group in the backbone shown in solid lines, at least a portion thereof forms a ring structure with a dotted arc portion, and these linking groups may be substituted. This means that Q¹ and Q² are incorporated into the ring structures.

In formula (15), X¹, X², X³, and X⁴, which are the same or different, each represent a hydrogen atom or a monovalent substituent as a substituent in a ring structure, and a plurality of such substituents may be bonded to the ring structures forming the dotted arc portions. Specifically, in the structure of the compound represented by formula (15), if X¹, X², X³, and X⁴ are hydrogen atoms, four ring structures containing X¹, X², X³, and X⁴ are not substituted; whereas if at least one or all of X¹, X², X³, and X⁴ are monovalent substituents, at least one or all of these four ring structures are substituted. In this case, the number of substituents in one ring structure may be one or two or more.

The term “substituent” as used herein encompasses carbon-containing organic groups and non-carbon-containing groups such as a halogen atom and a hydroxy group.

In formula (15), n¹ represents an integer of 2 to 10, and Y¹ is a direct bond or an n¹-valent linking group. Specifically, in the compound represented by formula (15), Y¹ is a direct bond and two structures other than Y¹ are independently bonded together at any one of a ring structure forming a dotted arc portion, Q¹, Q², X¹, X², X³, and X⁴; or Y¹ is an n¹-valent linking group, and a plurality of structures other than Y¹ is present in formula (15) and bonded together via Y¹ as a linking group.

In formula (15), if Y¹ is a direct bond, formula (15) indicates that a direct bond is formed between any one of a ring structure forming a dotted arc portion, Q¹, Q², X¹, X², X³, and X⁴ of one of the two structures other than Y¹ and any one of a ring structure forming a dotted arc portion, Q¹, Q², X¹, X², X³, and X⁴ of the other of the two structures. The binding position is not particularly limited. Yet, as for the bond between the two structures other than Y¹, a direct bond is preferably formed between one ring to which X¹ or X² is bonded and the other ring to which X¹ or X² of the other of the structures is bonded. More preferably, a direct bond is formed between a ring to which X² is bonded in one of the structures other than Y¹ and a ring to which X² is bonded in the other of the structures.

In this case, the structures of the two structures other than Y¹ may be the same or different from each other.

In formula (15), if Y¹ is an n¹-valent linking group and a plurality of structures other than Y¹ is present and bonded via Y¹ as a linking group in formula (15), such a structure in which a plurality of structures other than Y¹ is bonded via Y¹ as a linking group in formula (15) is more preferred because the structure is more resistant to oxidation and improves film-forming properties compared to a structure in which a direct bond is formed between structures other than Y¹.

If Y¹ is an n¹-valent linking group, n¹ number of structures other than Y¹ are each independently bonded to Y¹ at any one of a ring structure forming a dotted arc portion, Q¹, Q², X¹, X², X³, and X⁴. This means that structures other than Y¹ are bonded to Y¹ via any one of a ring structure forming a dotted arc portion, Q¹, Q², X¹, X², X³, and X⁴; and as for the binding sites of the structures other than Y¹ to Y¹, the n¹ number of structures other than Y¹ have independent binding sites, which may be all the same, partially the same, or all different. The binding position is not particularly limited. Yet, preferably, all of the n¹ number of structures other than Y¹ are bonded to Y¹ via a ring to which X¹ or X² is bonded. More preferably, all of the n¹ number of structures other than Y¹ are bonded to Y¹ via a ring to which X² is bonded.

In addition, the structures of the n¹ number of structures other than Y¹ may be all the same, partially different, or all different.

In formula (15), if Y¹ is an n¹-valent linking group, the linking group may be an optionally substituted linear, branched, or cyclic hydrocarbon group, an optionally substituted heteroatom-containing group, an optionally substituted aryl group, or an optionally substituted heterocyclic group. Among these, the linking group is preferably a group having an aromatic ring such as an optionally substituted aryl group or an optionally substituted heterocyclic group. Specifically, it is another preferred embodiment of the present invention that Y¹ in formula (15) contains an aromatic ring.

Further, Y¹ may be a linking group having a structure in which a plurality of the above-described linking groups is combined.

The linear, branched, or cyclic hydrocarbon group is preferably any of the groups represented by formulae (16-1) to (16-8) below. Among these, groups represented by formulae (16-1) and (16-7) below are more preferred.

The heteroatom-containing group is preferably a group represented by any of formulae (16-9) to (16-13) below. Among these, groups represented by (16-12) and (16-13) below are more preferred.

The aryl group is preferably a group represented by any of formulae (16-14) to (16-20) below. Among these, groups represented by (16-14) and (16-20) below are more preferred.

The heterocyclic group is preferably any of groups represented by formulae (16-21) to (16-27) below. Among these, groups represented by formulae (16-23) and (16-24) below are more preferred.

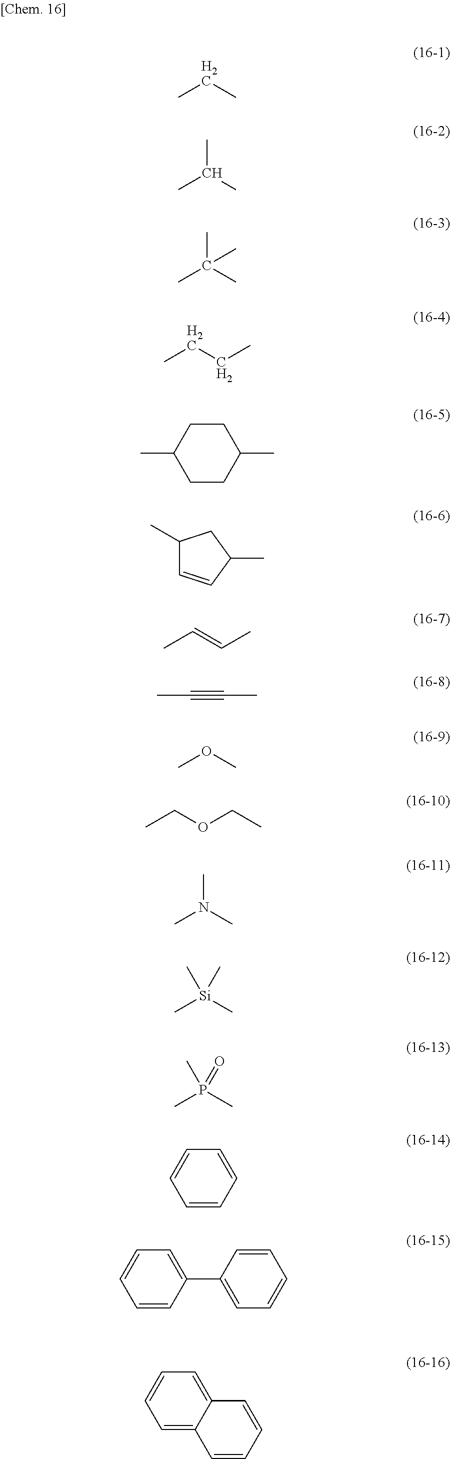

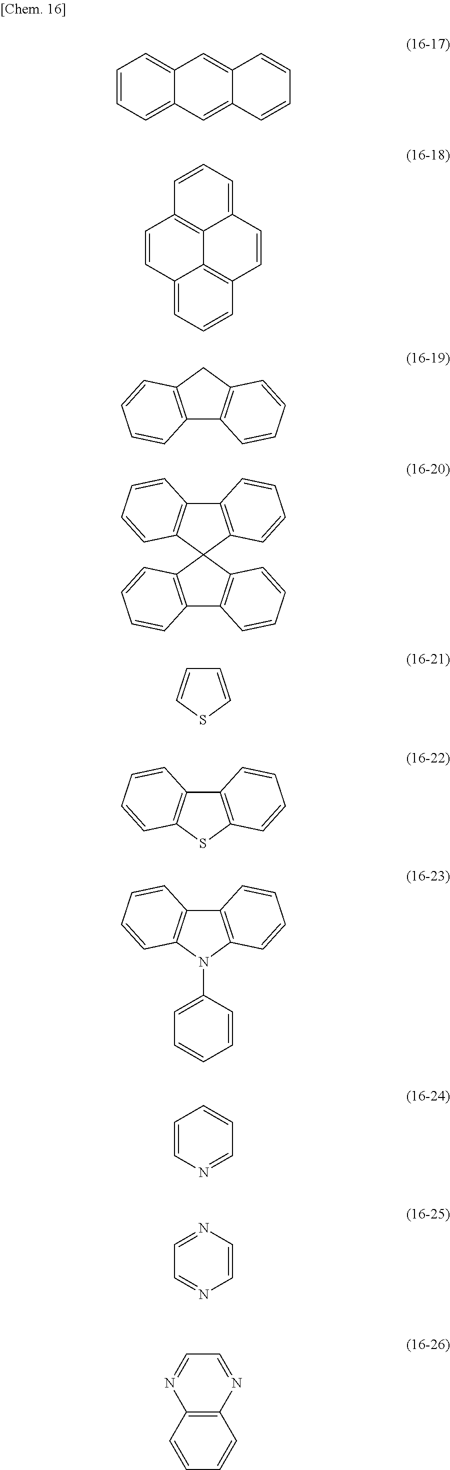

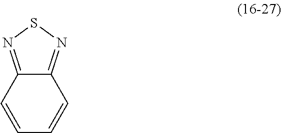

Examples of substituents in the linear, branched, or cyclic hydrocarbon group, the heteroatom-containing group, the aryl group, and the heterocyclic group include halogen atoms such as fluorine, chlorine, bromine, and iodine atoms; haloalkyl groups such as fluoromethyl, difluoromethyl, and trifluoromethyl groups; C1-20 linear or branched alkyl groups such as methyl, ethyl, propyl, isopropyl, butyl, isobutyl, and tert-butyl groups; C5-7 cyclic alkyl groups such as cyclopentyl, cyclohexyl, and cycloheptyl groups; C1-20 linear or branched alkoxy groups such as methoxy, ethoxy, propoxy, isopropoxy, butoxy, isobutoxy, tert-butoxy, pentyloxy, hexyloxy, heptyloxy, and octyloxy groups; a nitro group; a cyano group; C1-10 alkyl-containing dialkylamino groups such as methylamino, ethylamino, dimethylamino, and diethylamino groups; diarylamino groups such as diphenylamino and carbazolyl groups; acyl groups such as acetyl, propionyl, and butyryl groups; C2-30 alkenyl groups such as vinyl, 1-propenyl, allyl, and styryl groups; C2-30 alkynyl groups such as ethynyl, 1-propynyl, and propargyl groups; aryl groups optionally substituted with a halogen atom or a group such as an alkyl, alkoxy, alkenyl, or alkynyl group; heterocyclic groups optionally substituted with a halogen atom or a group such as an alkyl, alkoxy, alkenyl, or alkynyl group; N,N-dialkylcarbamoyl groups such as N,N-dimethylcarbamoyl and N,N-diethylcarbamoyl groups; and groups such as dioxaborolanyl, stannyl, silyl, ester, formyl, thioether, epoxy, and isocyanate groups. These groups may be substituted with a halogen atom, a heteroatom, an alkyl group, an aromatic ring, or the like.

Among these, the substituent in the linear, branched, or cyclic hydrocarbon group, the heteroatom-containing group, the aryl group, or the heterocyclic group in Y¹ is preferably a halogen atom, a C1-20 linear or branched alkyl group, a C1-20 linear or branched alkoxy group, an aryl group, a heterocyclic group, or a diarylamino group. The substituent is more preferably an alkyl group, an aryl group, an alkoxy group, or a diarylamino group.

In the case where the linear, branched, or cyclic hydrocarbon group, the heteroatom-containing group, the aryl group, or the heterocyclic group in Y¹ is substituted, the binding position and number of bonds are not particularly limited.

In formula (15), n¹ represents an integer of 2 to 10, preferably 2 to 6. It is more preferably an integer of 2 to 5, still more preferably 2 to 4, particularly preferably 2 or 3, in terms of solubility in a solvent. It is most preferably an integer of 2. Specifically, the boron-containing compound represented by formula (15) is most preferably a dimer.

Examples of Q¹ and Q² in formula (15) include structures represented by formulae (17-1) to (17-8) below:

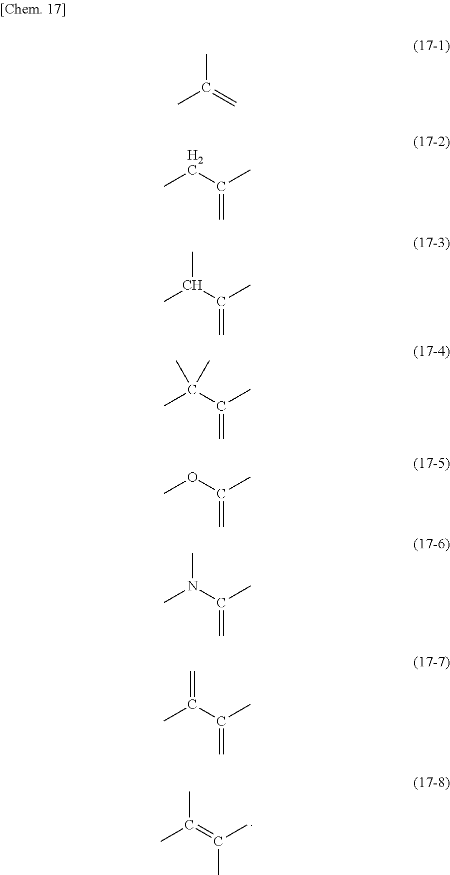

The structure represented by formula (17-2) consists of carbon atoms and two hydrogen atoms and three other atoms bonds to the structure represented by formula (17-2). None of these three atoms bonded to the carbon atoms other than the hydrogen atoms are hydrogen atoms. Among these formulae (17-1) to (17-8), any of (17-1), (17-7), and (17-8) is preferred. (17-1) is more preferred. Specifically, it is another preferred embodiment of the present invention that Q¹ and Q², which are the same or different, each represent a C1 linking group.

In formula (15), the ring structures formed by dotted arcs and a portion of the backbone shown in solid lines are not particularly limited as long as the backbone of the ring structure to which X¹ is bonded consists of carbon atoms.

In formula (15), if Y¹ is a direct bond and n¹ is 2, examples of the ring to which X¹ is bonded include a benzene ring, a naphthalene ring, an anthracene ring, a tetracene ring, a pentacene ring, a triphenylene ring, a pyrene ring, a fluorene ring, an indene ring, a thiophene ring, a furan ring, a pyrrole ring, a benzothiophene ring, a benzofuran ring, an indole ring, dibenzothiophene ring, a dibenzofuran ring, a carbazole ring, a thiazole ring, a benzothiazole ring, an oxazole ring, a benzoxazole ring, an imidazole ring, a pyrazole ring, a benzimidazole ring, a pyridine ring, a pyrimidine ring, a pyrazine ring, a pyridazine ring, a quinoline ring, an isoquinoline ring, a quinoxaline ring, and a benzothiadiazole ring. These are respectively represented by formulae (18-1) to (18-33) below.

Preferred among these are the ring structures having the backbone consisting of only carbon atoms, such as a benzene ring, a naphthalene ring, an anthracene ring, a tetracene ring, a pentacene ring, a triphenylene ring, a pyrene ring, a fluorene ring, and an indene ring. A benzene ring, a naphthalene ring, and a fluorene ring are more preferred; and a benzene ring is still more preferred.

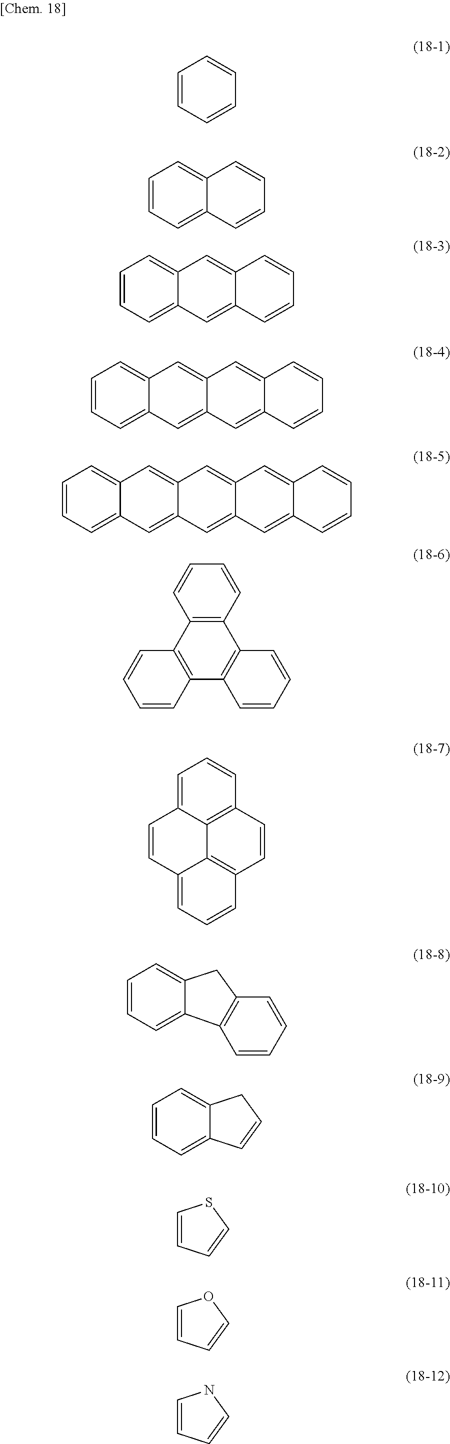

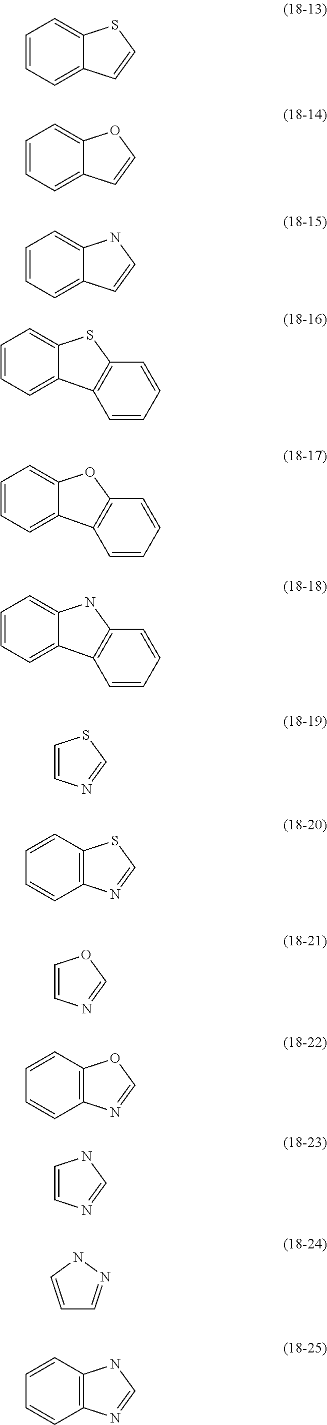

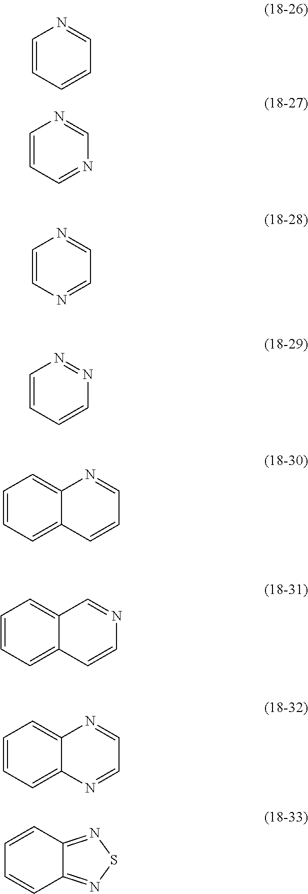

In formula (15), if Y¹ is a direct bond and n¹ is 2, examples of the ring to which X² is bonded includes an imidazole ring, a benzimidazole ring, a pyridine ring, a pyridazine ring, a pyrazine ring, a pyrimidine ring, a quinoline ring, an isoquinoline ring, a phenanthridine ring, a quinoxaline ring, a benzothiadiazole ring, a thiazole ring, a benzothiazole ring, an oxazole ring, a benzoxazole ring, a oxadiazole ring, and a thiadiazole ring. These are respectively represented by formulae (19-1) to (19-17). The symbol “*” in formulae (19-1) to (19-17) indicates that the carbon atom that forms the ring to which X¹ is bonded and that forms the backbone connecting the boron atom, Q¹, and the nitrogen atom in formula (15) is bonded to any one of the carbon atoms marked with *. These rings may be condensed with another ring structure at a site other than the carbon atoms marked with *. Among the examples mentioned above, a pyridine ring, a pyrimidine ring, a quinoline ring, and a phenanthridine ring are preferred. A pyridine ring, a pyrimidine ring, and a quinoline ring are more preferred, and a pyridine ring is still more preferred.

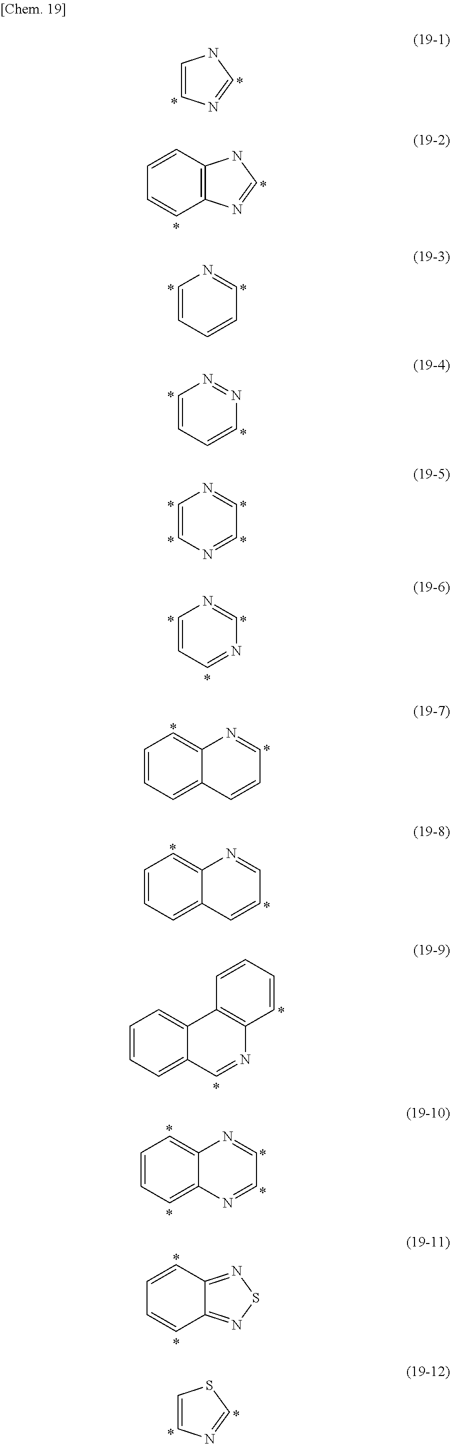

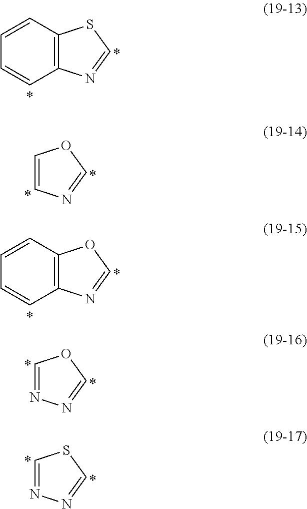

In addition, in formula (15), if Y¹ is a direct bond and n¹ is 2, examples of the ring to which X³ is bonded and the ring to which X⁴ is bonded include the rings represented by formulae (18-1) to (18-33). Among these, a benzene ring, a naphthalene ring, and a benzothiophene ring are preferred. A benzene ring is more preferred.

In formula (15), X¹, X², X³, and X⁴, which are the same or different, each represents a hydrogen atom or a monovalent substituent as a substituent in a ring structure. The monovalent substituent is not particularly limited. Examples of X¹, X², X³, and X⁴ include a hydrogen atom, an optionally substituted aryl group, a heterocyclic group, an alkyl group, an alkenyl group, an alkynyl group, an alkoxy group, an aryloxy group, an arylalkoxy group, a silyl group, an a hydroxy group, an amino group, a halogen atom, a carboxyl group, a thiol group, an epoxy group, an acyl group, an optionally substituted oligoaryl group, a monovalent oligoheterocyclic group, an alkylthio group, an arylthio group, an arylalkyl group, an arylalkoxy group, an arylalkylthio group, an azo group, a stannyl group, a phosphino group, a silyloxy group, an optionally substituted aryloxycarbonyl group, an optionally substituted alkoxycarbonyl group, an optionally substituted carbamoyl group, an optionally substituted arylcarbonyl group, an optionally substituted alkylcarbonyl group, an optionally substituted arylsulfonyl group, an optionally substituted alkylsulfonyl group, an optionally substituted arylsulfinyl group, an optionally substituted alkylsulfinyl group, a formyl group, a cyano group, a nitro group, an arylsulfonyloxy group, an alkylsulfonyloxy group; alkylsufonate groups such as methanesulfonate, ethanesulfonate, and trifluoromethanesulfonate groups; arylsulfonate groups such as benzene sulfonate and p-toluenesulfonate groups; arylalkylsufonate groups such as a benzylsulfonate group; a boryl group, a sulfonium methyl group, a phosphonium methyl group, a phosphonate methyl group, an arylsulfonate group, an aldehyde group, and an acetonitrile group.

Examples of the substituents in X¹, X², X³, and X⁴ include halogen atoms such as fluorine, chlorine, bromine, and iodine atoms; haloalkyl groups such as methyl chloride, methyl bromide, methyl iodide, fluoromethyl, difluoromethyl, and trifluoromethyl groups; C1-20 linear or branched alkyl groups such as methyl, ethyl, propyl, isopropyl, butyl, isobutyl, sec-butyl, and tert-butyl groups; C5-7 cyclic alkyl groups such as cyclopentyl, cyclohexyl, and cycloheptyl groups; C1-20 linear or branched alkoxy groups such as methoxy, ethoxy, propoxy, isopropoxy, butoxy, iso-butoxy, tert-butoxy, pentyloxy, hexyloxy, heptyloxy, and octyloxy groups; a hydroxy group; a thiol group; a nitro group; a cyano group; an amino group; an azo group; C1-40 alkyl-containing mono or dialkylamino groups such as methylamino, ethylamino, dimethylamino, and diethylamino groups; amino groups such as diphenylamino and carbazolyl groups; acyl groups such as acetyl, propionyl, and butyryl groups; C2-20 alkenyl groups such as vinyl, 1-propenyl, allyl, butenyl, and styryl groups; C2-20 alkynyl groups such as ethynyl, 1-propynyl, propargyl, and phenyl acetinyl groups; alkenyloxy groups such as vinyloxy and allyloxy groups; alkynyloxy groups such as ethynyloxy and phenylacetyloxy groups; aryloxy groups such as phenoxy, naphthoxy, biphenyloxy, and pyrenyloxy groups; perfluoro groups and longer chain perfluoro groups such as trifluoromethyl, trifluoromethoxy, pentafluoroethoxy, and perfluorophenyl groups; boryl groups such as diphenylboryl, dimesitylboryl, and bis(perfluorophenyl)boryl groups; carbonyl groups such as acetyl and benzoyl groups; carbonyloxy groups such as acetoxy and benzoyloxy groups; alkoxycarbonyl groups such as methoxycarbonyl, ethoxycarbonyl, and phenoxycarbonyl groups; sulfinyl groups such as methylsulfinyl and phenylsulfinyl groups; an alkylsulfonyloxy group; an arylsulfonyloxy group; a phosphino group; silyl groups such as trimethylsilyl, triisopropylsilyl, dimethyl-tert-butylsilyl, trimethoxysilyl, and triphenylsilyl groups; a silyloxy group; a stannyl group; aryl groups optionally substituted with a halogen atom, an alkyl group, an alkoxy group, or the like such as a phenyl group, 2,6-xylyl, mesityl, duryl, biphenyl, terphenyl, naphthyl, anthryl, pyrenyl, toluyl, anisyl, fluorophenyl, diphenylaminophenyl, dimethylaminophenyl, diethylaminophenyl, and phenanthrenyl groups; heterocyclic groups such as thienyl, furyl, silacyclopentadienyl, oxazolyl, oxadiazolyl, thiazolyl, thiadiazolyl, acridinyl, quinolyl, quinoxaloyl, phenanthrolyl, benzothienyl, benzothiazolyl, indolyl, carbazolyl, pyridyl, pyrrolyl, benzoxazolyl, pyrimidyl, and imidazolyl groups; a carboxyl group; a carboxylate ester; an epoxy group; an isocyano group; a cyanate group; an isocyanate group; a thiocyanate group; an isothiocyanate group; a carbamoyl group; N,N-dialkylcarbamoyl groups such as N,N-dimethylcarbamoyl and N,N-diethylcarbamoyl groups; a formyl group; a nitroso group; and a formyloxy group. These groups may be substituted with a halogen atom, an alkyl group, an aryl group, or the like. These groups may also be bonded together at any position to form a ring.

Among these examples mentioned above, preferred examples of X¹, X², X³, and X⁴ include a hydrogen atom; reactive groups such as halogen atoms and carboxyl, hydroxy, thiol, epoxy, amino, azo, acyl, allyl, nitro, alkoxycarbonyl, formyl, cyano, silyl, stannyl, boryl, phosphino, silyloxy, arylsulfonyloxy, and alkylsulfonyloxy groups; C1-20 linear or branched alkyl groups; C1-20 linear or branched alkyl groups substituted with a group such as a C1-8 linear or branched alkyl, C1-8 linear or branched alkoxy, aryl, C2-8 alkenyl, or C2-8 alkynyl group, or any of the reactive groups; C1-20 linear or branched alkoxy groups; C1-20 linear or branched alkoxy groups substituted with a group such as a C1-8 linear or branched alkyl, C1-8 linear or branched alkoxy, aryl, C2-8 alkenyl, or C2-8 alkynyl group, or any of the reactive groups; aryl groups; aryl groups substituted with a group such as a C1-8 linear or branched alkyl, C1-8 linear or branched alkoxy, aryl, C2-8 alkenyl, or C2-8 alkynyl group, or any of the reactive groups; oligoaryl groups; oligoaryl groups substituted with a group such as a C1-8 linear or branched alkyl, C1-8 linear or branched alkoxy, aryl, C2-8 alkenyl, or C2-8 alkynyl group, or any of the reactive groups; monovalent heterocyclic groups; monovalent heterocyclic groups substituted with a group such as a C1-8 linear or branched alkyl, C1-8 linear or branched alkoxy, aryl, C2-8 alkenyl, or C2-8 alkynyl group, or any of the reactive groups; monovalent oligoheterocyclic groups; monovalent oligoheterocyclic groups substituted with a group such as a C1-8 linear or branched alkyl, C1-8 linear or branched alkoxy, aryl, C2-8 alkenyl, or C2-8 alkynyl group, or any of the reactive groups; alkylthio groups; aryloxy groups; arylthio groups; arylalkyl groups; arylalkoxy groups; arylalkylthio groups; alkenyl groups; alkenyl groups substituted with a group such as a C1-8 linear or branched alkyl, C1-8 linear or branched alkoxy, aryl, C2-8 alkenyl, or C2-8 alkynyl group, or any of the reactive groups; alkynyl groups; and alkynyl groups substituted with a group such as a C1-8 linear or branched alkyl, C1-8 linear or branched alkoxy, aryl, C2-8 alkenyl, or C2-8 alkynyl group, or any of the reactive groups.

More preferred examples among these are a hydrogen atom, a bromine atom, an iodine atom, an amino group, a boryl group, an alkynyl group, an alkenyl group, a formyl group, a silyl group, a stannyl group, a phosphino group, an aryl group substituted with any of the reactive groups, an oligoaryl group substituted with any of the reactive groups, a monovalent heterocyclic group substituted with a monovalent heterocyclic group or any of the reactive groups, a monovalent oligoheterocyclic group substituted with any of the reactive groups, an alkenyl group substituted with an alkenyl group or any of the reactive groups, and an alkynyl group substituted with an alkynyl group or any of the reactive groups. Still more preferred examples of X¹ and X² include a hydrogen atom and functional groups that are resistant to reduction such as alkyl, aryl, nitrogen-containing heteroaromatic, alkenyl, alkoxy, aryloxy, and silyl groups. Particularly preferred among these are a hydrogen atom, aryl groups, and nitrogen-containing heteroaromatic groups. Still more preferred examples of X³ and X⁴ include a hydrogen atom and functional groups that are resistant to oxidation such as carbazolyl, triphenylamino, thienyl, furanyl, alkyl, aryl, and indolyl groups. Particularly preferred among these are a hydrogen atom, carbazolyl groups, triphenylamino groups, and thienyl groups. The boron-containing compound containing reduction-resistant functional groups as X¹ and X² and oxidation-resistant functional groups as X³ and X⁴ is considered to be a compound having higher resistance to reduction and oxidation as a whole.

In formula (15), if X¹, X², X³, and X⁴ are monovalent substituents, the binding position and number of bonds of X¹, X², X³ and X⁴ to the ring structures are not particularly limited.

In formula (15), if Y¹ is an n¹-valent linking group and n¹ is 2 to 10, examples of the ring to which X¹ is bonded include the same examples of the ring to which X¹ is bonded when Y¹ is a direct bond and n¹ is 2 in formula (15). Among these rings, a benzene ring, a naphthalene ring, and a benzothiophene ring are preferred. A benzene ring is more preferred.

In formula (15), if Y¹ is an n¹-valent linking group and n¹ is 2 to 10, examples of the ring to which X² is bonded, examples of the ring to which X³ is bonded, and examples of the ring to which X⁴ is bonded include the same examples of the ring to which X² is bonded, the same examples of the ring to which X³ is bonded, and the same examples of the ring to which X⁴ is bonded, respectively, when Y¹ is a direct bond and n¹ is 2 in formula (15), and preferred structures are also the same.

Specifically, it is another preferred embodiment of the present invention that the boron-containing compound represented by formula (15) is a boron-containing compound represented by formula (20) below in either case where Y¹ is a direct bond and n¹ is 2 or where Y¹ is an n¹-valent linking group and n¹ is 2 to 10 in formula (15):

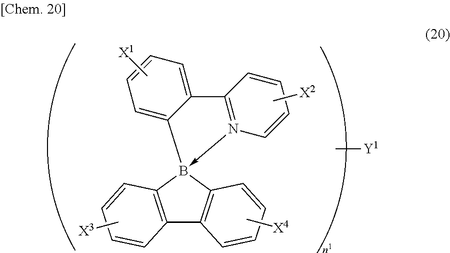

(in formula (20), an arrow from a nitrogen atom to a boron atom, X¹, X², X³, X⁴, n¹, and Y¹ are as defined above for formula (15)).

The boron-containing compound represented by formula (15) can be synthesized by various reactions that are commonly used such as Suzuki coupling reaction. The boron-containing compound can also be synthesized by the method described in Journal of the American Chemical Society, 2009, vol. 131, no. 40, pp. 14549-14559.

Examples of the synthesis scheme of the boron-containing compound represented by formula (15) include the following reaction formulae. Reaction formula (I) below is an example of the synthesis scheme of the boron-containing compound represented by formula (15) wherein Y¹ is a direct bond and n¹ is 2; reaction formula (II) below is an example of the synthesis scheme of the boron-containing compound represented by formula (15) wherein Y¹ is an n¹-valent linking group and n¹ is 2 to 10. Methods for producing the boron-containing compound represented by formula (15) are not limited to these described below.

In the following schemes, a compound (a) as a raw material can be synthesized by the method described in Journal of Organic Chemistry, 2010, vol. 75, no. 24, pp. 8709-8712. A compound (b) as a raw material can be synthesized by subjecting the compound (a) to a borylation reaction represented by reaction formula (III).

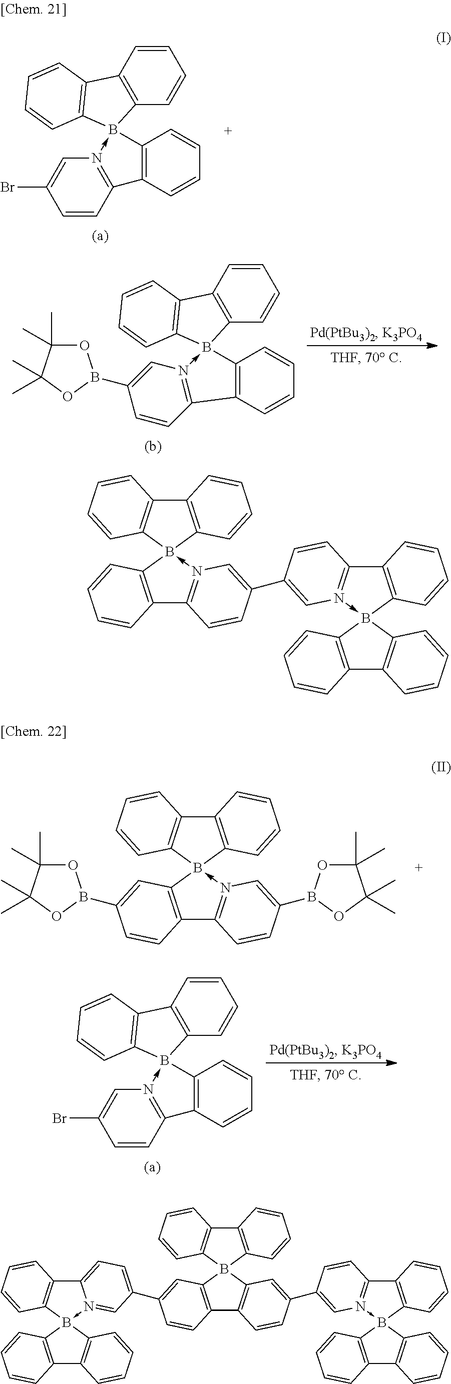

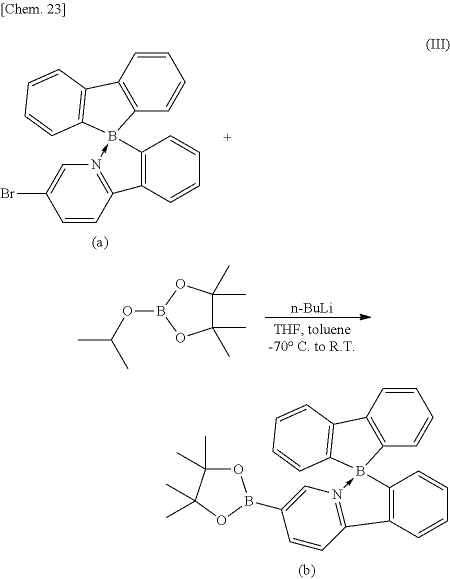

In addition, a boron-containing compound represented by formula (21) below is also preferred as an organic compound forming the buffer layer of the organic electroluminescence device of the present invention. Such a boron-containing compound is also encompassed by the present invention.

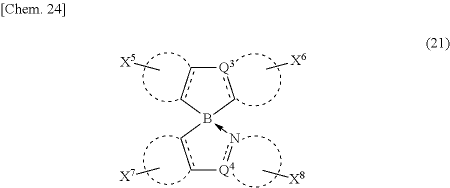

(in the formula, dotted arcs indicate that ring structures are formed with the backbone shown in solid lines; dotted line portions of the backbone shown in solid lines indicate that pairs of atoms connected by these dotted lines may be bonded by a double bond; an arrow from a nitrogen atom to a boron atom indicates that the nitrogen atom is coordinated to the boron atom; Q³ and Q⁴, which are the same or different, each represent a linking group in the backbone shown in solid lines, at least a portion thereof forms a ring structure with a dotted arc portion, and these linking groups may be substituted; X⁵ and X⁶, which are the same or different, each represent a hydrogen atom or a monovalent substituent as a substituent in a ring structure; X⁷ and X⁸, which are the same or different, each represent a monovalent substituent having electron transportability as a substituent in a ring structure; and a plurality of X⁵'s, X⁶'s, X⁷'s, and X⁸'s may be bonded to the ring structures forming the dotted arc portions).

In formula (21), dotted arcs indicate that ring structures are formed with a portion of the backbone shown in solid lines (i.e., a portion of the backbone connecting the boron atom and Q³, or a portion of the backbone connecting the boron atom, Q⁴, and the nitrogen atom). This indicates that the compound represented by formula (21) has at least four ring structures, and that these ring structures incorporate the backbone connecting the boron atom and Q³ and the backbone connecting the boron atom, Q⁴, and nitrogen atom in formula (21).

In formula (21), dotted line portions of the backbone shown in solid lines (i.e., a dotted portion of the backbone connecting the boron atom and Q³, and a dotted portion of the backbone connecting the boron atom, Q⁴, and the nitrogen atom) indicate that pairs of atoms connected by these dotted lines in the respective portions of the backbone may be bonded by a double bond.

In formula (21), an arrow from the nitrogen atom to the boron atom indicates that the nitrogen atom is coordinated to the boron atom. The term “coordinated” as used herein means that the nitrogen atom is acting as a ligand and chemically affecting the boron atom.

In formula (21), Q³ and Q⁴, which are the same or different, each represent a linking group in the backbone shown in solid lines, at least a portion thereof forms a ring structure with a dotted arc portion, and these linking groups may be substituted. This means that Q³ and Q⁴ are incorporated into the ring structures.

Examples of Q³ and Q⁴ in formula (21) include structures represented by formulae (17-1) to (17-8). The structure represented by formula (17-2) includes carbon atoms and two hydrogen atoms, and three other atoms bonds to the structure represented by formula (17-2) None of these three atoms bonds to the carbon atoms other than the hydrogen atoms are hydrogen atoms. Among these formulae (17-1) to (17-8), any of (17-1), (17-7), and (17-8) is preferred. (17-1) is more preferred. Specifically, it is another preferred embodiment of the present invention that Q³ and Q⁴, which are the same or different, each represent a C1 linking group.

In formula (21), examples of the rings to which X⁵ to X⁷ are bonded include the same specific examples of the ring to which X¹ is bonded when Y¹ is a direct bond and n¹ is 2 in formula (15). Among these, a benzene ring, a naphthalene ring, and a benzothiophene ring are preferred. A benzene ring is more preferred.

In formula (21), examples of the ring to which X⁸ is bonded include the same specific examples of the ring to which X² is bonded when Y¹ is a direct bond and n¹ is 2 in formula (15), and preferred ring structures among these examples are also the same. The symbol “*” in formulae (19-1) to (19-17) indicates that the carbon atom that form the ring to which X⁷ is bonded and that form the backbone connecting the boron atom, Q⁴, and the nitrogen atom in formula (1) is bonded to any one of the carbon atoms marked with *. Such a carbon atom may be condensed with another ring structure at a site other than the carbon atoms marked with *.

Specifically, it is another preferred embodiment of the present invention that the boron-containing compound represented by formula (21) is a boron-containing compound represented by formula (22) below:

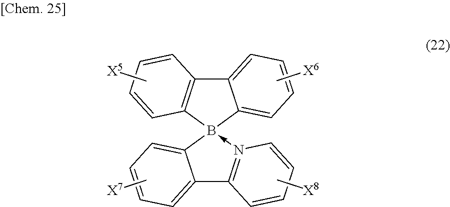

(in the formula, an arrow from a nitrogen atom to a boron atom, X⁵, X⁶, X⁷, and X⁸ are as defined above for formula (21)). In the case where the boron-containing compound of the present invention has a structure represented by formula (22), the rings to which X⁵, X⁶, X⁷, and X⁸ are bonded consist of only carbon atoms, except for the nitrogen atom coordinated to the boron atom. Thus, compared to a compound containing a heteroatom such as S in the ring, the molecular orbital of the compound of the present invention is less spread, which, in general terms, allows the compound to maintain a wide energy gap between HOMO and LUMO. Because of such characteristics, the compound of the present invention can be more suitably used, for examples, as a phosphorescent host material of an organic EL device.

In formula (21), X⁵ and X⁶, which are the same or different, each represent a hydrogen atom or a monovalent substituent as a substituent in a ring structure. The monovalent substituent is not particularly limited. Examples thereof include the same specific examples of the monovalent substituents represented by X¹, X², X³, and X⁴ in formula (15). Preferred substituents are also the same, except that more preferred substituents also include an oligoaryl group, a monovalent heterocyclic group, and a monovalent oligoheterocyclic group.

In formula (21), if X⁵, X⁶, X⁷, and X⁸ are monovalent substituents, the binding position and number of bonds of X⁵, X⁶, X⁷, and X⁸ to the ring structures are not particularly limited.

In formula (21), X⁷ and X⁸, which are the same or different, each represent a monovalent substituent having electron transportability as a substituent in a ring structure. The boron-containing compound represented by formula (21) is a material having excellent electron transportability due to the substituents having electron transportability represented by X⁷ and X⁸.

Examples of the monovalent substituent having electron transportability include monovalent groups derived from a nitrogen-containing heterocyclic ring in which a carbon-nitrogen double bond (C═N) is present in the ring such as an imidazole ring, a thiazole ring, an oxazole ring, an oxadiazole ring, a triazole ring, a pyrazole ring, a pyridine ring, a pyrazine ring, a triazine ring, a benzimidazole ring, a benzothiazole ring, a quinoline ring, an isoquinoline ring, a quinoxaline ring, or a benzothiadiazole ring; monovalent groups derived from an aromatic hydrocarbon ring or an aromatic heterocyclic ring in which a carbon-nitrogen double bond is not present in the ring having one or more electron-withdrawing substituents such as a benzene ring, a naphthalene ring, a fluorene ring, a thiophene ring, a benzothiophene ring, or a carbazole ring; and rings such as dibenzothiophene dioxide ring, dibenzophosphole oxide ring, and a silole ring.

Examples of the electron-withdrawing substituent include —CN, —COR, —COOR, —CHO, —CF₃, —SO₂Ph, and —PO(Ph)₂. The symbol “R” as used herein represents a hydrogen atom or a monovalent hydrocarbon group.

Among these examples, the monovalent substituent having electron transportability is preferably a group derived from a nitrogen-containing heterocyclic ring in which a carbon-nitrogen double bond (C═N) is present in a ring.

The monovalent substituent having electron transportability is more preferably any of monovalent groups derived from a heteroaromatic ring in which a carbon-nitrogen double bond is present in the ring.

Examples of the substituents represented by X⁵, X⁶, X⁷, and X⁶ include the same substituents represented by X¹, X², X³, and X⁴ in formula (15).

The boron-containing compound represented by formula (21) is preferably synthesized by a synthesis method represented by formula (23) below. In the formula, Z¹ represents a bromine atom or an iodine atom; and Z² represents a chlorine atom, a bromine atom, or an iodine atom.

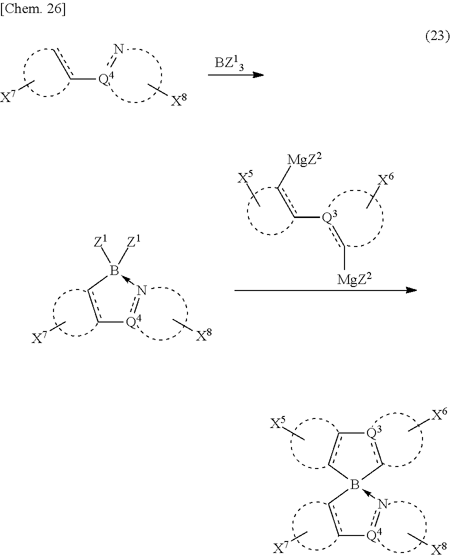

Producing the boron-containing compound represented by formula (21) by such a synthesis method allows the boron-containing compound to be produced at low cost. A second step of this synthesis method is an entirely novel reaction. The present invention also encompasses a method for producing the boron-containing compound represented by formula (21) using such a reaction, i.e., a method for producing the boron-containing compound formula (21) below:

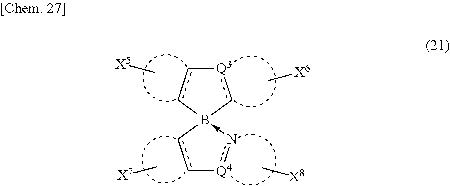

(in the formula, dotted arcs indicate that ring structures are formed with the backbone shown in solid lines; dotted line portions of the backbone shown in solid lines indicate that pairs of atoms connected by these dotted lines may be bonded by a double bond; an arrow from a nitrogen atom to a boron atom indicates that the nitrogen atom is coordinated to the boron atom; Q³ and Q⁴, which are the same or different, each represent a linking group in the backbone shown in solid lines, at least a portion thereof forms a ring structure with a dotted arc portion, and these linking groups may be substituted; X⁵ and X⁶, which are the same or different, each represent a hydrogen atom or a monovalent substituent as a substituent in a ring structure; X⁷ and X⁸, which are the same or different, each represent a monovalent substituent having electron transportability as a substituent in a ring structure; and a plurality of X⁵'s, X⁶'s, X⁷'s, and X⁸'s may be bonded to the ring structures forming the dotted arc portions), wherein the production method includes the step of reacting a compound (I) represented by formula (24) below:

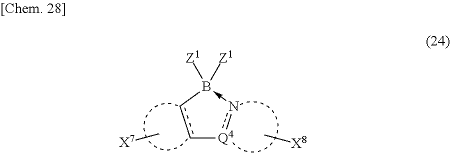

(in the formula, dotted arcs, dotted line portions of the backbone shown in solid lines, an arrow from a nitrogen atom to a boron atom, Q⁴, X⁷, and X⁵ are as defined above for formula (21); and Z¹ represents a bromine atom or an iodine atom) with a compound (II) represented by formula (25) below:

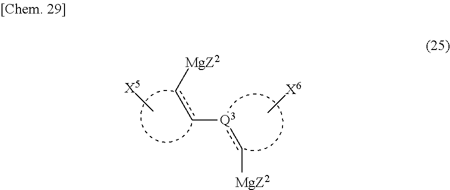

(in the formula, each dotted arc indicates that a ring structure is formed with the backbone connecting two MgZ's; a dotted line portion between two carbon atoms and a dotted line portion between a carbon atom and Q³ in the backbone indicate that pairs of atoms connected by these dotted lines may be bonded by a double bond; Q³, X⁵, and X⁶ are as defined above for formula (21); Z² represents a chlorine atom, a bromine atom, or an iodine atom). Such a method for producing a boron-containing compound is also encompassed by the present invention.

A solvent used in a first step of the synthesis method represented by formula (23) is not particularly limited. Examples thereof include hexane, heptane, benzene, toluene, diethyl ether, diisopropyl ether, dibutyl ether, and cyclopentyl methyl ether. They can be used alone or in combination of two or more thereof.

The first step of the synthesis method represented by formula (23) can be carried out by referring to the disclosure of JP-A 2011-184430.

The reaction temperature of the second step is preferably in the range of 0° C. to 40° C. The reaction may be carried out under any of normal, reduced, or increased pressure.

The reaction time of the second step is preferably 3 to 48 hours.

The synthesis method represented by formula (23) may further include one or more steps of replacing any one or more of the substituents represented by X⁵ to X⁸ by other substituent(s) after the second step. For example, if at least one of X⁵ to X⁸ is a halogen atom, the halogen atom can be replaced by a substituent X by a reaction such as Stille cross-coupling reaction, Suzuki-Miyaura cross-coupling reaction, Sonogashira cross-coupling reaction, Heck cross-coupling reaction, Hiyama coupling reaction, Negishi coupling reaction, or the like.

The above coupling reaction can be carried out by suitably using reaction conditions commonly used for these coupling reactions.

Another preferred material forming the buffer layer of the organic electroluminescence device of the present invention is a polymer having a repeating unit represented by formula (26) below:

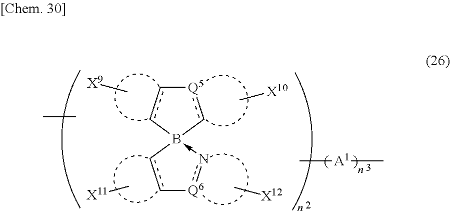

(in the formula, dotted arcs indicate that ring structures are formed with the backbone shown in solid lines; dotted line portions of the backbone shown in solid lines indicate that pairs of atoms connected by these dotted lines may be bonded by a double bond; an arrow from a nitrogen atom to a boron atom indicates that the nitrogen atom is coordinated to the boron atom; Q⁵ and Q⁶, which are the same or different, each represent a linking group in the backbone shown in solid lines, at least a portion thereof forms a ring structure with a dotted arc portion, and these linking groups may be substituted; X⁹, X¹⁰, X¹¹, and X¹², which are the same or different, each represent a hydrogen atom, a monovalent substituent as a substituent in a ring structure, or a direct bond, and a plurality of such substituents may be bonded to the ring structures forming the dotted arc portions; each A¹ is the same or different and represents a divalent group; a structural unit in a parenthesis marked with n² is bonded to its adjacent structural units via any two of X⁹, X¹⁰, X¹¹, and X¹²; n² and n³, which are the same or different, each independently represent an integer of 1 or more). Such a boron-containing polymer is also encompassed by the present invention.

Q⁵ and Q⁶ in formula (26) are the same as Q³ and Q⁴ in formula (21), respectively, and preferred embodiments are also the same. Specifically, Q⁵ and Q⁶, which are the same or different, each preferably represent a C1 linking group.

In formula (26), dotted arcs, dotted line portions of the backbone shown in solid lines, and an arrow from the nitrogen atom to the boron atom are as defined above for formula (21); and preferred structures of the dotted arcs are also as mentioned above for formula (21). Specifically, the boron-containing polymer (26) of the present invention preferably has a repeating unit structure represented by formula (27) below:

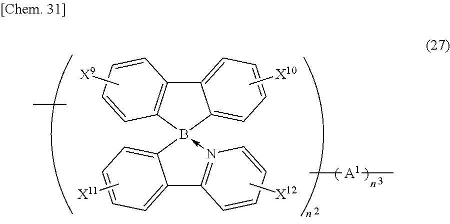

(in the formula, an arrow from a nitrogen atom to a boron atom, X⁹, X¹⁰, X¹¹, X¹², A¹, n², and n³ are as defined above for formula (26); and the bond of the structural unit in the parenthesis marked with n² to its adjacent structural units is also as defined above for formula (26)).

In formula (26), n² represents the number of structural units in the parenthesis marked with n², and represents an integer of 1 or more. n³ represents the number of structural units in the parenthesis marked with n³, and represents an integer of 1 or more. n² and n³, which are the same or different, each independently represent an integer of 1 or more. This means as follows.

n² and n³ each represents an independent integer. Thus, n² and n³ may represent the same or different integers.

The boron-containing polymer represented by formula (26) may have one or more structures represented by formula (26). If the boron-containing polymer has a plurality of structures represented by formula (26), n² and n³ in one structure and n² and n³ in its adjacent structure may be the same or different.

Thus, examples of the boron-containing polymer represented by formula (26) include all of the following structures: an alternating copolymer (which has two or more structures represented by formula (26) wherein each n² represents the same integer and each n³ also represents the same integer in all the structures represented by formula (26)); a block copolymer (which has one structure represented by formula (26) wherein at least one of n² and n³ represents an integer of 2 or more); and a random copolymer (which has two or more structures represented by formula (26) wherein either or both of n² and n³ in at least one of the structures represented by formula (26) are different from n² and n³ in other structure (s)).

The boron-containing polymer represented by formula (26) is preferably an alternating copolymer among these copolymers.

In formula (26), X⁹, X¹⁰, X¹¹, and X¹², which are the same or different, each represent a hydrogen atom, a monovalent substituent as a substituent in a ring structure, or a direct bond.

In formula (26), any two of X⁹, X¹⁰, X¹¹, and X¹² form a bond as a portion of the main chain of the polymer. Among X⁹ to X¹², those that form a bond as a portion of the main chain of the polymer are direct bonds. Among X⁹, X¹⁰, X¹¹, and X¹², those that are not involved in polymerization are hydrogen atoms or monovalent substituents.

Among X⁹, X¹⁰, X¹¹, and X¹², specific examples and preferred examples of the monovalent groups that are not involved in polymerization are the same as specific examples and preferred examples of X⁵ and X⁶ of the boron-containing compound represented by formula (21).

In the boron-containing polymer represented by formula (26), any of X⁹, X¹⁰, X¹¹, and X¹² may be a direct bond, but it is preferred that X⁹ and X¹⁰ are direct bonds or X¹¹ and X¹² are direct bonds. In this case, the boron-containing polymer represented by formula (26) is a polymer having a repeating unit structure represented by formulae (28-1) or (28-2) below:

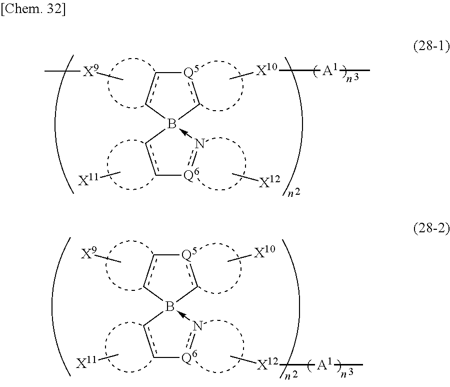

(in the formula, dotted arcs, dotted line portions of the backbone shown in solid lines, an arrow from a nitrogen atom to a boron atom, Q⁵, Q⁶, A¹, n², and n³ are as defined above for formula (26); in formula (28-1), X⁹ and X¹⁰ represents direct bonds, and X¹¹ and X¹² represents hydrogen atoms or monovalent substituents; and in formula (28-2), X¹¹ and X¹² represents direct bonds, and X⁹ and X¹⁰ represent hydrogen atoms or monovalent substituents).

The boron-containing polymer represented by formula (26) is preferably produced by reacting a boron-containing compound (26′) having a reactive group represented by formula (29) below:

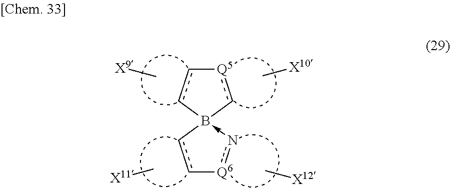

(in the formula, dotted arcs, dotted line portions of the backbone shown in solid lines, an arrow from a nitrogen atom to a boron atom, and Q⁵ and Q⁶ are as defined above for formula (26); and X^{9′}, X^{10′}, X^{11′}, and X^{12′}, which are the same or different, each represent a hydrogen atom or a monovalent substituent as a substituent in a ring structure, and at least two of X^{9′}, X^{10′}, X^{11′}, and X^{12′} are reactive groups that react with X¹³ or X¹⁴ in formula (30) below),
with a compound represented by formula (30):

X¹³-A¹-X¹⁴ (30)

(in the formula, A¹ is as defined above for formula (26); and X¹³ and X¹⁴ represent reactive groups).

The reaction between the boron-containing compound (26′) and the compound represented by formula (30) results in synthesis of the boron-containing polymer (26) by condensation polymerization.

Among X^{9′} to X^{12′}, monovalent substituents other than the reactive groups that react with X¹³ or X¹⁴ in formula (30) are the same as the monovalent substituents represented by X⁹ to X¹² in formula (26).

Preferred combinations of reactive groups that can undergo polycondensation are listed below. It is preferred that the boron-containing compound (26′) and the compound represented by formula (30) undergo condensation polymerization by a combination of any of these reactive groups that can undergo polycondensation.

Such combinations are as follows: boryl group and halogen atom; stannyl group and halogen atom; aldehyde group and phosphonium methyl group; vinyl group and halogen atom; aldehyde group and phosphonate methyl group; halogen atom and halogenated magnesium; halogen atom and halogen atom; halogen atom and silyl group; and halogen atom and hydrogen atom.

A¹ in formula (26) is not particularly limited as long as it is a divalent group. Any of an alkenyl group, an arylene group, and a divalent aromatic heterocyclic group are preferred.

The arylene group is an atomic group in which two hydrogen atoms are removed from an aromatic hydrocarbon. The number of carbon atoms forming the ring is usually about 6 to 60, preferably 6 to 20. Examples of the aromatic hydrocarbon also include those having a condensed ring and those having two or more independent benzene rings or condensed rings bonded together directly or via a group such as vinylene.

Examples of the arylene group include groups represented by formulae (31-1) to (31-23) below. Among these, a phenylene group, a biphenylene group, a fluorene-diyl group, and a stilbene-diyl group are preferred.

In formulae (31-1) to (31-23), each R may be the same or different and represents a hydrogen atom, a halogen atom, an alkyl group, an alkyloxy group, an alkylthio group, an alkylamino group, an aryl group, an aryloxy group, an arylthio group, an arylalkyl group, an arylalkyloxy group, an arylalkylthio group, an acyl group, an acyloxy group, an amide group, an imide group, an imine residue, an amino group, a substituted amino group, a substituted silyl group, a substituted silyloxy group, a substituted silylthio group, a substituted silylamino group, a monovalent heterocyclic group, a heteroaryloxy group, a heteroarylthio group, an arylalkenyl group, an arylethynyl group, a carboxyl group, an alkyloxycarbonyl group, an aryloxycarbonyl group, an arylalkyloxycarbonyl group, a heteroaryloxycarbonyl group, or a cyano group. A line crossing a ring structure as shown “x-y” in formula (31-1) indicates that the ring structure is directly bonded to an atom in a binding site to which the ring structure is bonded. Specifically, in formula (31-1), it means that one of carbon atoms forming the ring with a line “x-y” is directly bonded to an atom in a binding site to which the ring is bonded, and the binding position in the ring structure is not particularly limited. A line at a corner of a ring structure as shown “z-” in formula (31-10) indicates that the ring structure is directly bonded at this position to an atom in a binding site to which the ring structure is bonded. In addition, a line with “R” crossing a ring structure indicates that one or more R's may be bonded to the ring structure, and the binding position is also not limited. Further, in formulae (31-1) to (31-10) and (31-15) to (31-20), carbon atoms may be replaced by nitrogen atoms, and hydrogen atoms may be replaced by fluorine atoms.

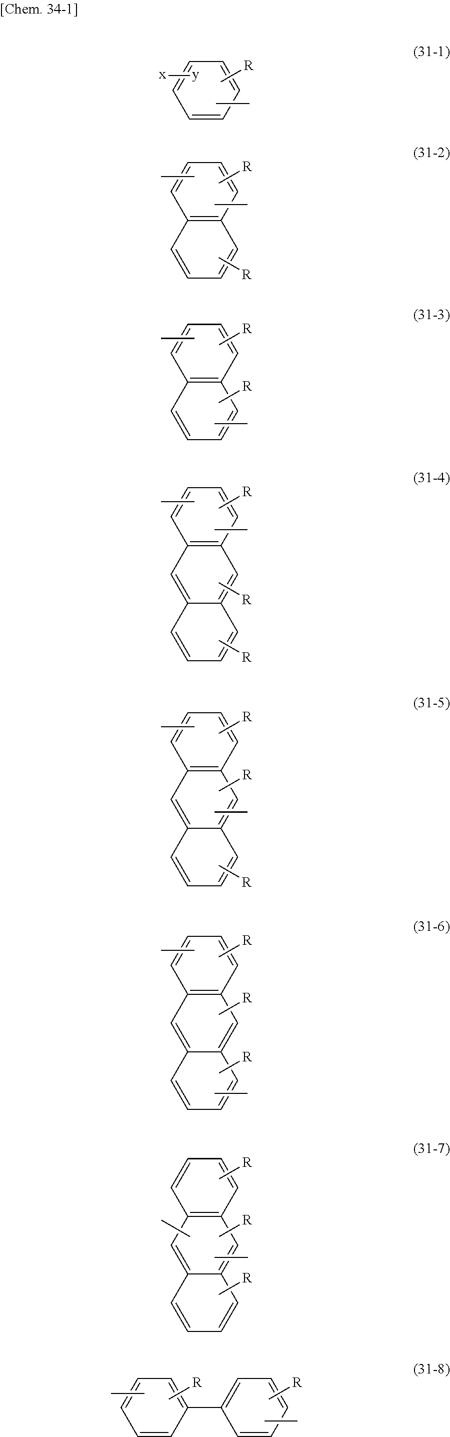

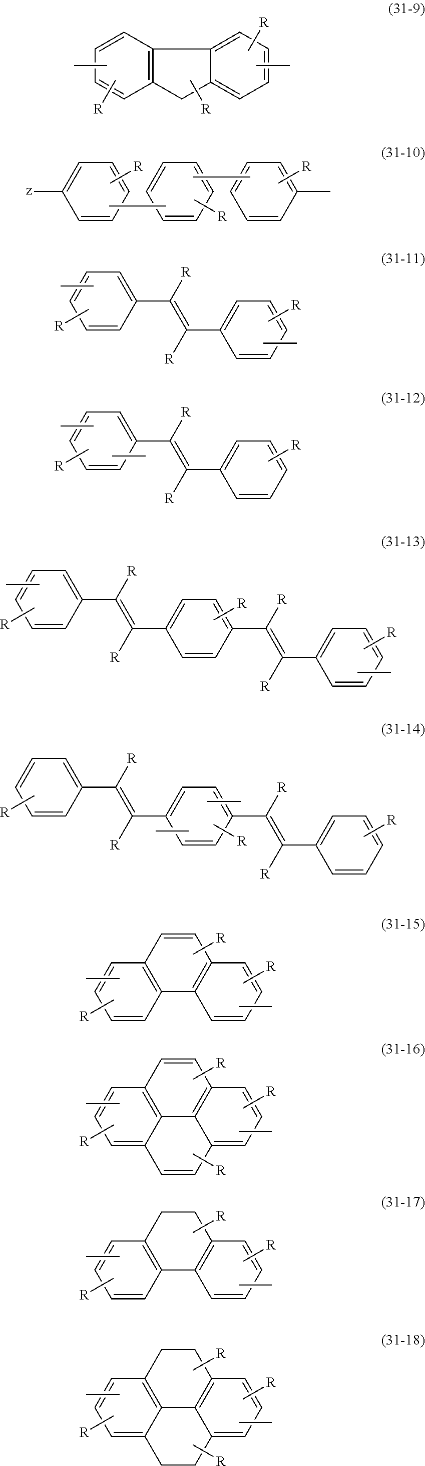

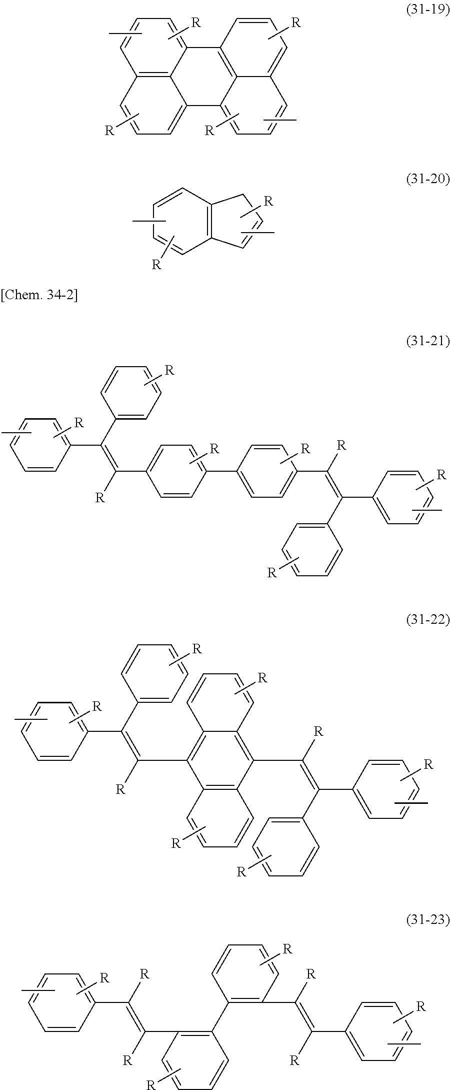

The divalent aromatic heterocyclic group is an atomic group in which two hydrogen atoms are removed from an aromatic heterocyclic compound. The number of carbon atoms forming the ring is usually about 3 to 60. Examples of the aromatic heterocyclic ring include aromatic organic compounds having a cyclic structure consisting of only carbon atoms and aromatic organic compounds having a cyclic structure containing a heteroatomsuch as oxygen, sulfur, nitrogen, phosphorus, boron, or arsenic.

Examples of the divalent heterocyclic group include heterocyclic groups represented by formulae (32-1) to (32-38) below. In formulae (32-1) to (32-38), each R is the same as R in the arylene group. Y represents O, S, SO, SO₂, Se, or Te. A line crossing a ring structure, a line at a corner of a ring structure, and a line with “R” crossing a ring structure are as defined above for formulae (31-1) to (31-23). In addition, in formulae (32-1) to (32-38), carbon atoms may be replaced by nitrogen atoms, and hydrogen atoms may be replaced by fluorine atoms.

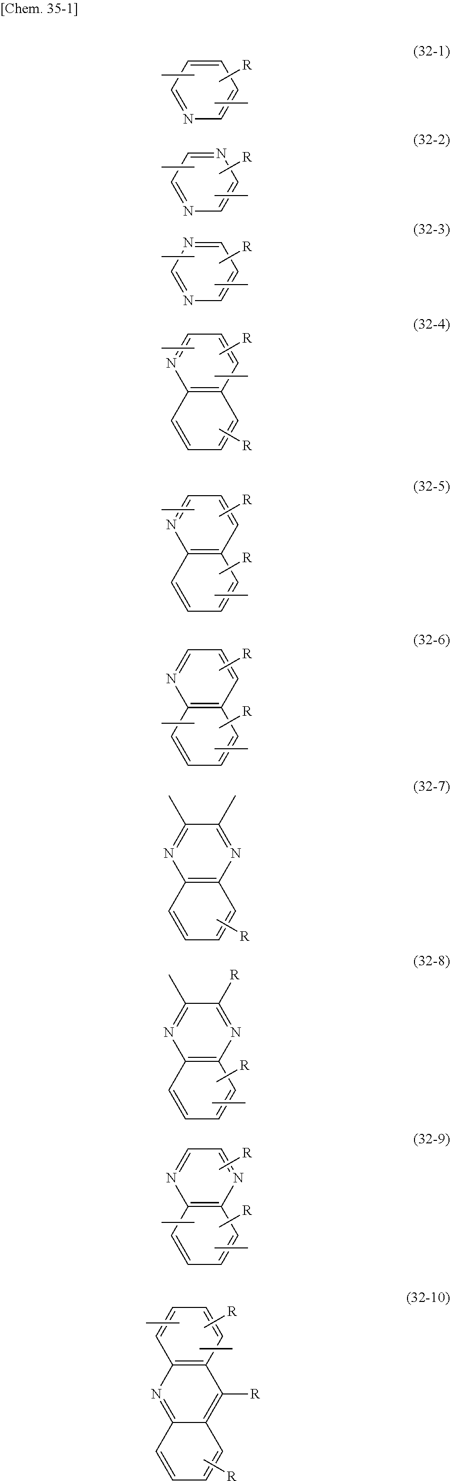

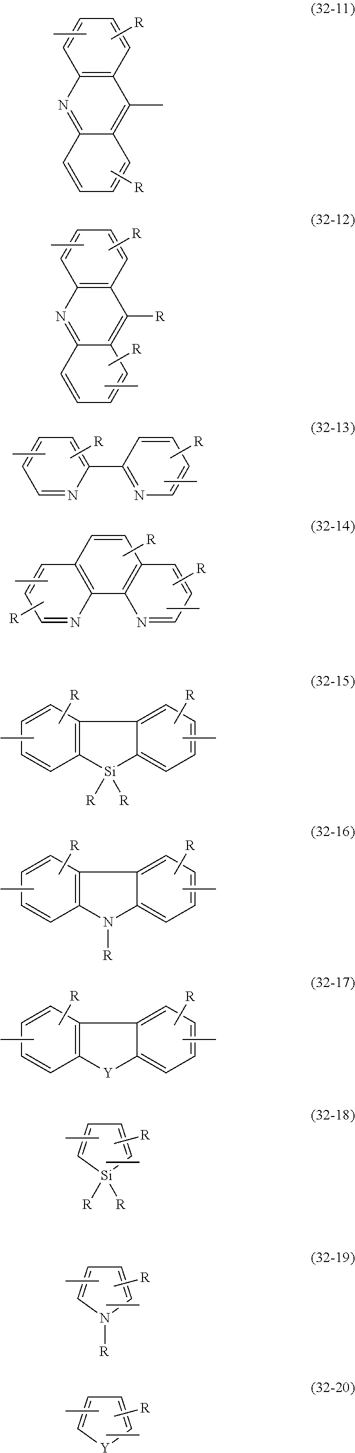

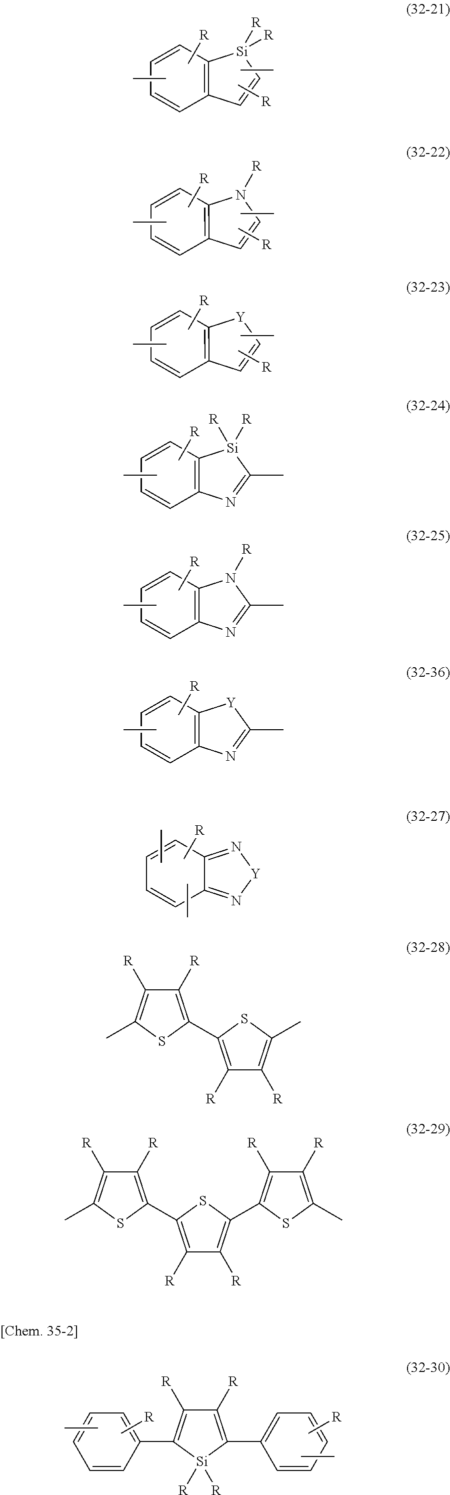

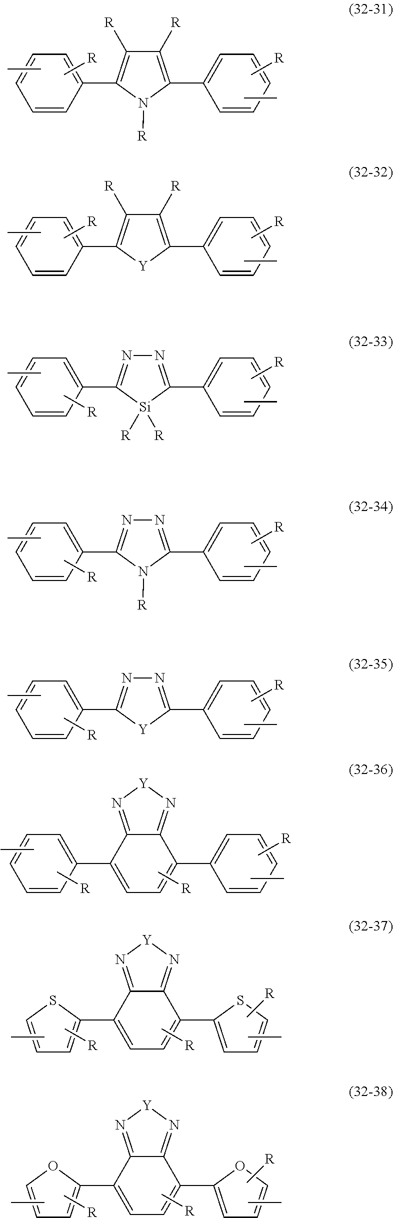

Among these, formulae (31-1), (31-9), (32-1), (32-9), (32-16), and (32-17) are preferred as A¹, for improving the film-forming properties by application of the boron-containing polymer represented by formula (26). Formulae (31-1) and (31-9) are more preferred.

The weight average molecular weight of the boron-containing polymer represented by formula (26) is preferably 5,000 to 1,000,000.

With the weight average molecular weight in this range, it is possible to successfully obtain a thin film. The weight average molecular weight is more preferably 10,000 to 500,000, still more preferably 30,000 to 200,000.

The weight average molecular weight can be measured by gel permeation chromatography (GPC system, developing solvent; chloroform) using polystyrene standards with the following device under the following measurement conditions.

High-speed GPC system: HLC-8220 GPC (available from Tosoh Corporation) was used for measurement.
Developing solvent: chloroform
Column: TSK-gel GMHXL×2 columns
Eluent flow rate: 1 ml/min
Column temperature: 40° C.

The boron-containing polymer represented by formula (26) can be produced, for example, by reacting a monomer component containing the boron-containing compound (26′) and the compound represented by formula (30).

The monomer component may contain other monomer(s) as long as the monomer component contains the boron-containing compound (26′) and the compound represented by formula (30). The total amount of the boron-containing compound (26′) and the compound represented by formula (30) is preferably 90% by mole or more relative to 100% by mole of the entire monomer component. The total amount is more preferably 95% by mole or more, most preferably 100% by mole. In other words, most preferably, the monomer component consists of only the boron-containing compound (26′) and the compound represented by formula (30).

Examples of the other monomer (s) include compounds having a reactive group that can react with the boron-containing compound (26′) or the compound represented by formula (30). The monomer component may contain one or more boron-containing compounds (26′) and one or more compounds represented by formula (30).

In the monomer component as a raw material of the boron-containing polymer represented by formula (26), the molar ratio of the boron-containing compound (26′) to the compound represented by formula (30) is preferably 100/0 to 10/90. The molar ratio is more preferably 70/30 to 30/70, most preferably 50/50.

In addition, during polymerization reaction, the solid concentration of the monomer component can be suitably set in the range of 0.01% by mass to the maximum dissolution concentration. If the solid concentration is too low, the reaction efficiency may be poor; while if the solid concentration is too high, the reaction may be difficult to control. Thus, the solid concentration is preferably 0.05 to 10% by mass.

The boron-containing polymer represented by formula (26) may be produced by any method, such as a production method disclosed in JP-A 2011-184430.

As described above, the boron-containing compound represented by formula (15) and the boron-containing compound represented by formula (21) can form a uniform film by an application method and have low HOMO and LUMO levels; the boron-containing compound represented by formula (21) also has electron transportability; and the boron-containing polymer represented by formula (26) has low HOMO and LUMO levels and better coating film-forming properties. Thus, these compounds can be suitably used as materials of the organic electroluminescence device of the present invention.

Besides the organic compounds described above, a polyamine or a triazine ring-containing compound can be used as a organic compound forming the buffer layer of the organic electroluminescence device of the present invention to achieve high electron-injection properties.

A polyamine that can form a coating layer by an application method is preferred, and may be a low-molecular compound or a high-molecular compound. As for a low-molecular compound, a polyalkylenepolyamine such as diethylenetriamine is preferred; and as for a high-molecular compound, a polymer having a polyalkyleneimine structure is preferred. A polyethyleneimine is particularly preferred.

The term “low-molecular compound” as used herein refers to a compound that is not a high-molecular compound (polymer), and does not necessarily refer to a low molecular weight compound.

As for the polymer having a polyalkyleneimine structure, the polyalkyleneimine structure is preferably a structure formed from C2-4 alkyleneimine. It is more preferably a structure formed from C2 or C3 alkyleneimine.

The polymer having the polyalkyleneimine structure is not limited as long as the polyalkyleneimine structure is present in the main chain, and it may be a copolymer having an additional structure besides the polyalkyleneimine structure in the main chain.

In the case where the polymer having the polyalkyleneimine structure in the main chain has an additional structure besides the polyalkyleneimine structure, examples of a monomer as a raw material of the additional structure besides the polyalkyleneimine structure include ethylene, propylene, butene, acetylene, acrylic acid, styrene, and vinylcarbazole. These can be used alone or in combination of two or more thereof. These monomers in which hydrogen atoms bonded to carbon atoms are replaced by other organic groups can also be suitably used. Examples of the other organic groups that replace hydrogen atoms include C1-10 hydrocarbon groups optionally containing at least one atom selected from the group consisting of an oxygen atom, a nitrogen atom, and a sulfur atom.

As for the polymer having the polyalkyleneimine structure, the amount of a monomer forming the polyalkyleneimine structure is preferably 50% by mass or more in 100% by mass of the monomer component forming the main chain of the polymer. The amount is more preferably 66% by mass or more, still more preferably 80% by mass or more. Most preferably, the amount of a monomer forming the polyalkyleneimine structure is 100% by mass. In other words, most preferably, the polymer having the polyalkyleneimine structure is a homopolymer of polyalkyleneimine.

The weight average molecular weight of the polymer having the polyalkyleneimine structure in the main chain is preferably 100000 or less. An organic electroluminescence device having better driving stability can be obtained by forming a layer from a polymer having a weight average molecular weight in the above range and carrying out heat treatment at a temperature at which the polymer is dissolved. The weight average molecular weight is more preferably 10000 or less, still, more preferably 100 to 1000.

The weight average molecular weight can be measured by gel permeation chromatography (GPC) under the following conditions.

Measurement system: Waters Alliance (2695) (product name, available from Waters)
Molecular weight column: TSK guard column α, TSK gel α-3000, TSK gel α-4000, and TSK gel α-5000 (all available from Tosoh Corporation) connected in series
Eluent: a solution in which an aqueous solution (96 g) of 50 mM sodium hydroxide and acetonitrile (3600 g) are mixed in an aqueous solution (14304 g) of 100 mM boric acid.
Standard substance for calibration curve: polyethylene glycol (available from Tosoh Corporation)
Measurement method: an object to be measured is dissolved in the eluent in such a manner that the solid content is about 0.2% by mass, and the filtrate that has passed through the filter is used as a measurement sample for measurement of the molecular weight.

Examples of the triazine ring-containing compound include compounds such as melamine and guanamines such as benzoguanamine and acetoguanamine; methylolated melamine and methylolated guanamines; and compounds having a melamine or guanamine backbone such as melamine or guanamine resins. These can be used alone or in combination of two or more thereof, and melamine is preferred among these.

Preferred examples of the organic compound forming the buffer layer of the organic electroluminescence device of the present invention also include polymers having repeating units of structures represented by formulae (33) to (41) below, triethylamine represented by formula (42), and ethylenediamine represented by formula (43).

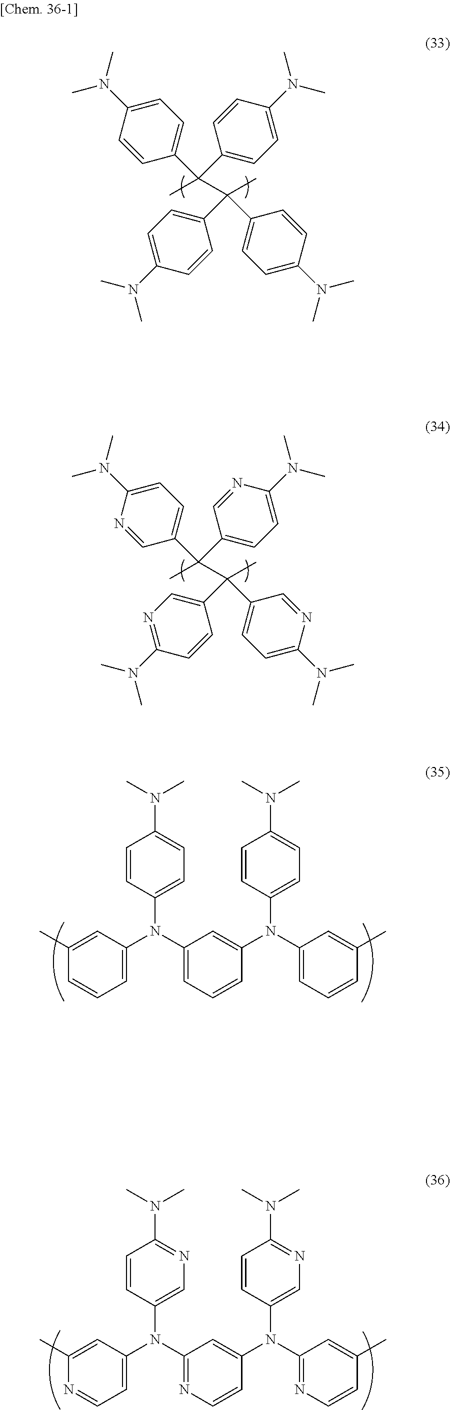

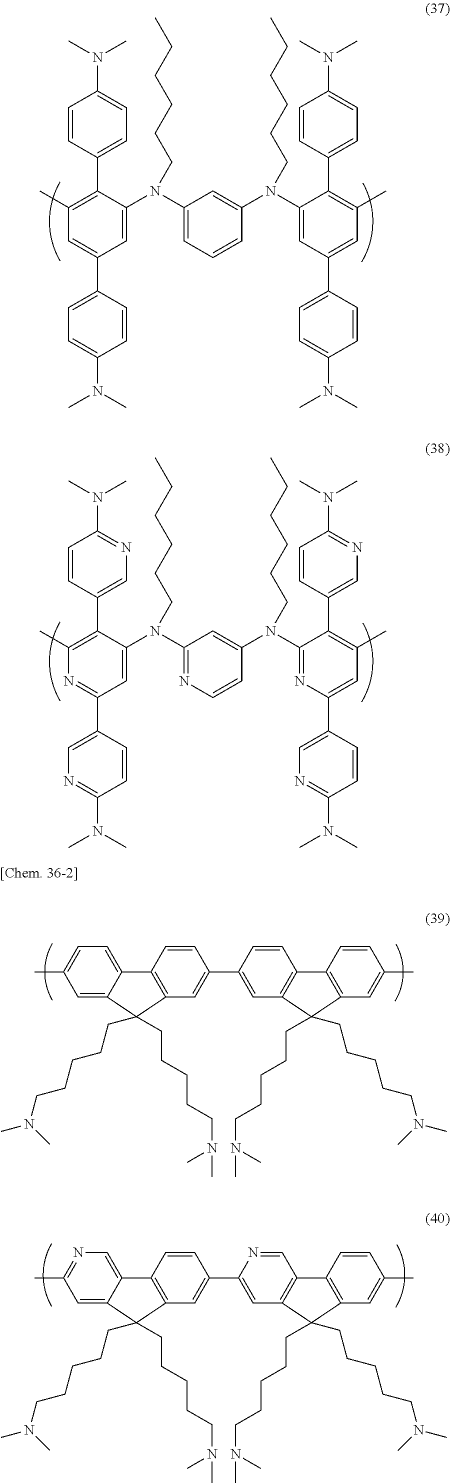

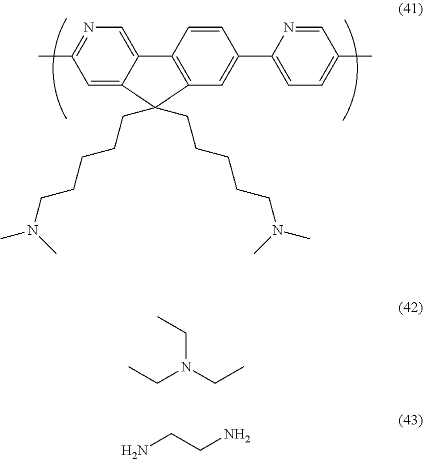

The buffer layer may contain a reducing agent. The reducing agent acts as an n-dopant so that the electrons can be sufficiently supplied from the cathode to the emitting layer due to the reducing agent in the buffer layer, resulting in improved luminous efficiency.

The reducing agent in the buffer layer is not particularly limited as long as it is an electron-donating compound. Examples thereof include 2,3-dihydrobenzo[d]imidazole compounds such as 1,3-dimethyl-2,3-dihydro-1H-benzo[d]imidazole, 1,3-dimethyl-2-phenyl-2,3-dihydro-1H-benzo[d]imidazole, (4-(1,3-dimethyl-2,3-dihydro-1H-benzimidazol-2-yl)phenyl)di methylamine (N-DMBI), and 1,3,5-trimethyl-2-phenyl-2,3-dihydro-1H-benzo[d]imidazole; 2,3-dihydrobenzo[d]thiazole compounds such as 3-methyl-2-phenyl-2,3-dihydrobenzo[d]thiazole; 2,3-dihydrobenzo[d]oxazole compounds such as 3-methyl-2-phenyl-2,3-dihydrobenzo[d]oxazole; triphenylmethane compounds such as leuco crystal violet (=tris(4-dimethylaminophenyl)methane), leucomalachite green (=bis(4-dimethylaminophenyl)phenylmethane), and triphenylmethane; and dihydropyridine compounds such as 2,6-dimethyl-1,4-dihydropyridine-3,5-dicarboxylic acid diethyl (Hantzsch ester). These can be used alone or in combination of two or more thereof. Among these, a 2,3-dihydrobenzo[d]imidazole compound and a dihydropyridine compound are preferred. (4-(1,3-Dimethyl-2,3-dihydro-1H-benzimidazol-2-yl)phenyl)di methylamine (N-DMBI) or 2,6-dimethyl-1,4-dihydropyridine-3,5-dicarboxylic acid diethyl (Hantzsch ester) is more preferred.

The amount of the reducing agent in the buffer layer is preferably 0.1 to 15% by mass relative to 100% by mass of the organic compound forming the buffer layer. The organic electroluminescence device achieves sufficiently high luminous efficiency due to the reducing agent in the above amount. The amount is more preferably 0.5 to 10% by mass, still more preferably 0.5 to 5% by mass, relative to 100% by mass of the organic compound forming the buffer layer.

The electroluminescence device of the present invention can emit light by applying a voltage (usually, 15 V or less) between the anode and the cathode. Usually, a direct current voltage is applied, but a voltage having an alternating current component may be included.

While the organic electroluminescence device of the present invention is simply sealed compared to the conventional organic electroluminescence device that is strictly sealed, the device of the present invention has a good continuous operation life and storage stability. In addition, it is possible to change the color of the light by suitably selecting a material of the organic compound layer of the organic electroluminescence device, and it is also possible to obtain a desired color of the light by using a color filter or the like in combination. Thus, the organic electroluminescence device of the present invention can be suitably used as a material of a display device or a lighting system.

Such a display device formed with the organic electroluminescence device of the present invention is also encompassed by the present invention. A lighting system formed with the organic electroluminescence device of the present invention is also encompassed by the present invention.

### Advantageous Effects of Invention

Owing to the above-described structure, the organic electroluminescence device of the present invention can achieve a good continuous operation life and storage stability without requiring strict sealing which would be required in conventional organic electroluminescence devices. In addition, properties such as luminescence properties can be further enhanced owing to a preferred material of the emitting layer and a preferred layer structure of the device as described above. Thus, the device can be suitably used as a material of a display device or a lighting system.

### BRIEF DESCRIPTION OF DRAWINGS

FIG. 1 is a schematic view showing an example of the structure of an organic electroluminescence device including a sealing structure of the present invention.

FIG. 2 is a graph showing ¹H-NMR measurement results of a boron-containing polymer C produced in Synthesis Example 5.

FIG. 3 shows images of EL emission of an organic electroluminescence device 1 produced in Example 1 at day 1, day 12, day 80, and day 336 at 6 V (the images attached show EL emission at 5 V).

FIG. 4 shows images of EL emission of an organic electroluminescence device 3 produced in Example 2 at day 1, day 14, and day 93 at 4 V (the images attached show EL emission at 3 V or 3.3 V).

FIG. 5 shows images of EL emission of an organic electroluminescence device 4 produced in Comparative Example 1 at day 1, day 14, and day 93 at 4 V (the images attached show EL emission at 3 V).

FIG. 6 shows images of EL emission of an organic electroluminescence device 4 produced in Example 3 at day 2, day 12, and day 80 at 6 V.

FIG. 7 shows images of EL emission of an organic electroluminescence device 5 produced in Example 4 at day 1, day 12, day 80, day 336, and day 384 at 6 V.

FIG. 8 shows images of EL emission of an organic electroluminescence device 7 produced in Example 6 at day 1 and day 17 at 6 V.

FIG. 9 shows images of EL emission of an organic electroluminescence device 8 produced in Comparative Example 2 at day 7 at 6 V.

FIG. 10 is a graph showing voltage-luminance properties of the organic electroluminescence device 5 produced in Example 4 immediately after sealing A (initial period), immediately after sealing B (initial period), and at day 398.

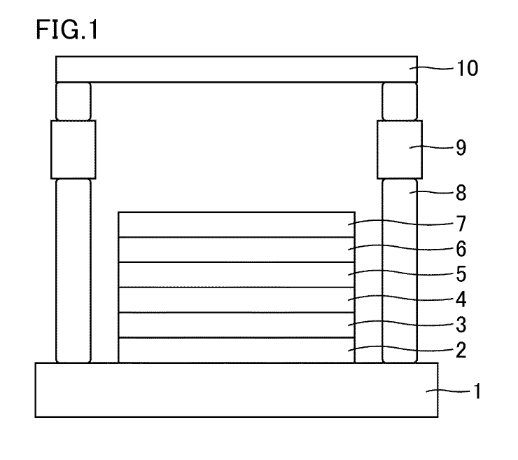

### DESCRIPTION OF EMBODIMENTS

The present invention is described in more detail with reference to examples below, but the present invention is not limited to these examples. Herein, “part(s)” means “part(s) by weight” and “%” means “% by mass” unless otherwise stated.

### Synthesis Example 1

### Synthesis of Boron-Containing Compound A

A 100-mL two-necked recovery flask was charged with 2-(dibenzoborolyl phenyl)-5-bromopyridine (2.6 g, 6.5 mmol), 2,7-bis(4,4,5,5-tetramethyl-1,3,2-dioxaborolanyl)-9,9′-spirofluorene (1.5 g, 2.7 mmol), and Pd (P^{t}Bu₃)₂ (170 mg, 0.32 mmol). The flask was purged with nitrogen and charged with THF (65 mL), followed by stirring.

To the flask was added an aqueous solution (11 mL, 22 mmol) of 2 M tripotassium phosphate, and the mixture was heated with stirring under reflux at 70° C. After 12 hours, the reaction solution was cooled to room temperature and transferred to a separating funnel to which water was added to extract an organic layer with ethyl acetate. The organic layer was washed with 3 N hydrochloric acid, water, and saturated saline solution, and then dried with magnesium sulfate. The filtrate that passed through a filter was concentrated, and the resulting solid was washed with methanol. Thus, 2,7-bis(3-dibenzoborolyl-4-pyridyl phenyl)-9,9′-spirofluorene (a boron-containing compound A) was obtained at a yield of 47% (1.2 g, 1.3 mmol).

Physical properties were as follows:

¹H-NMR (CDCl₃): δ6.67 (d, J=7.6 Hz, 2H), 6.75 (d, J=1.2 Hz, 2H), 6.82 (d, J=7.2 Hz, 4H), 6.97 (dt, J=7.2, 1.2 Hz, 4H), 7.09 (dt, J=7.2, 0.8 Hz, 2H), 7.24-7.40 (m, 14H), 7.74-7.77 (m, 6H), 7.84-7.95 (m, 10H).

The reaction in Synthesis Example 1 is represented as in reaction formula (44) below:

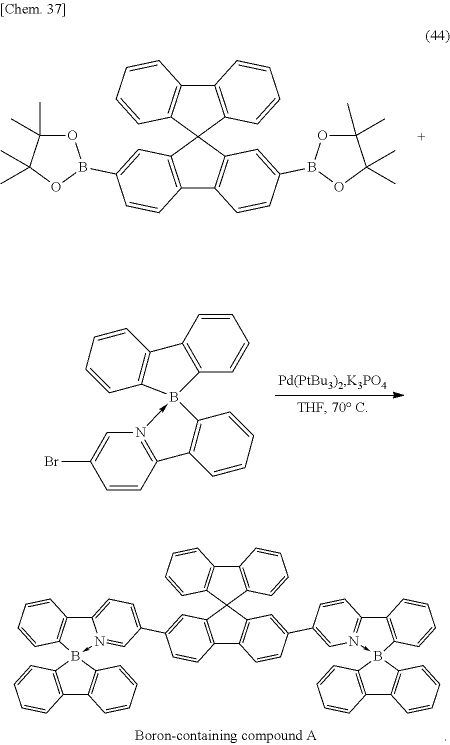

### Synthesis Example 2

### Synthesis of Boron Compound 1

Under an argon atmosphere, ethyldiisopropylamine (39 mg, 0.30 mmol) was added to a dichloromethane solution (0.3 ml) containing 5-bromo-2-(4-bromophenyl)pyridine (94 mg, 0.30 mmol), and then boron tribromide (1.0 M dichloromethane solution, 0.9 ml, 0.9 mmol) was added to the mixture at 0° C., followed by stirring for 9 hours at room temperature. After cooling to 0° C., an aqueous solution of saturated potassium carbonate was added to the reaction solution, followed by extraction with chloroform. The organic layer was washed with saturated saline solution, dried with magnesium sulfate, and filtered. The filtrate was concentrated with a rotary evaporator, and the resulting white solid was obtained by filtration, which was then washed with hexane. Thus, a boron compound 1 (40 mg, 0.082 mmol) was obtained at a yield of 28%. This reaction is represented by formula (45) below.

Physical properties were as follows:

¹H-NMR (CDCl₃): 7.57-7.59 (m, 2H), 7.80 (dd, J=8.4, 0.6 Hz, 1H), 7.99 (s, 1H), 8.27 (dd, J=8.4, 2.1 Hz, 1H), 9.01 (d, J=1.5 Hz, 1H).

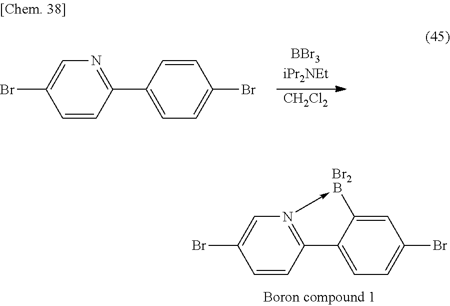

### Synthesis Example 3

### Synthesis of Boron Compound 2

A 50-mL two-necked flask was charged with magnesium (561 mg, 23.1 mmol), and the reaction vessel was purged with nitrogen. Subsequently, cyclopentyl methyl ether (10 mL) was placed in the reaction vessel and a small portion of iodine was placed therein, followed by stirring until the color disappeared. A solution (9 mL) of 2,2′-dibromobiphenyl (3.0 g, 9.6 mmol) in cyclopentyl methyl ether was added dropwise thereof, followed by stirring at room temperature for 12 hours and at 50° C. for 1 hour. Thus, Grignard reagent was prepared.

The boron compound 1 (3.71 g, 7.7 mmol) was placed in a different 200-mL three-necked flask, which was then purged with nitrogen. Subsequently, toluene (77 mL) was added. While stirring the mixture at −78° C., the Grignard reagent was added collectively through a cannula. After stirring for 10 minutes, the mixture was heated to room temperature and stirred for additional 12 hours. Water was added to the resulting reaction solution, and an organic layer was extracted with toluene. The organic layer was washed with saturated saline solution, dried with magnesium sulfate, and filtered. The filtrate was concentrated and the residue was purified by column chromatography. Thus, a boron compound 2 (3.0 g) was obtained (a yield of 82%). This reaction is represented by formula (46) below.

Physical properties were as follows:

¹H-NMR (CDCl₃): 6.85 (d, J=7.04 Hz, 2H), 7.05 (t, J=7.19 Hz, 2H), 7.32 (t, J=7.48 Hz, 2H), 7.47 (s, 1H) 7.49-7.57 (m, 1H), 7.74-7.84 (m, 3H), 7.90-8.00 (m, 2H), 8.07-8.20 (m, 1H).

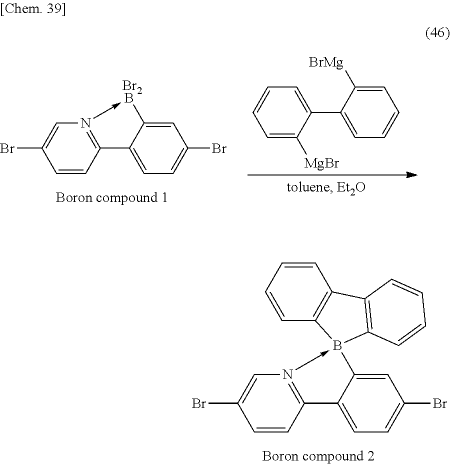

### Synthesis Example 4

### Synthesis of Boron-Containing Compound B

A 100-mL two-necked flask was charged with the boron compound 2 (2.0 g, 4.2 mmol) and Pd (PPh₃)₄ (240 mg, 0.21 mmol), and the reaction vessel was purged with nitrogen. Toluene (21 mL) and tributyl(2-pyridyl) tin (3.7 g, 10.1 mmol) were added thereto, followed by stirring at 120° C. overnight. After the reaction was completed, the resulting product was concentrated, and the residue was purified by column chromatography. Thus, a boron-containing compound B of the present invention (800 mg) was obtained (a yield of 40%). This reaction is represented by formula (47) below.

Physical properties were as follows:

¹H-NMR (CDCl₃): 6.93 (m, J=7.04 Hz, 2H), 7.03 (t, J=7.19 Hz, 2H), 7.13-7.20 (m, 1H), 7.21-7.26 (m, 1H), 7.30 (t, J=7.48 Hz, 2H), 7.51 (d, J=7.92 Hz, 1H), 7.60-7.74 (m, 3H), 7.82 (m, J=7.63 Hz, 2H), 7.87 (s, 1H), 8.12 (d, J=8.22 Hz, 1H), 8.18 (d, J=7.92 Hz, 1H), 8.22 (d, J=8.51 Hz, 1H), 8.39 (s, 1H), 8.59-8.69 (m, 2H), 8.76 (dd, J=8.51, 1.17 Hz, 1H).

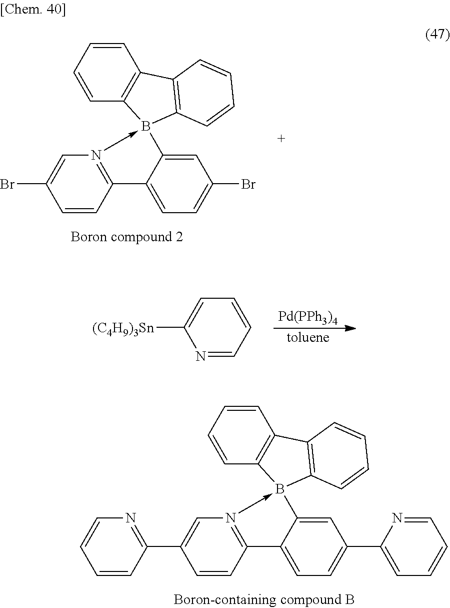

### Synthesis Example 5

### Synthesis of Boron-Containing Compound C (Boron-Containing Polymer)

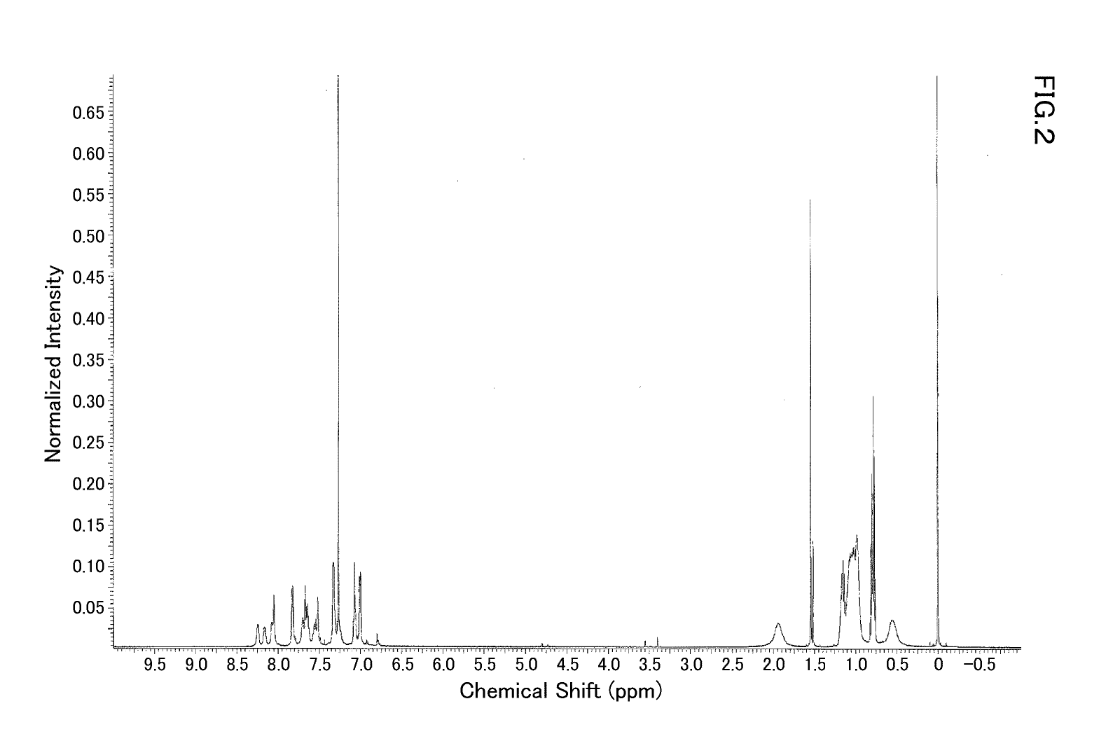

A Schlenk flask was charged with the boron compound 2 (474 mg, 1.00 mmol) and 9,9-dioctylfluorene-2,7-boronic acid-bis(propanediol) ester, (568 mg, 1.02 mmol), and the reaction vessel was purged with nitrogen. Subsequently, THF (6 mL) was added to the mixture and dissolved therein. To the resulting product were added 35 wt % tetraethylammonium hydroxide (1.68 mL, 3.99 mmol) water (2.2 mL), and a solution (6 mL) of Aliquat (registered trademark) (40 mg, 0.10 mmol) in toluene. The mixture was heated at 90° C., and Pd (PPh₃)₄ (23 mg, 0.020 mmol) was added thereto, followed by stirring at 90° C. for 12 hours. Bromobenzene (204 mg, 1.30 mmol) was added thereto, followed by stirring for 5 hours. Subsequently, phenylboronic acid (572 mg, 4.69 mmol) was added thereto, followed by stirring overnight. After cooling to room temperature, the reaction solution was diluted with toluene, and the organic layer was washed with water and dried with magnesium sulfate. After filtration and concentration, the residue was dissolved in chloroform and passed through a silica gel short column. This solution was concentrated, and yellow precipitate obtained by adding the concentrate to methanol was filtered. Thus, a boron-containing compound C (boron-containing polymer) (386 mg) was obtained. This reaction is represented by formula (48) below. FIG. 2 shows ¹H-NMR measurement results of the boron-containing compound C.

Properties of the obtained boron-containing polymer were as follows: Mn was 14,304; Mw was 36,646; and PDI was 2.56.

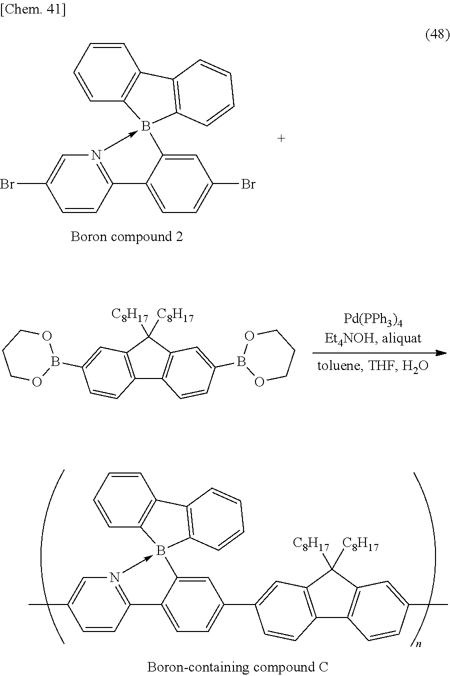

### Example 1

[1] A commercially available transparent glass substrate having an ITO electrode layer of an average thickness of 0.7 mm was provided. At this point, a substrate with an ITO electrode (cathode) patterned to have a width of 2 mm was used. This substrate was ultrasonically washed in acetone and isopropanol each for 10 minutes and then boiled in isopropanol for 5 minutes. This substrate was taken out from isopropanol, dried by blowing nitrogen, and washed with UV ozone for 20 minutes.

[2] This substrate was fixed to a substrate holder of a mirrortron sputtering apparatus having a zinc metal target. After the pressure was decreased to about 1×10⁻⁴ Pa, sputtering was carried out while introducing argon and oxygen. Thus, a zinc oxide layer having a thickness of about 2 nm was produced. At this point, a metal mask was also used to prevent the formation of a zinc oxide layer on a portion of the ITO electrode for leading out electrodes.

[3] As a buffer layer, a mixed solution of 1% by weight of the boron-containing compound A and 0.01% by weight of (4-(1,3-dimethyl-2,3-dihydro-1H-benzimidazol-2-yl)phenyl)di methylamine (N-DMBI) in 1,2-dichloroethane was prepared. The substrate having a thin zinc oxide film produced in step [2] was set in a spin coater. The mixed solution of the boron-containing compound A and N-DMBI was dropped onto the substrate, and the substrate was rotated at 2000 rpm for 30 seconds to form a buffer layer containing a boron-containing organic compound. Further, the substrate was annealed for 1 hour on a hot plate at 100° C. under a nitrogen atmosphere. The buffer layer had an average thickness of 30 nm.

[4] The substrate in which the zinc oxide layer and the boron-containing compound layer was formed was fixed to a substrate holder of a vacuum deposition apparatus. Bis[2-(2′-hydroxyphenyl)pyridine]beryllium (Bepp₂), tris[3-methyl-2-phenylpyridine]iridium(III) (Ir(mpy)₃), and N,N′-di(1-naphthyl)-N,N′-diphenyl-1,1′-biphenyl-4,4′-diamine (α-NPD) were separately placed in alumina crucibles and set in a deposition source. The vacuum deposition apparatus was depressurized to about 1×10⁻⁵ Pa, and Bepp₂ as a host and (Ir(mpy)₃) as a dopant were co-deposited to a thickness of 35 nm to form an emitting layer. At this point, the dope concentration was controlled such that (Ir(mpy)₃) would be 6% relative to the entire emitting layer. Next, α-NPD was deposited to a thickness of 60 nm to forma hole transport layer. Next, after purging with nitrogen once, molybdenum trioxide and gold were placed in alumina crucibles, which were then set in a deposition source. The vacuum deposition apparatus was depressurized to about 1×10⁻⁵ Pa, and molybdenum trioxide (second metal oxide layer) was deposited to a thickness of 10 nm. Next, gold (anode) was deposited to a thickness of 50 nm. Thus, an organic electroluminescence device 3 was produced. During deposition of a second electrode, a stainless steel deposition mask was used to obtain a band-like deposition surface having a width of 2 mm. Specifically, the produced organic electroluminescence device had an emitting area of 4 mm².

[5] UV curing resin was applied to a peripheral area (i.e., a region outside the device forming area and inside the substrate) of the device produced so far up to step [4], and a glass frame of the same size as the peripheral area was placed thereon. Further, UV curable resin was applied to the glass frame, and lastly, a sealing film (a water vapor transmission rate of 3×10⁻⁴ g/m²·day, available from OIKE & Co., Ltd.) was bonded thereto, followed by UV curing. Thus, the organic electroluminescence device 1 was produced.

### Example 2

An organic electroluminescence device 2 was produced in the same manner as in Example 1, except that step [3] was carried out as in step [3-2] described below. The buffer layer had an average thickness of 6 nm.

[3-2] Next, as a buffer layer, a dilute solution (0.5% by weight) of polyethyleneimine (registered trademark: EPOMIN, available from NIPPON SHOKUBAI CO., LTD.) in ethanol was spin-coated at 2000 rpm for 30 seconds. EPOMIN P1000 having a molecular weight of 70000 was used.

### Comparative Example 1

An organic electroluminescence device 3 was produced in the same manner as in Example 2, except that in step [5] of Example 2, glass instead of the sealing film (water vapor transmission rate 3×10⁻⁴ g/m²·day, available from OIKE & Co., Ltd.) was used as a sealing substrate.

### Example 3

An organic electroluminescence device 4 was produced in the same manner as in Example 1, except that in step [3] of Example 1, the buffer layer was formed to have an average thickness of 60 nm.

### Example 4

An organic electroluminescence device 5 was produced in the same manner as in Example 1, except that in step [3] of Example 1, the buffer layer was formed to have an average thickness of 10 nm.

### Example 5

An organic electroluminescence device 6 was produced in the same manner as in Example 1, except that step [3] was carried out as in step [3-3] described below. The buffer layer had an average thickness of 10 nm.

[3-3] Next, as a buffer layer, a dilute solution (0.25% by weight) of the boron-containing compound A in 1,2-dichloroethane without addition of a reducing agent was spin-coated at 2000 rpm for 30 seconds.

### Example 6

An organic electroluminescence device 7 was produced in the same manner as in Example 5, except that in step [5] of Example 5, a film (water vapor transmission rate 3×10⁻³ g/m²·day, available from OIKE & Co., Ltd.) instead of the sealing film (water vapor transmission rate 3×10⁻⁴ g/m²·day, available from OIKE & Co., Ltd.) was used as a sealing substrate.

### Comparative Example 2

An organic electroluminescence device 8 was produced in the same manner as in Example 1, except that step [3] was carried out as in step [3-4] described below, and that in [5], a film (water vapor transmission rate 5×10⁻² g/m²·day, available from OIKE & Co., Ltd.) instead of the sealing film (water vapor transmission rate 3×10⁻⁴ g/m²·day, available from OIKE & Co., Ltd.) was used as a sealing substrate. The buffer layer had an average thickness of 30 nm.

[3-4] Next, as a buffer layer, a dilute solution (1% by weight) of the boron-containing compound B in tetrahydrofuran without addition of a reducing agent was spin-coated at 2000 rpm for 30 seconds.

### Example 7

An organic electroluminescence device 9 was produced in the same manner as in Comparative Example 2, except that in step [5] of Comparative Example 2, a film (water vapor transmission rate 3×10⁻⁴ g/m²·day, available from OIKE & Co., Ltd.) instead of the sealing film (water vapor transmission rate 5×10⁻² g/m²·day, available from OIKE & Co., Ltd.) was used as a sealing substrate.

### Example 8

An organic electroluminescence device 10 was produced in the same manner as in Comparative Example 2, except that in step [5] of Comparative Example 2, a film (water vapor transmission rate 3×10⁻³ g/m²·day, available from OIKE & Co., Ltd.) instead of the sealing film (water vapor transmission rate 5×10⁻² g/m²·day, available from OIKE & Co., Ltd.) was used as a sealing substrate.

### Comparative Example 3

An organic electroluminescence device 11 was produced in the same manner as in Example 5, except that in step [3-3] of Example 5, the buffer layer was formed to have an average thickness of 30 nm, and that a film (water vapor transmission rate 2×10⁻¹ g/m²·day, available from OIKE & Co., Ltd.) was used instead of the sealing film (water vapor transmission rate 3×10⁻⁴ g/m²·day, available from OIKE & Co., Ltd.) as a sealing substrate.

### Example 9

An organic electroluminescence device 12 was produced in the same manner as in Example 1, except that step [3] of Example 1 was carried out as in step [3-5] described below. The buffer layer had an average thickness of 30 nm.

[3-5] Next, as a buffer layer, a dilute solution (1% by weight) of the boron-containing compound C in 1,2-dichloroethane without addition of a reducing agent was spin-coated at 2000 rpm for 30 seconds.

### Example 10

An organic electroluminescence device 13 was produced in the same manner as in Example 1, except that step [1] of Example 1 was carried out as in [1-2] described below.

[1-2] A commercially available polyethylene naphthalate film substrate (coated with a barrier to provide a water vapor transmission rate of 10⁻⁴ g/m²·day) having an ITO electrode layer was provided. At this point, a substrate with an ITO electrode (cathode) patterned to have a width of 2 mm was used. A protection film was removed from this substrate. After ultrasonically washing in isopropanol for 10 minutes, this substrate was taken out from isopropanol, dried by blowing nitrogen, and washed with UV ozone for 20 minutes.

### (Observation of Emission of Organic Electroluminescence Devices)

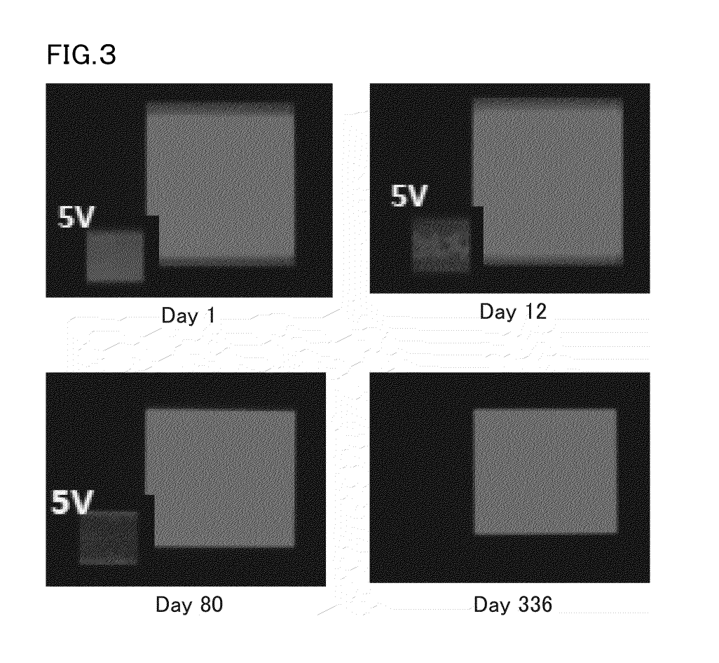

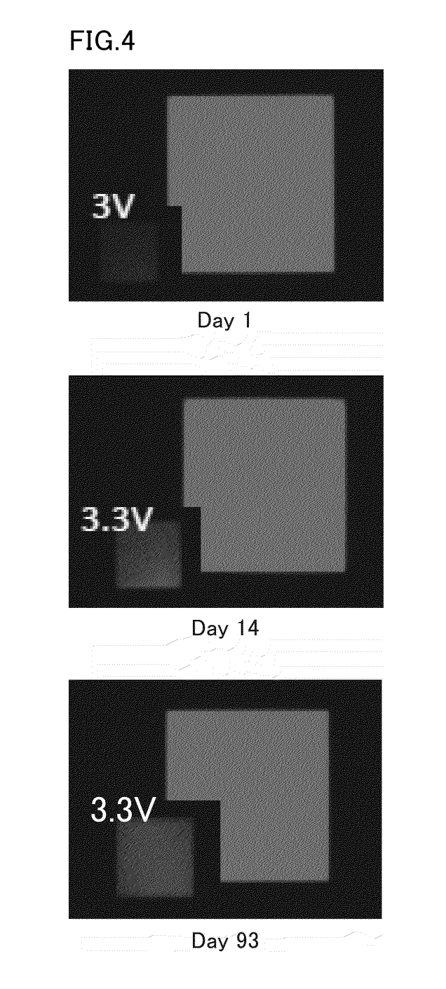

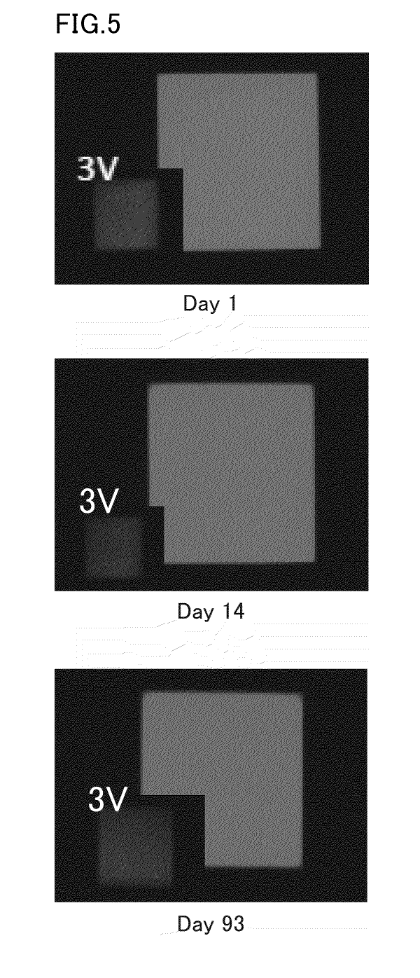

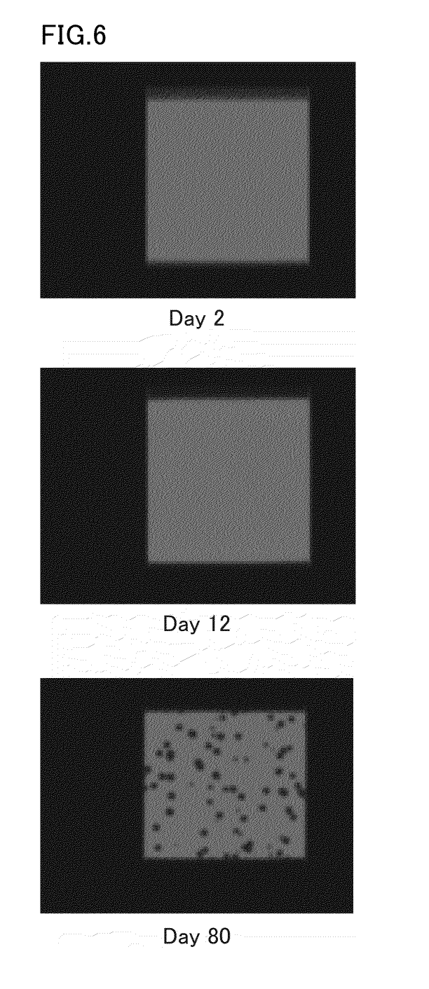

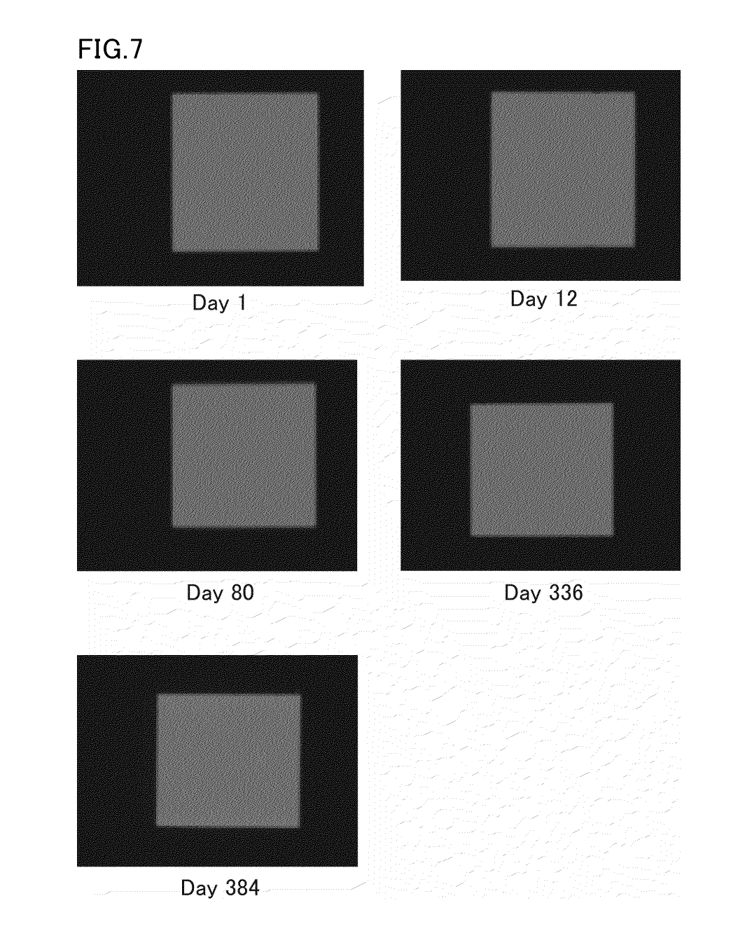

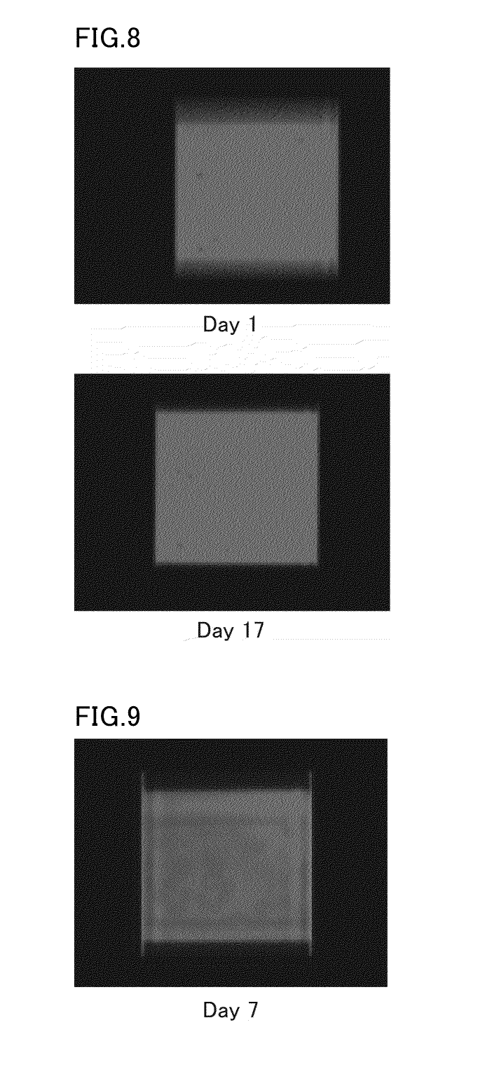

“Model 2400 SourceMeter” available from Keithley Instruments was used to apply a voltage to the devices. Each device was left to stand in air for a specified period of time, and then EL emission was photographed. FIGS. 3 to 9 show results of the organic electroluminescence devices 1 to 5, 7, and 8, respectively.

### (Measurement of Luminescence Properties of Organic Electroluminescence Devices)

The emission of the organic electroluminescence device 5 produced in Example 4 were measured at two different emission areas A and B immediately after sealing (initial period) and at day 398 using “Model 2400 SourceMeter” available from Keithley Instruments for voltage application to the device and for measurement of the current. The luminance was also measured with “LS-100” available from Konica Minolta, Inc.

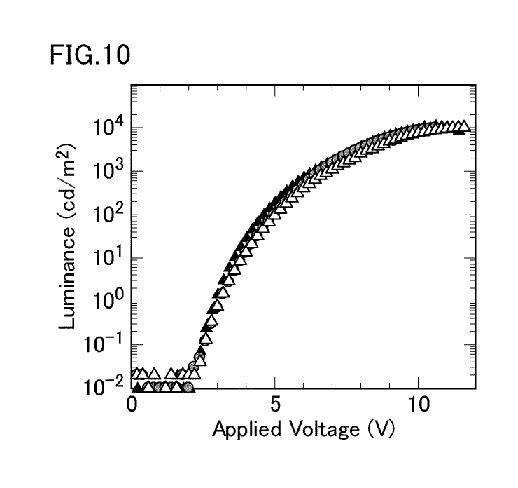

FIG. 10 shows voltage-luminance properties of the organic electroluminescence device when a direct current voltage was applied thereto under an argon atmosphere.

Examples 1, 3, and 4 in which the boron compound A doped with a reducing agent was used as a buffer layer showed no large dark spots until day 12 with a sealing film having a water vapor transmission rate of 3×10⁻⁴ g/m²·day. In particular, Examples 1 and 4 in which the buffer layers having an average thickness of 30 nm and 10 nm were used showed no large dark spots until after day 336 and 384, respectively. In addition, Example 4 also showed that the voltage-luminance properties remained the same between the initial period and day 398.

Also in Example 6 in which the boron compound A without a reducing agent was used as a buffer layer and a sealing film having a water vapor transmission rate 3×10⁻³ g/m²·day was used for sealing, while dark spots from stain were present in the initial period, these dark spots did not seem to increase in size even after day 17. Good results were obtained also in Example 5 in which the same boron compound A without a reducing agent as in Example 6 was used and the same sealing film as in Example 1 was used for sealing in which the water vapor transmission rate of the sealing film was lower than that of the sealing film used in Example 6.

In contrast, Comparative Example 2 in which a sealing film having a water vapor transmission rate of 5×10⁻² g/m²·day was used for sealing showed dim portions (not non-emitting portions) at day 7, and emission irregularities and a decrease in luminance were clearly observed. In addition, Comparative Example 3 in which a sealing film having a higher water vapor transmission rate than the sealing film of Comparative Example 2 was used showed more prominent dim portions at day 7.

Good results were obtained in Examples 7 and 8 in which a sealing film having an improved water vapor transmission rate was used in the device structure of Comparative Example 2, and these examples also showed long-term storage stability as in Example 4 (no dark spots were observed; and the fact that the voltage was the same at the time of photographing indicates no significant changes in voltage-luminance properties).

Likewise, Example 9 in which a polymer (i.e., the boron compound C) was used as a buffer material also showed long-term storage stability.

In addition, as shown in Example 10, the long-term storage stability was maintained even when the substrate was changed from glass to a film substrate having barrier properties.

Based on the above, it became clear that a sealant having sealing properties with a water vapor transmission rate of about 10⁻³ g/m²·day was comparable with a sealant having a lower water vapor transmission rate at a high luminance level in the range of practical use (about 100 cd/m²).

Further, a comparison was made between Example 2 and Comparative Example 1 for the case where polyethyleneimine was used as a buffer layer. The results show that emission comparable with that of a glass sealant was observed until about day 100. This comparison shows that the structure of the device of the present invention makes it possible with a sealant having a water vapor transmission rate of about 10⁻³ g/m²·day to maintain device characteristics comparable to those of a device with a glass sealant for a long time.

### REFERENCE SIGNS LIST

1: substrate
2: cathode
3: first metal oxide layer
4: buffer layer
5: organic compound layer
6: second metal oxide layer
7: anode
8: UV curable resin
9: glass frame
10: sealing substrate

1. An organic electroluminescence device comprising a structure in which a plurality of layers is laminated between an anode and a cathode formed on a substrate;
wherein the organic electroluminescence device is sealed to provide a water vapor transmission rate of 10⁻⁶ to 10⁻³ g/m²·day.

2. The organic electroluminescence device according to claim 1,
wherein the organic electroluminescence device comprises a metal oxide layer between the anode and the cathode.

3. The organic electroluminescence device according to claim 1,
wherein the organic electroluminescence device comprises a buffer layer formed from a material containing an organic compound,
the material containing an organic compound contains 0.1 to 15% by mass of a reducing agent relative to the amount of the organic compound, and
the buffer layer has an average thickness of 5 to 30 nm.

4. The organic electroluminescence device according to claim 1,
wherein the organic electroluminescence device comprises a buffer layer formed from a material containing an organic compound,
the material containing an organic compound contains 0 to 0.1% by mass of a reducing agent relative to the amount of the organic compound, and
the buffer layer has an average thickness of 5 to 60 nm.

5. A film material for use in forming the organic electroluminescence device as defined in claim 1,
wherein the thin film material essentially comprises a film having a water vapor transmission rate or 10⁻⁶ to 10⁻³ g/m²·day.

6. A display device comprising the organic electroluminescence device as defined in claim 1.

7. A lighting system comprising the organic electroluminescence device as defined in claim 1.

8. The organic electroluminescence device according to claim 1, wherein the organic electroluminescence device has no dark spots after 500 hours of being left in air.

9. The organic electroluminescence device according to claim 1, wherein the cathode comprises at least one selected from conductive metal oxide, silver and silver alloy.
